(19) United States
(12) Patent Application Publication
(10) Pub. No.: US 2025/0321482 A1
(43) Pub. Date: Oct. 16, 2025

(54) RESIST COMPOSITION, DRY FILM RESIST, METHOD FOR PRODUCING DRY FILM RESIST, METHOD FOR FORMING RESIST PATTERN, AND METHOD FOR PRODUCING PLATED OBJECT

(71) Applicant: Sumitomo Chemical Company, Limited, Tokyo (JP)

(72) Inventors: Takuya NAKAGAWA, Osaka (JP); Masako SUGIHARA, Osaka (JP)

(73) Assignee: Sumitomo Chemical Company, Limited, Tokyo (JP)

(21) Appl. No.: 19/176,592

(22) Filed: Apr. 11, 2025

(30) Foreign Application Priority Data
Apr. 16, 2024 (JP) 2024-066252

(51) Int. Cl. G03F 7/038; C08L 29/08; G03F 7/00; G03F 7/039; G03F 7/16; G03F 7/20

(52) U.S. Cl. CPC G03F 7/0388; C08L 29/08; G03F 7/0017; G03F 7/0382; G03F 7/0392; G03F 7/168; G03F 7/2002; G03F 7/70008

(57) ABSTRACT

A resist composition, a dry film resist, a method for producing a dry film resist, a method for forming a resist pattern, and a method for producing a plated object are described. The resist composition includes a resin (A1) having a group represented by formula (1), a resin (A2) including a structural unit represented by formula (a3), and an acid generator (B1).

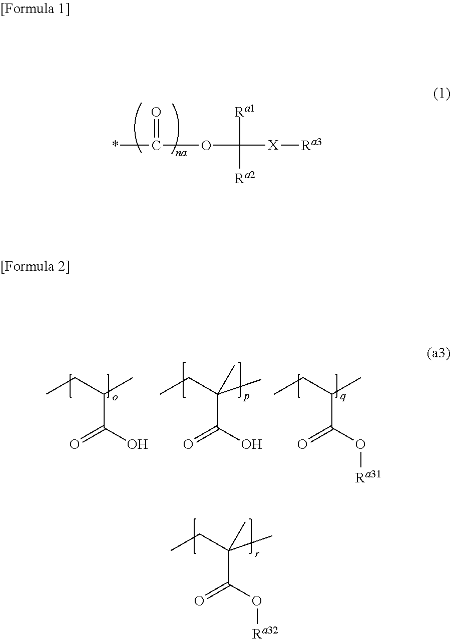

### TECHNICAL FIELD

The present invention relates to a resist composition, a dry film resist, a method for producing a dry film resist, a method for forming a resist pattern, and a method for producing a plated object.

### BACKGROUND ART

Patent Literature 1 discloses a resist composition containing a resin having a repeating unit in which a phenolic hydroxyl group is protected by a tertiary alkyl group (e.g., Polymer-1) and a resin having a repeating unit of a polyacrylic acid ester polymer (e.g., Polymer-4).

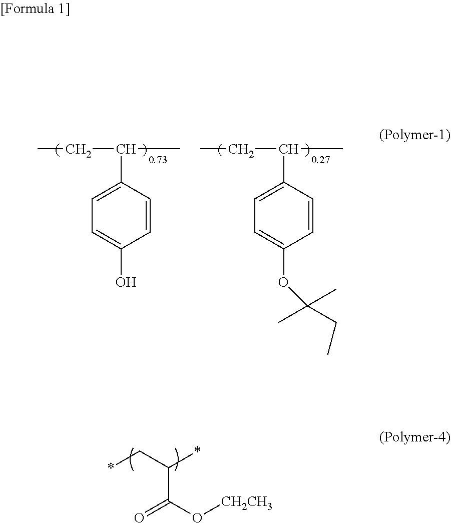

Patent Literature 2 discloses a resist dry film using a resist composition containing a resin having a repeating unit of a hydroxystyrene structure.

### CITATION LIST

### Patent Literature

Patent Literature 1: Japanese Patent Laid-Open No. 2015-232607
Patent Literature 2: Japanese Patent Laid-Open No. 2016-57612

### SUMMARY OF INVENTION

### Problems to be Solved by Invention

When forming a resist pattern using the resist composition disclosed in Patent Literature 1, there is a problem of failing to perform resolution unless diffusion of a photoacid generator is promoted by heating treatment after exposure (post exposure bake).

When a plating treatment is performed using a resist pattern obtained by using the resist composition disclosed in Patent Literature 2, there is still room for improvement in forming a plated object.

Therefore, an object of the present invention is to provide a resist composition capable of forming a resist pattern that can be resolved without a heat treatment after exposure and has sufficient resistance to plating treatment.

### Means to Solve the Problems

The present invention provides the following invention:

[1] A resist composition comprising:
a resin (A1) having a group represented by formula (1);
a resin (A2) including a structural unit represented by formula (a3); and
an acid generator (B),

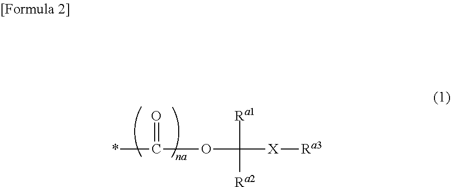

wherein,
R^{a1} and R^{a2} each independently represent a hydrogen atom or a hydrocarbon group having 1 to 20 carbon atoms, R^{a3} represents a hydrocarbon group having 1 to 20 carbon atoms, or R^{a1} represents a hydrogen atom or a hydrocarbon group having 1 to 20 carbon atoms, and R^{a2} and R^{a3} are bonded to each other to form a heterocycle having 3 to 20 carbon atoms together with the carbon atom to which R^{a2} is bonded and X to which R^{a3} is bonded, and a methylene group included in the hydrocarbon group and the heterocycle is optionally replaced with an oxygen atom or a sulfur atom,
X represents an oxygen atom or a sulfur atom,
na represents 0 or 1,
* represents a binding site,

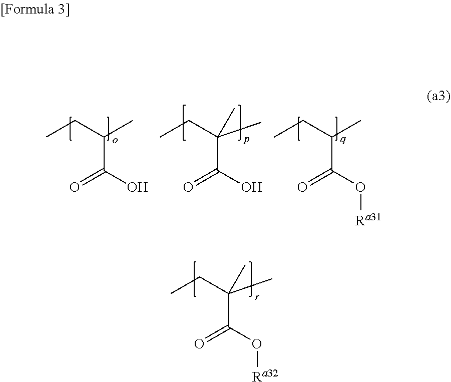

wherein, R^{a31} and R^{a32} each independently represent an alkyl group having 1 to 12 carbon atoms, and a methylene group included in the alkyl group is optionally replaced with an oxygen atom, and
o, p, q, and r each independently represent 0 or a positive number less than 1, and at least one of o and p represents a positive number less than 1, and when o is 0, p and q each represent a positive number less than 1, and when p is 0, o and r each represent a positive number less than 1, and when q is 0, o and r each represent a positive number less than 1, and when r is 0, p and q each represent a positive number less than 1, provided that o+p+q+r=1 is satisfied.

The resist composition according to [1], wherein the resin (A1) includes a structural unit represented by formula (a1-1) or formula (a1-2):

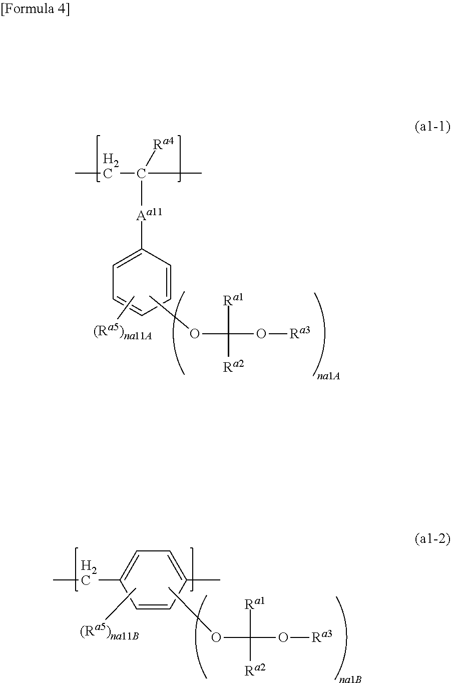

wherein,
R^{a1}, R^{a2}, and R^{a3} have a same meaning as in formula (1),
R^{a4} represents a hydrogen atom, a halogen atom, an alkyl group having 1 to 6 carbon atoms, or a haloalkyl group having 1 to 6 carbon atoms,
R^{a5} represents a halogen atom, a hydroxy group, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group,

A^{a11} represents a single bond or an alkanediyl group having 1 to 12 carbon atoms, and —CH₂— included in the alkanediyl group is optionally replaced with —O—, —CO—, or —NR^{a6}—, R^{a6} represents a hydrogen atom or an alkyl group having 1 to 6 carbon atoms,
na1A represents an integer of 1 to 5, and when na1A is 2 or more, a plurality of groups in parentheses are optionally the same or different from each other,
na11A represents an integer of 0 to 4, and when na11A is 2 or more, a plurality of R^{a5}s are optionally the same or different from each other, provided that 1≤na1A+na11A≤5 is satisfied,
na1B represents an integer of 1 to 4, and when na1B is 2 or more, a plurality of groups in parentheses are optionally the same or different from each other, and
na11B represents an integer of 0 to 3, and when na11B is 2 or more, a plurality of R^{a5}s are optionally the same or different from each other, provided that 1≤na1B+na11B≤4 is satisfied.

[3] The resist composition according to [2], wherein the resin (A1) includes a structural unit represented by formula (a1-1).

[4] The resist composition according to any one of [1] to [3], wherein the resin (A1) further includes a structural unit represented by formula (a2-1):

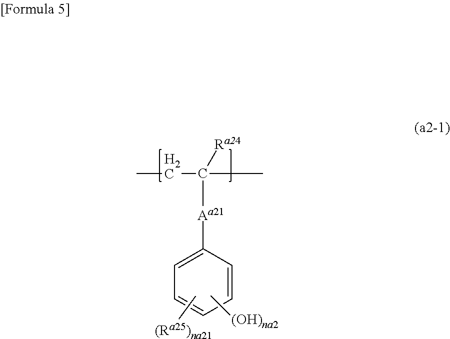

wherein,
R^{a24} represents a hydrogen atom, a halogen atom, an alkyl group having 1 to 6 carbon atoms, or a haloalkyl group having 1 to 6 carbon atoms,
R^{a25} represents a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group,
A^{a21} represents a single bond or an alkanediyl group having 1 to 12 carbon atoms, and —CH₂— included in the alkanediyl group is optionally replaced with —O—, —CO—, or —NR^{a26}—,
R^{a26} represents a hydrogen atom or an alkyl group having 1 to 6 carbon atoms,
na2 represents an integer of 1 to 5, and
na21 represents an integer of 0 to 4, and satisfies 1≤na2+na21≤5, and when na21 is 2 or more, a plurality of R^{a25}s are optionally the same or different from each other.

[5] The resist composition according to any one of [1] to [4], wherein 0.05≤o+p≤0.30 is satisfied, and q and r each represent a positive number less than 1.

[6] The resist composition according to any one of [1] to [5], further comprising a novolak resin (A³).

[7] The resist composition according to any one of [1] to [6], further comprising an adhesion improver (E), wherein the adhesion improver (E) includes at least one selected from the group consisting of a sulfur-containing compound, an aromatic hydroxy compound, a benzotriazole-based compound, a triazine-based compound, and a silicon-containing compound.

[8] A dry film resist comprising:
a support film; and
a resist composition layer stacked on the support film and including the resist composition according to any one of [1] to [7].

[9] A method for producing a dry film resist, comprising:
(1a) a step of applying the resist composition according to any one of [1] to [7] to a support film to form a photoresist composition layer; and
(2a) a step of drying the resist composition layer.

A pattern forming method comprising:
(1b) a step of applying the resist composition according to any one of [1] to [7] onto a substrate and drying the resist composition to form a resist composition layer;
(2b) a step of exposing the resist composition layer to ultraviolet light having a wavelength of 500 nm or less; and
(3b) a step of developing the exposed resist composition layer without heating.

A pattern forming method comprising:
(1c) a step of stacking the dry film resist according to [8] on a substrate;
(2c) a step of peeling at least a portion of the support film from the resist composition layer and exposing the resist composition layer to ultraviolet light having a wavelength of 500 nm or less; and
(3c) a step of developing the exposed resist composition layer without heating.

A method for producing a plated object, comprising:
a step of forming a resist pattern on a substrate having a conductive layer using the resist composition according to any one of [1] to [7] such that a portion of the conductive layer is exposed;
a step of forming a plated object using the resist pattern as a mold; and
a step of peeling off the resist pattern after forming the plated object.

### Effects of Invention

Using the resist composition of the present invention can provide a resist pattern that has both excellent resolution and plating resistance.

The resist composition of the present invention can form a resist pattern with excellent resolution and plating resistance without a heat treatment after exposure (post exposure bake (PEB)).

In addition, a thick dry film resist (resist composition layer) is formed using the resist composition of the present invention, and the thick resist pattern formed using the resist composition has excellent resolution and plating resistance.

### EMBODIMENTS FOR CARRYING OUT INVENTION

In the present specification, unless otherwise specified, in the explanation of the structural formula of a compound, a “hydrocarbon group” means a straight-chain or branched-chain hydrocarbon group, an alicyclic hydrocarbon group, an aromatic hydrocarbon group, or a group formed by combining these groups. When the number of carbon atoms for the “hydrocarbon group” is specified, the above groups can be used within the acceptable range of the number of carbon atoms. When stereoisomers exist, all stereoisomers are included.

In the present specification, “(meth)acrylic acid” means “at least one of acrylic acid and methacrylic acid”, and “(meth)acrylate” means “at least one of acrylate and methacrylate”.

Among the groups described in the present specification, those that can have both a straight-chain structure and a branched structure are interpreted as including both. The “combined group” means a group in which two or more of the exemplified groups are bonded together, and the valence of these groups may be changed appropriately depending on the bonding form.

The “derived from” or “induced from” refer to a polymerizable C═C bond included in the molecule that is polymerized to a —C—C— group (single bond).

When stereoisomers exist, all stereoisomers are included.

For each group, any number of hydrogen atoms included this group at any positions are optionally replaced with a bond, depending on the number of substituents and the like.

The number of carbon atoms in a substituent is not included in the number of carbon atoms in the substituted group.

In the present specification, the “solid content of a resist composition” means the sum of the components excluding the solvent (D), which will be described later, from the total amount of the resist composition.

### <Resist Composition>

The resist composition of the present invention contains a resin having a group represented by formula (1) (hereinafter may be referred to as “resin (A1)”), a resin (A2) having a structural unit represented by formula (a3) (hereinafter may be referred to as “resin (A2)”), and an acid generator (hereinafter may be referred to as “acid generator (B)”).

Further, the resist composition of the present invention may optionally include an adhesion improver (hereinafter, may be referred to as “adhesion improver (E)”) and a resin containing a structural unit represented by formula (a4) (hereinafter, may be referred to as “resin (A³)”).

Further, the resist composition of the present invention may include, as necessary, a quencher (hereinafter, sometimes referred to as “quencher (C)”), a solvent (hereinafter, sometimes referred to as “solvent (D)”), and other components (hereinafter, sometimes referred to as “other components (F)”).

### <Resin (A1)>

Resin (A1) is a resin that includes a structural unit having an acid labile group (a structural unit having an acid labile group may be referred to as “structural unit (a1)”) and includes a structural unit having a group represented by formula (1) as the acid labile group. Resin (A1) may optionally include structural units that are known in the technical field in addition to the structural unit having a group represented by formula (1).

### <Group Represented by Formula (1)>

Structural unit (a1) includes a structural unit having a group represented by formula (1).

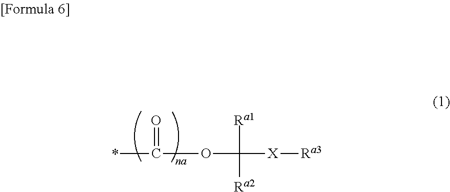

In formula (1), R^{a1} and R^{a2} each independently represent a hydrogen atom or a hydrocarbon group having 1 to 20 carbon atoms, and R^{a3} represents a hydrocarbon group having 1 to 20 carbon atoms. Alternatively, R^{a1} represents a hydrogen atom or a hydrocarbon group having 1 to 20 carbon atoms, and R^{a2} and R^{a3} are bonded to each other to form a heterocycle having 3 to 20 carbon atoms together with the carbon atom and X to which they are bonded. The methylene group included in the hydrocarbon group having 1 to 20 carbon atoms and the heterocycle having 3 to 20 carbon atoms is optionally replaced with an oxygen atom or a sulfur atom. X represents an oxygen atom or a sulfur atom. na represents 0 or 1.*represents a bond.

Examples of the hydrocarbon group having 1 to 20 carbon atoms for R^{a1}, R^{a2}, and R^{a3} include the chain hydrocarbon group having 1 to 20 carbon atoms (such as alkyl group, alkenyl group, and alkynyl group), the alicyclic hydrocarbon group having 3 to 20 carbon atoms, the aromatic hydrocarbon group having 6 to 20 carbon atoms, and the group having 4 to 20 carbon atoms, being a combination of these groups.

Examples of the alkyl group having 1 to 20 carbon atoms include a methyl group, an ethyl group, a propyl group, a butyl group, a pentyl group, a hexyl group, a heptyl group, an octyl group, a decyl group, and a dodecyl group.

Examples of the alkenyl group having 2 to 20 carbon atoms include an ethenyl group, a propenyl group, an isopropenyl group, a butenyl group, an isobutenyl group, a tert-butenyl group, a pentenyl group, a hexenyl group, a heptenyl group, an octenyl group, an isooctenyl group, and a nonenyl group.

Examples of the alkynyl group having 2 to 20 carbon atoms include an ethynyl group, a propynyl group, an isopropynyl group, a butynyl group, an isobutynyl group, a tert-butynyl group, a pentynyl group, a hexynyl group, an octynyl group, and a nonynyl group.

The chain hydrocarbon group having 1 to 20 carbon atoms preferably has 1 to 18 carbon atoms, more preferably has 1 to 16 carbon atoms, still more preferably has 1 to 12 carbon atoms, even more preferably has 1 to 8 carbon atoms, and yet even more preferably has 1 to 6 carbon atoms.

Examples of the alicyclic hydrocarbon group having 3 to 20 carbon atoms include a monocyclic alicyclic hydrocarbon group such as a cycloalkyl group including a cyclopentyl group, a cyclohexyl group, a cycloheptyl group, and a cyclooctyl group; and a polycyclic alicyclic hydrocarbon group such as a decahydronaphthyl group, an adamantyl group, and a norbornyl group. The alicyclic hydrocarbon group having 3 to 20 carbon atoms preferably has 3 to 18 carbon atoms, more preferably has 3 to 16 carbon atoms, and still more preferably has 3 to 12 carbon atoms.

Examples of the aromatic hydrocarbon group having 6 to 20 carbon atoms include an aryl group such as a phenyl group, a naphthyl group, an anthryl group, a biphenyl group, and a phenanthryl group. The aromatic hydrocarbon group may further have a substituent, and examples of the substituent include an aryloxy group having 6 to 10 carbon atoms. The aromatic hydrocarbon group having 6 to 20 carbon atoms preferably has 6 to 18 carbon atoms, more preferably has 6 to 14 carbon atoms, and still more preferably has 6 to 10 carbon atoms.

Among the groups having 4 to 20 carbon atoms in which the above groups are combined, examples of the group in which an alkyl group and an alicyclic hydrocarbon group are combined (group having 4 to 20 carbon atoms) include a methylcyclohexyl group, a dimethylcyclohexyl group, a methylnorbornyl group, an isobornyl group, a 2-alkyladamantan-2-yl group, and a 1-(adamantan-1-yl)alkane-1-yl group.

Examples of the group in which an alkyl group and an aromatic hydrocarbon group are combined (group having 7 to 20 carbon atoms) include an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2, 6-diethylphenyl group, and a 2-methyl-6-ethylphenyl group.

Examples of the group in which an alicyclic hydrocarbon group and an aromatic hydrocarbon group are combined (group having 9 to 20 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group, a p-adamantylphenyl group, and a phenylcyclohexyl group.

When R^{a2} and R^{a3} are bonded to each other to form a heterocycle having 3 to 20 carbon atoms together with the carbon atom and X to which they are bonded, the heterocycle may be a monocycle or a polycycle. Examples of —C(R^{a1})(R^{a2})—X—R^{a3} include the following groups. In the following groups, R^{a1} has the same meaning as above, and*represents the binding site.

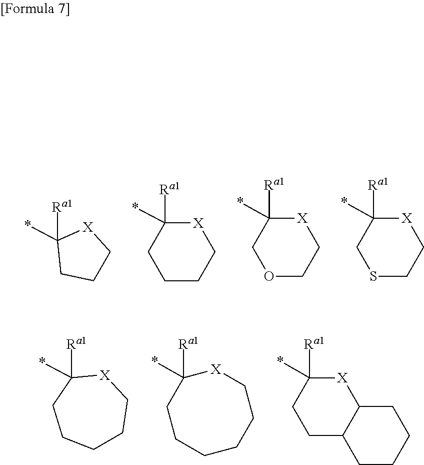

R^{a1} is preferably a hydrogen atom or a hydrocarbon group having 1 to 18 carbon atoms, more preferably a hydrogen atom or a hydrocarbon group having 1 to 12 carbon atoms, and still more preferably a hydrogen atom.

R^{a2} is preferably a hydrogen atom or a hydrocarbon group having 1 to 18 carbon atoms, or is bonded to R^{a3} to form a heterocycle having 3 to 18 carbon atoms together with the carbon atom and X to which they are bonded, more preferably a hydrogen atom or a hydrocarbon group having 1 to 12 carbon atoms, or is bonded to R^{a3} to form a heterocycle having 3 to 12 carbon atoms together with the carbon atom and X to which they are bonded, still more preferably a hydrocarbon group having 1 to 12 carbon atoms, and even more preferably a methyl group or an ethyl group.

R^{a3} is preferably a hydrocarbon group having 1 to 18 carbon atoms, or is bonded to Raz to form a heterocycle having 3 to 18 carbon atoms together with the carbon atom and X to which they are bonded, and more preferably a hydrocarbon group having 1 to 12 carbon atoms, or is bonded to R^{a2} to form a heterocycle having 3 to 12 carbon atoms together with the carbon atom and X to which they are bonded.

The hydrocarbon groups of R^{a1}, R^{a2}, and R^{a3} each include an alkyl group having 1 to 18 carbon atoms, an alicyclic hydrocarbon group having 3 to 18 carbon atoms, an aromatic hydrocarbon group having 6 to 18 carbon atoms, or the group having 4 to 18 carbon atoms, being a combination thereof. These groups can be optionally selected from those listed above.

X is preferably an oxygen atom. na is preferably 0.

Specific examples of the group represented by formula (1) include the following groups.

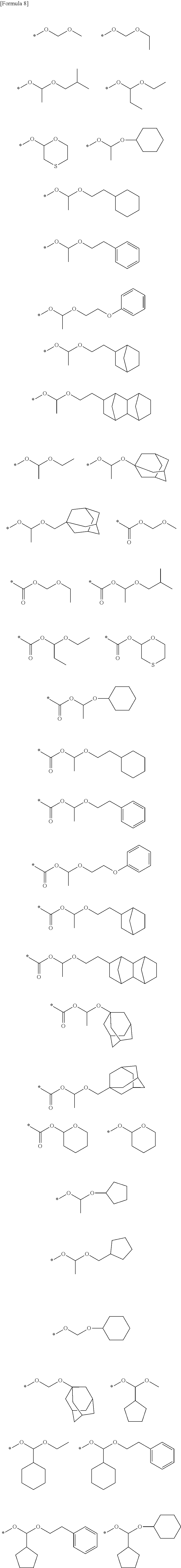

<Structural unit (a1-1) and structural unit (a1-2): structural unit having group represented by formula (1)>

An example of the structural unit having a group represented by formula (1) include the structural unit represented by the following formulas (a1-1) and (a1-2) (hereinafter, may be referred to as “structural unit (a1-1)” and “structural unit (a1-2) “, respectively). <Structural unit (a1-1): structural unit having group represented by formula (1)>

Structural unit (a1-1) is a structural unit represented by the following formula (a1-1).

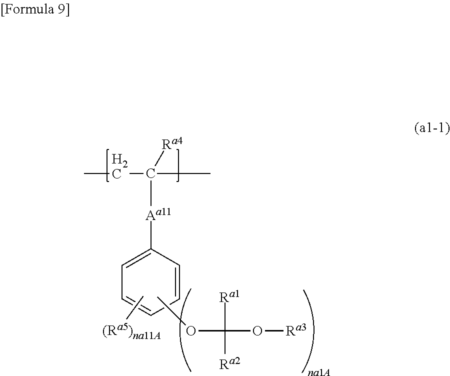

In formula (a1-1),
R^{a1}, R^{a2}, and R^{a3} have the same meanings as in formula (1).

R^{a4} represents a hydrogen atom, a halogen atom, an alkyl group having 1 to 6 carbon atoms, or a haloalkyl group having 1 to 6 carbon atoms.

R^{a5} represents a halogen atom, a hydroxy group, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group.

A^{a11} represents a single bond or an alkanediyl group having 1 to 12 carbon atoms, and —CH₂— included in the alkanediyl group is optionally replaced with —O—, —CO—, or —NR^{a6}—. R^{a6} represents a hydrogen atom or an alkyl group having 1 to 6 carbon atoms.

na1A represents an integer of 1 to 5, and when na1A is 2 or more, a plurality of the group in the parentheses are optionally the same or different from each other.

na11A represents a positive number of 0 to 4, and when na11A is 2 or more, a plurality of R^{a5}s are optionally the same or different from each other, provided that 1≤na1A+na11A≤5 is satisfied.

In formula (a1-1), specific and suitable examples of R^{a1}, R^{a2}, and R^{a3} include the same groups as the suitable examples of R^{a1}, R^{a2}, and R^{a3} listed in formula (1).

Examples of the halogen atom for R^{a4} include a fluorine atom, a chlorine atom, a bromine atom, and an iodine atom.

The alkyl group having 1 to 6 carbon atoms for R^{a4} may be a linear or branched alkyl group, and examples thereof include a methyl group, an ethyl group, a propyl group, a butyl group, a pentyl group, and a hexyl group.

Examples of the haloalkyl group having 1 to 6 carbon atoms for R^{a4} include the group in which a hydrogen atom included in the above-described alkyl group is replaced with the above-described halogen atom, such as a fluorinated alkyl group having 1 to 6 carbon atoms, a chlorinated alkyl group having 1 to 6 carbon atoms, a brominated alkyl group having 1 to 6 carbon atoms, or an iodinated alkyl group having 1 to 6 carbon atoms, and among these, the perfluoroalkyl group having 1 to 3 carbon atoms is preferable.

R^{a4} is preferably a hydrogen atom or a methyl group.

Examples of the alkanediyl group having 1 to 12 carbon atoms for A^{a11} include: the straight-chain alkanediyl group such as a methylene group, an ethylene group, a propane-1,3-diyl group, a propane-1,2-diyl group, a butane-1,4-diyl group, a pentane-1,5-diyl group, a hexane-1,6-diyl group, an octane-1,8-diyl group, a nonane-1,9-diyl group, a decane-1,10-diyl group, an undecane-1,11-diyl group, and a dodecane-1, 1 2-diyl group; and the branched alkanediyl group such as a butane-1,3-diyl group, a 2-methylpropane-1,3-diyl group, a 2-methylpropane-1,2-diyl group, a pentane-1,4-diyl group, a 2-methylbutane-1,4-diyl group, heptane-1,6-diyl group, an octane-1,8-diyl group, a nonane-1,9-diyl group, and a decane-1,10-diyl group. When A^{a11} is an alkanediyl group, the alkanediyl group preferably has 1 to 6 carbon atoms, more preferably 1 to 4 carbon atoms, still more preferably 1 to 3 carbon atoms, and even more preferably 1 or 2 carbon atoms.

Examples of the alkyl group having 1 to 6 carbon atoms for R^{a6} include a methyl group, an ethyl group, an n-propyl group, an isopropyl group, an n-butyl group, and a tert-butyl group.

When —CH₂— included in the alkanediyl group of A^{a11} is replaced with —O—, —CO—, or —NR^{a6}, the number of carbon atoms before replacement is regarded as the number of carbon atoms of the hydrocarbon group.

Examples of the group in which the —CH₂— in the alkanediyl group having 1 to 12 carbon atoms of A^{a11} is replaced with —O— or —CO— include: a hydroxy group (a group in which —CH₂— included in the methyl group is replaced with —O—); a carboxy group (a group in which —CH₂ —CH₂— included in the ethyl group is replaced with —O—CO—); a carbonyl group (a group in which —CH₂— included in the methylene group is replaced with —CO—); an oxy group (a group in which —CH₂— in the methylene group is replaced with —O—); an amino group (a group in which —CH₂— included in the alkanediyl group is replaced with —NR^{a6}—); an alkoxy group (a group in which —CH₂— included at any position in the alkyl group is replaced with —O—); an alkoxycarbonyl group (a group in which —CH₂ —CH₂— at any position included in the alkyl group is replaced with —O—CO—); an alkylcarbonyl group (a group in which —CH₂— at any position included in the alkyl group is replaced with —CO—); and an alkylamino group (a group in which —CH₂— included in the alkyl group is replaced with —NR^{a6}—). These replaced groups include those similar to the groups exemplified in the present specification, in the acceptable range of the upper limit of the carbon number.

Examples of the group in which —CH₂— included in the alkanediyl group having 1 to 12 carbon atoms of A^{a11} is replaced with —O—, —CO—, or —NR26 include * —O—, *—CO—O—, * —O—CO—, *—CO—O—A^{a12}—CO—O—, * —O—CO—A^{a12} —O—, * —O—A^{a12}—CO—O—, *—CO—O—A^{a12} —O—CO—, and * —O—CO—A^{a12} —O—CO—. Among these, *—CO—O—, *—CO—O—A^{a12}—CO—O—, * —O—A^{a12}—CO—O—, or *—CO—NR^{a26}— is preferable. Herein, A^{a12} represents an alkanediyl group having 1 to 8 carbon atoms, and * represents the binding site that bonds to the carbon atom to which R^{a4} is bonded. The alkanediyl group of A^{a12} includes the same alkanediyl group as A^{a11}, in the acceptable range of the upper limit of the number of carbon atoms.

A^{a11} is preferably a single bond, *—CO—O—, or *—CO—O—A^{a12}—CO—O—, more preferably a single bond, *—CO—O—, or *—CO—O—CH₂—CO—O—, and still more preferably a single bond or *—CO—O—.

Examples of the halogen atom, alkyl group having 1 to 6 carbon atoms, and haloalkyl group having 1 to 6 carbon atoms for R^{a5} include the same groups as the halogen atom, alkyl group having 1 to 6 carbon atoms, and haloalkyl group having 1 to 6 carbon atoms for R^{a4} in formula (a1-1).

Examples of the alkoxy group having 1 to 6 carbon atoms for R^{a5} include a methoxy group, an ethoxy group, a propoxy group, an isopropoxy group, a butoxy group, a sec-butoxy group, and a tert-butoxy group. The alkoxy group has preferably 1 to 4 carbon atoms, more preferably 1 to 3 carbon atoms, still more preferably a methoxy group or an ethoxy group, and even more preferably a methoxy group.

Examples of the alkoxyalkyl group having 2 to 12 carbon atoms for R^{a5} include a methoxymethyl group, an ethoxyethyl group, a propoxymethyl group, an isopropoxymethyl group, a butoxymethyl group, a sec-butoxymethyl group, and a tert-butoxymethyl group. The alkoxyalkyl group is preferably an alkoxyalkyl group having 2 to 8 carbon atoms, more preferably a methoxymethyl group or an ethoxyethyl group, and still more preferably a methoxymethyl group.

Examples of the alkoxyalkoxy group having 2 to 12 carbon atoms for R^{a5} include a methoxymethoxy group, a methoxyethoxy group, an ethoxymethoxy group, an ethoxyethoxy group, a propoxymethoxy group, an isopropoxymethoxy group, a butoxymethoxy group, a sec-butoxymethoxy group, and a tert-butoxymethoxy group. The alkoxyalkoxy group is preferably an alkoxyalkoxy group having 2 to 8 carbon atoms, and more preferably a methoxyethoxy group or an ethoxyethoxy group.

Examples of the alkylcarbonyl group having 2 to 4 carbon atoms for R^{a5} include an acetyl group, a propionyl group, and a butyryl group. The alkylcarbonyl group is preferably an alkylcarbonyl group having 2 to 3 carbon atoms, and more preferably an acetyl group.

Examples of the alkylcarbonyloxy group having 2 to 4 carbon atoms for R^{a5} include an acetyloxy group, a propionyloxy group, and a butyryloxy group. The alkylcarbonyloxy group is preferably an alkylcarbonyloxy group having 2 to 3 carbon atoms, and more preferably an acetyloxy group.

R^{a5} is preferably a halogen atom, a hydroxy group, an alkyl group having 1 to 4 carbon atoms, an alkoxy group having 1 to 4 carbon atoms, or an alkoxyalkoxy group having 2 to 8 carbon atoms, more preferably a fluorine atom, an iodine atom, a hydroxy group, a methyl group, a methoxy group, an ethoxy group, an ethoxyethoxy group, or an ethoxymethoxy group, and still more preferably a fluorine atom, an iodine atom, a hydroxy group, a methyl group, a methoxy group, or an ethoxyethoxy group.

na1A is preferably 1, 2, or 3, and more preferably 1 or 2.

na11A is preferably 0, 1, 2, or 3, and more preferably 0 or 1.

The group represented by —O-CRalR^{a2} —O—R^{a3} is preferably bonded to the 3rd or 4th position of the benzene ring, and more preferably bonded to the 4th position of the benzene ring.

Examples of the group represented by formula (a1-1) include structural units represented by the following formula. Specific examples of structural unit (a1-1) include structural units in which the hydrogen atom corresponding to R^{a4} is replaced with a halogen atom, an alkyl group having 1 to 6 carbon atoms, or a haloalkyl group having 1 to 6 carbon atoms in the following structural units.

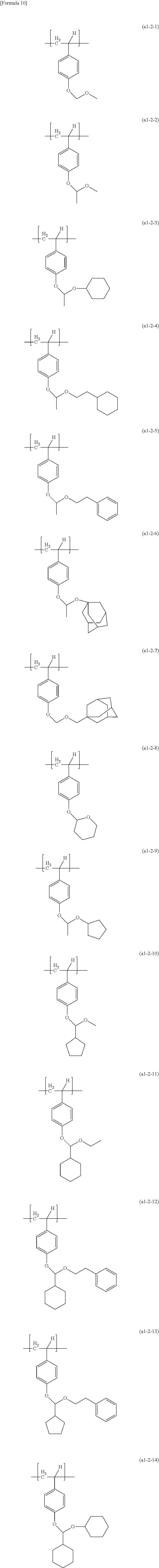

<Structural Unit (a1-2): Structural Unit Having Group Represented by Formula (1)>

A structural unit (a1-2) is a structural unit represented by the following formula (a1-2)

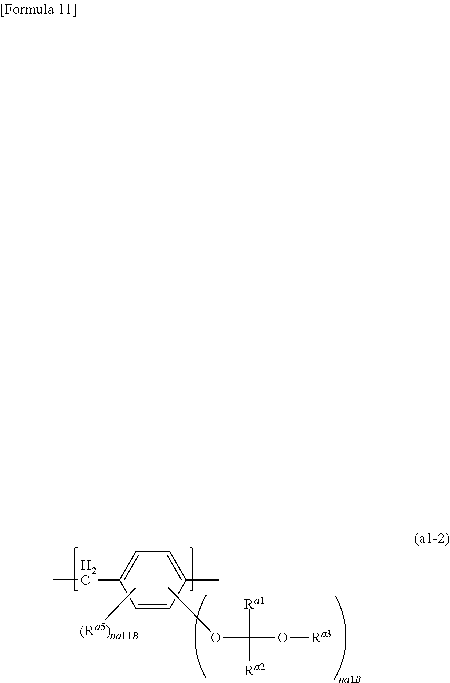

In formula (a1-2),
R^{a1}, R^{a2}, and R^{a3} have the same meaning as in formula (1).

R^{a5} represents a halogen atom, a hydroxy group, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group.

na1B represents an integer of 1 to 4, and when na1B is 2 or more, the groups in the parentheses are optionally the same or different from each other. na11B represents a positive number of 0 to 3, and when na11B is 2 or more, a plurality of R^{a5}s are optionally the same or different from each other. However, 1<na1B+na11B≤4 is satisfied.

In formula (a1-2), suitable examples of R^{a1}, R^{a2}, and R^{a3} are the same as those of formula (a1-1) and are the same as the suitable examples of R^{a1}, R^{a2}, and R^{a3} in formula (1).

In formula (a1-2), specific examples of R^{a5} that are the halogen atom, alkyl group having 1 to 6 carbon atoms, haloalkyl group having 1 to 6 carbon atoms, alkoxy group having 1 to 6 carbon atoms, alkoxyalkyl group having 2 to 12 carbon atoms, alkoxyalkoxy group having 2 to 12 carbon atoms, alkylcarbonyl group having 2 to 4 carbon atoms, and alkylcarbonyloxy group having 2 to 4 carbon atoms include the same groups as those listed for R^{a5} in formula (a1-1).

In formula (a1-2), R^{a5} is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group, or an ethoxy group, and even more preferably a methyl group or a methoxy group.

na1B is preferably 1 or 2, more preferably 1. na11B is preferably 0, 1, or 2, more preferably 0 or 1.

Examples of the structural unit represented by formula (a1-2) include structural units represented by the following formula.

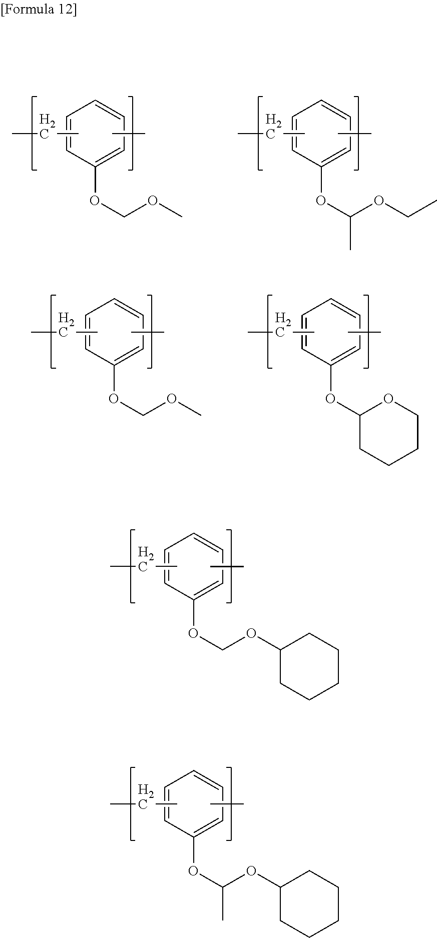

Resin (A1) may include one or more structural units (a1-1) or one or more structural units (a1-2). When resin (A1) includes structural unit (a1-1) or structural unit (a1-2), the total content of structural unit (a1-1) or structural unit (a1-2) is preferably 3 to 80 mol %, more preferably 5 to 60 mol %, still more preferably 10 to 55 mol %, even more preferably 15 to 50 molo, and yet even more preferably 20 to 45 mol %, with respect to all structural units of resin (A1).

The structural unit having a group represented by formula (1) is preferably structural unit (a1-1).

Resin (A1) may include a structural unit having an acid labile group other than the group represented by formula (1) that is conventionally known. When resin (A1) includes the structural unit having an acid labile group other than the group represented by formula (1), the total content of the structural unit having an acid labile group other than the group represented by formula (1) is preferably 0 mol % to 10 mol %, more preferably 0 mol % to 5 mol %, and still more preferably 0 mol % to 3 mol %, with respect to all structural units of resin (A1).

<Structural Unit (a2)>

Resin (A1) may further include a structural unit that does not have an acid labile group (a structural unit that does not include an acid labile group may be referred to as “structural unit (a2)”), as necessary. As structural unit (a2), a structural unit known in the art may be used. Examples of structural unit (a2) include a structural unit represented by the following formula (a2-1), formula (a2-2), formula (a2-3), or formula (a2-4) (hereinafter, these may be referred to as “structural unit (a2-1) “, “structural unit (a2-2) “, “structural unit (a2-3) “, or “structural unit (a2-4) “, respectively).

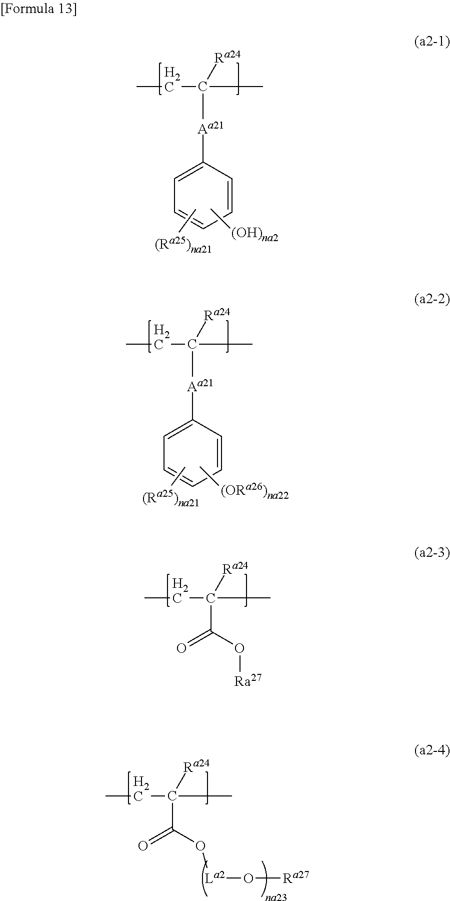

In formulas (a2-1), (a2-2), (a2-3), and (a2-4),
R^{a24} represents a hydrogen atom, a halogen atom, an alkyl group having 1 to 6 carbon atoms, or a haloalkyl group having 1 to 6 carbon atoms.

R^{a25} represents a halogen atom, a hydroxy group, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group.

R^{a26} represents a hydrocarbon group having 1 to 12 carbon atoms. However, this excludes groups in which the carbon atom bonded to an oxygen atom is a tertiary carbon atom. A methylene group included in the hydrocarbon group having 1 to 12 carbon atoms is optionally replaced with an oxygen atom or a carbonyl group. However, a methylene group bonded to an oxygen atom and a methylene group bonded to the methylene group are not replaced with an oxygen atom.

R^{a27} represents a hydrogen atom or a hydrocarbon group having 1 to 12 carbon atoms. However, this excludes the group in which the carbon atom bonded to the oxygen atom is a tertiary carbon atom.

A^{a21} represents a single bond or an alkanediyl group having 1 to 12 carbon atoms, and —CH₂— included in the alkanediyl group is optionally replaced with —O—, —CO—, or —NR^{a6}—. La2 represents an alkanediyl group having 2 to 6 carbon atoms. However, this excludes the group in which the carbon atom bonded to the oxygen atom is a tertiary carbon atom.

na2 represents an integer of 1 to 5.

na21 represents an integer of 0 to 4, and satisfies 1≤na2+na21≤5, and when na21 is 2 or more, a plurality of R^{a25}s are optionally the same or different from each other. na22 represents an integer of 0 to 5, and satisfies 0<na21+na22≤5, and when na22 is 2 or more, the groups in parentheses are optionally the same or different from each other.

na23 represents an integer of 1 to 30, and when na22 is 2 or more, a plurality of La's are optionally the same or different from each other.

In formulas (a2-1) to (a2-4), specific and suitable examples of R^{a24} include the same groups as the suitable examples of R^{a4} in formula (a1-1).

In formulas (a2-1) and (a2-2), specific and suitable examples of R^{a25} include the same groups as the suitable examples of R^{a5} in the formula (a1-1).

In formula (a2-2), examples of the hydrocarbon group for R^{a26} include the group in which the bond to the oxygen atom is not a tertiary carbon atom, that is, the group in which the bonded carbon has one or more atoms other than carbon atoms, such as hydrogen atoms, bonded thereto. In addition, examples of the hydrocarbon group for R^{a26} include the group in which the methylene group bonded to an oxygen atom and a methylene group bonded to the methylene group are not replaced with an oxygen atom, that is, the group that includes no acetal structure. Therefore, the structural unit represented by formula (a2-2) does not include the structural unit represented by formula (a1-1).

R^{a26} is preferably a hydrocarbon group having 1 to 10 carbon atoms, or a group in which the methylene group included in the hydrocarbon group is replaced with an oxygen atom or a carbonyl group, more preferably a linear or branched alkyl group having 1 to 8 carbon atoms, an alicyclic hydrocarbon group having 3 to 10 carbon atoms, an aromatic hydrocarbon group having 6 to 10 carbon atoms, or a group having 6 to 10 carbon atoms formed by combining these, or a group in which the methylene group included in these groups is replaced with an oxygen atom or a carbonyl group, and still more preferably a linear or branched alkyl group having 1 to 5 carbon atoms, an alicyclic hydrocarbon group having 5 to 10 carbon atoms, a phenyl group, or a group having 6 to 10 carbon atoms formed by combining these, or a group in which the methylene group adjacent to the oxygen atom of these groups is replaced with a carbonyl group.

In formula (a2-1), na2 is preferably 1, 2, or 3, and more preferably 1 or 2.

In formulas (a2-1) and (a2-2), na21 is preferably 0, 1, 2, or 3, and more preferably 0 or 1.

In formula (a2-2), na22 is preferably 1, 2, or 3, and more preferably 1 or 2.

In formulas (a2-3) and (a2-4), examples of the hydrocarbon group having 1 to 12 carbon atoms for R^{a27} include a chain hydrocarbon group having 1 to 12 carbon atoms (such as an alkyl group, an alkenyl group, and an alkynyl group), an alicyclic hydrocarbon group having 3 to 12 carbon atoms, an aromatic hydrocarbon group having 6 to 12 carbon atoms, and a group having 4 to 12 carbon atoms formed by combining these groups.

Examples of the alkyl group having 1 to 12 carbon atoms include a methyl group, an ethyl group, an n-propyl group, an isopropyl group, an n-butyl group, a sec-butyl group, an isobutyl group, an n-pentyl group, an n-hexyl group, an n-heptyl group, an n-octyl group, an n-nonyl group, and an n-decyl group.

Examples of the alkenyl group having 2 to 12 carbon atoms include an ethenyl group, a propenyl group, an isopropenyl group, a butenyl group, an isobutenyl group, a tert-butenyl group, a pentenyl group, a hexenyl group, a heptenyl group, an octenyl group, an isooctenyl group, and a nonenyl group.

Examples of the alkynyl group having 2 to 12 carbon atoms include an ethynyl group, a propynyl group, an isopropynyl group, a butynyl group, an isobutynyl group, a tert-butynyl group, a pentynyl group, a hexynyl group, an octynyl group, and a nonynyl group.

The chain hydrocarbon group having 1 to 12 carbon atoms preferably has 1 to 10 carbon atoms, more preferably 1 to 8 carbon atoms, and still more preferably 1 to 6 carbon atoms.

The alicyclic hydrocarbon group having 3 to 12 carbon atoms may be either monocyclic or polycyclic. Examples of the monocyclic alicyclic hydrocarbon group include a cycloalkyl group such as a cyclopentyl group, a cyclohexyl group, a cycloheptyl group, and a cyclooctyl group. Examples of the polycyclic alicyclic hydrocarbon group include a decahydronaphthyl group, an adamantly group, a norbornyl group, and the following group (* represents a bond).

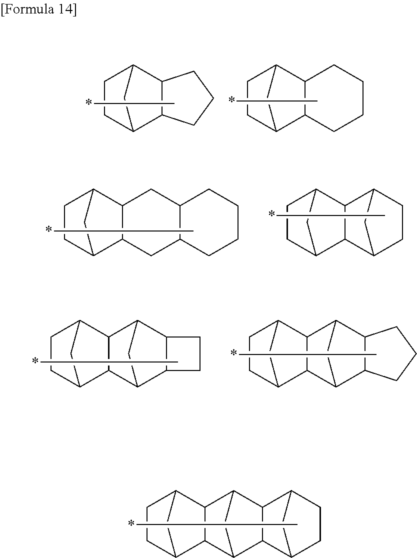

The alicyclic hydrocarbon group having 3 to 12 carbon atoms preferably has 3 to 10 carbon atoms, and more preferably has 3 to 8 carbon atoms.

Examples of the aromatic hydrocarbon group having 6 to 12 carbon atoms include a phenyl group and a naphthyl group. The aromatic hydrocarbon group having 6 to 12 carbon atoms is preferably a group having 6 to 10 carbon atoms.

Examples of the group having 4 to 12 carbon atoms formed by combining the above groups, such as a group obtained by combining an alkyl group with an alicyclic hydrocarbon group (a group having 4 to 12 carbon atoms), include a methylcyclohexyl group, a dimethylcyclohexyl group, a methylnorbornyl group, a cyclohexylmethyl group, an adamantylmethyl group, and a norbornylethyl group.

Examples of the group formed by combining an alkyl group and an aromatic hydrocarbon group (group having 7 to 12 carbon atoms) include an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Examples of the group formed by combining an alicyclic hydrocarbon group and an aromatic hydrocarbon group (group having 9 to 12 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group and a phenylcyclohexyl group.

In formula (a2-3), R^{a27} is preferably a hydrogen atom or a hydrocarbon group having 1 to 10 carbon atoms, more preferably a hydrogen atom, an alkyl group having 1 to 8 carbon atoms, or an alicyclic hydrocarbon group having 3 to 10 carbon atoms, and still more preferably a hydrogen atom, an alkyl group having 1 to 6 carbon atoms, or an alicyclic hydrocarbon group having 3 to 8 carbon atoms. However, this excludes the group in which the carbon atom bonded to the oxygen atom is a tertiary carbon atom.

In formula (a2-4), R^{a27} is preferably an alkyl group having 1 to 4 carbon atoms, and more preferably an alkyl group having 1 to 3 carbon atoms. However, this excludes the group in which the carbon atom bonded to the oxygen atom is a tertiary carbon atom.

La2 is preferably an alkanediyl group having 2 to 4 carbon atoms (e.g., an ethane-1,2-diyl group, a propane-1,3-diyl group, a propane-1,2-diyl group, or a butane-1,4-diyl group), more preferably an alkanediyl group having 2 to 3 carbon atoms (e.g., an ethane-1,2-diyl group, a propane-1,3-diyl group, or a propane-1,2-diyl group), and still more preferably an ethane-1,2-diyl group.

na23 is preferably an integer of 1 to 20, more preferably an integer of 1 to 16, still more preferably an integer of 1 to 14, even more preferably an integer of 1 to 10, and yet even more preferably an integer of 1 to 6.

Structural unit (a2-1) is preferably a structural unit represented by formula (a2-1-1), formula (a2-1-2), formula (a2-1-3), or formula (a2-1-4).

In addition, the monomer from which structural unit (a2-1) is derived is disclosed, for example, in Japanese Patent Laid-Open No. 2010-204634.

Specific examples of structural unit (a2-1) include structural units represented by the following formulas. Specific examples of structural unit (a2-1) include structural units represented by formulas (a2-1-1) to (a2-1-4) in which the hydrogen atom or methyl group corresponding to R^{a24} is replaced with a halogen atom, an alkyl group having 2 to 6 carbon atoms, or a haloalkyl group having 1 to 6 carbon atoms.

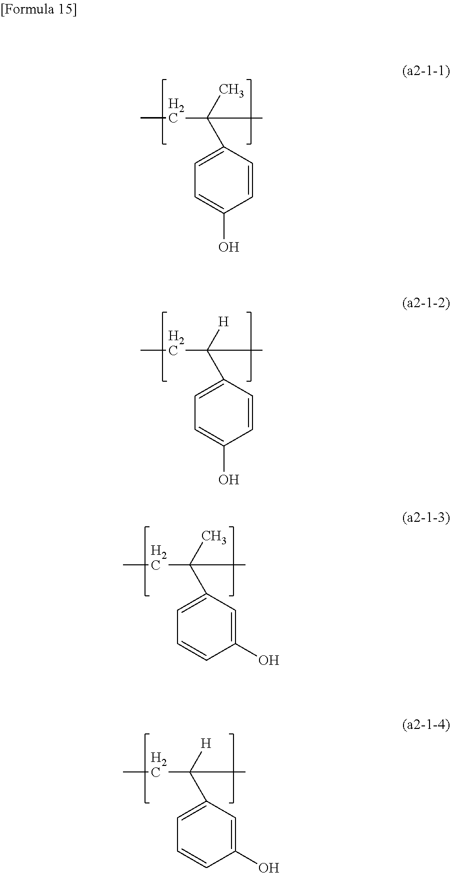

Specific examples of structural unit (a2-2) include structural units represented by the following formulas. Specific examples of structural unit (a2-1) include structural units represented by formulas (a2-2-1) to (aFeb. 2, 2010) in which the hydrogen atom corresponding to R^{a24} is replaced with a halogen atom, an alkyl group having 1 to 6 carbon atoms, or a haloalkyl group having 1 to 6 carbon atoms.

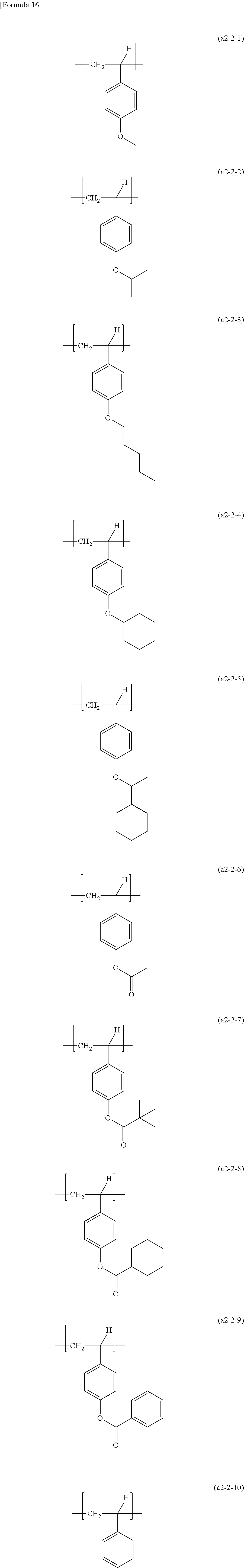

Examples of the monomer that leads to structural unit (a2-3) include: an alkyl (meth)acrylate such as methyl (meth)acrylate, ethyl (meth)acrylate, propyl (meth)acrylate, butyl (meth)acrylate, and hexyl (meth)acrylate;

a monocyclic (meth)acrylate ester such as a cycloalkyl (meth)acrylate such as cyclopentyl (meth)acrylate and cyclohexyl (meth)acrylate; a polycyclic (meth)acrylate ester such as adamantyl (meth)acrylate and norbornyl (meth)acrylate; and an aryl (meth)acrylic acid ester such as phenyl (meth)acrylate and benzyl (meth)acrylate.

Examples of the monomer that leads to structural unit (a2-4) include a (meth)acrylate ester such as a (poly)ethylene glycol monomethyl ether (meth)acrylate ((poly)alkylene glycol monoalkyl ether (meth)acrylate) such as ethylene glycol monomethyl ether (meth)acrylate, ethylene glycol monoethyl ether (meth)acrylate, ethylene glycol monopropyl ether (meth)acrylate, ethylene glycol monobutyl ether (meth)acrylate, diethylene glycol monomethyl ether (meth)acrylate, triethylene glycol monomethyl ether (meth)acrylate, tetraethylene glycol monomethyl ether (meth)acrylate, pentaethylene glycol monomethyl ether (meth)acrylate, hexaethylene glycol monomethyl ether (meth)acrylate, heptaethylene glycol monomethyl ether (meth)acrylate, nonaethylene glycol monomethyl ether (meth)acrylate, and octaethylene glycol monomethyl ether (meth)acrylate.

Further, examples of the monomer that leads to structural unit (a2) include: carboxylic acids such as acrylic acid, methacrylic acid, crotonic acid, maleic acid, fumaric acid, citraconic acid, mesaconic acid, and itaconic acid; a (meth)acrylic acid hydroxyalkyl ester such as 2-hydroxyethyl (meth)acrylate and 2-hydroxypropyl (meth)acrylate; and styrenes such as styrene, a-methylstyrene, 4-methylstyrene, 2-methylstyrene, 3-methylstyrene, 4-methoxystyrene, 4-isopropoxystyrene, and hydroxystyrene.

When resin (A1) includes structural unit (a2-1), structural unit (a2-2), structural unit (a2-3), and/or structural unit (a2-4), the total content of these is preferably 1 to 90 mol %, more preferably 1 to 85 mol %, still more preferably 5 to 80 mol %, and particularly preferably 5 to 75 mol %, with respect to all structural units in resin (A1).

When resin (A1) includes structural unit (a2), the content ratio between structural unit (a1) and structural unit (a2) (structural unit (a1): structural unit (a2)) is preferably 10:90 to 80:20, more preferably 15:85 to 60:40, and still more preferably 15:85 to 45:55, on a molar basis.

Resin (A1) is preferably a resin having structural unit (a1-1) and structural unit (a2-1) or structural unit (a2-2).

Examples of the combination of structural units included in resin (A1) include those represented by formulas (A¹-1) to (A¹-22).

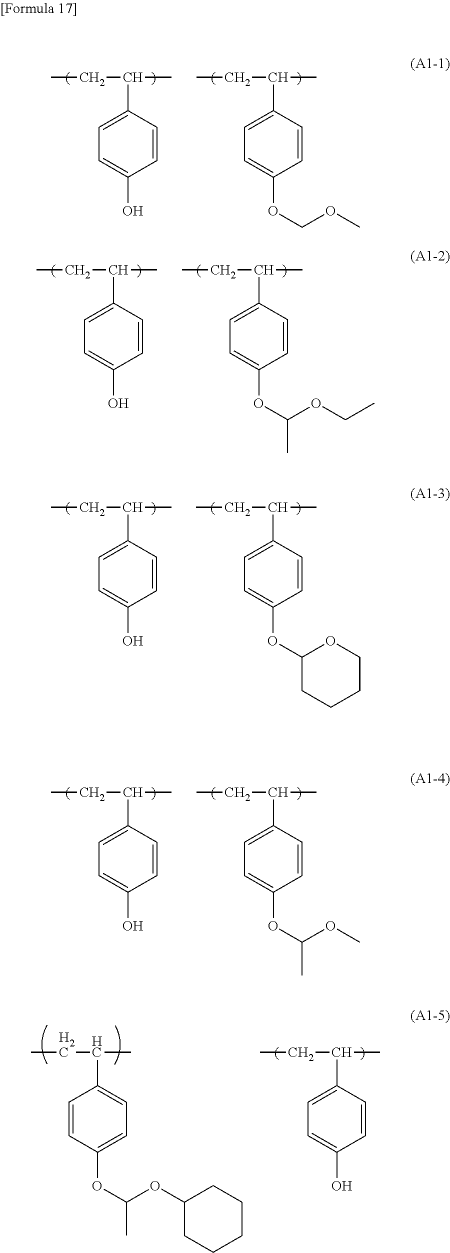

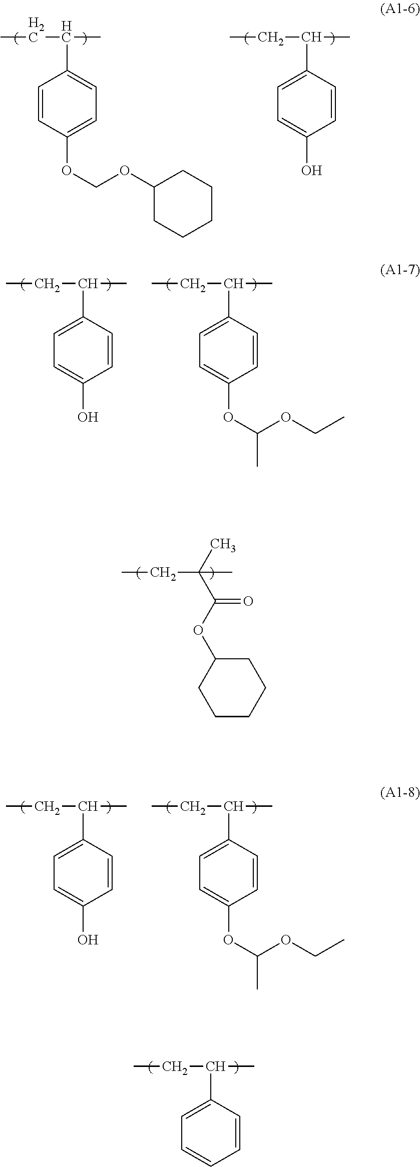

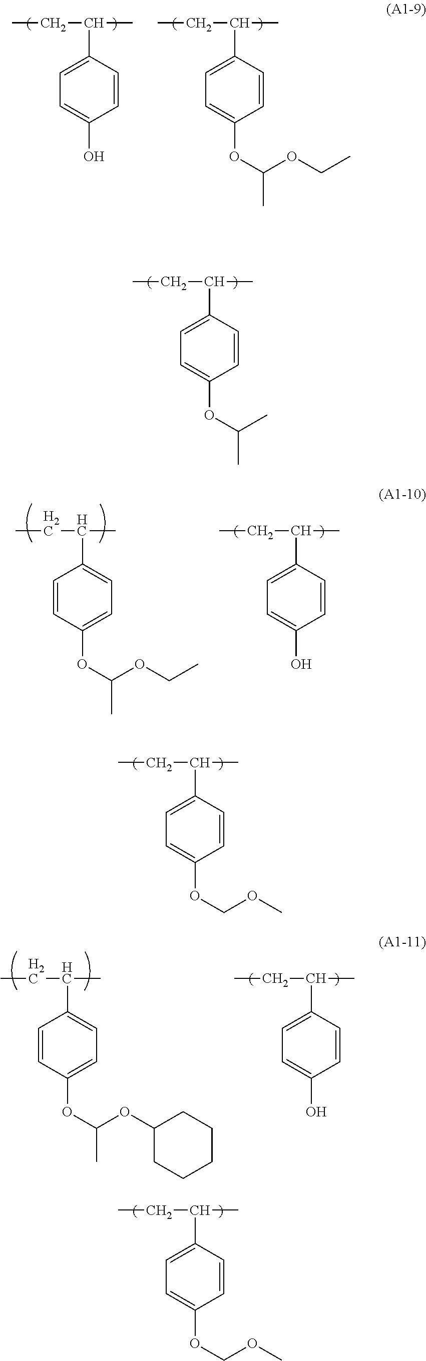

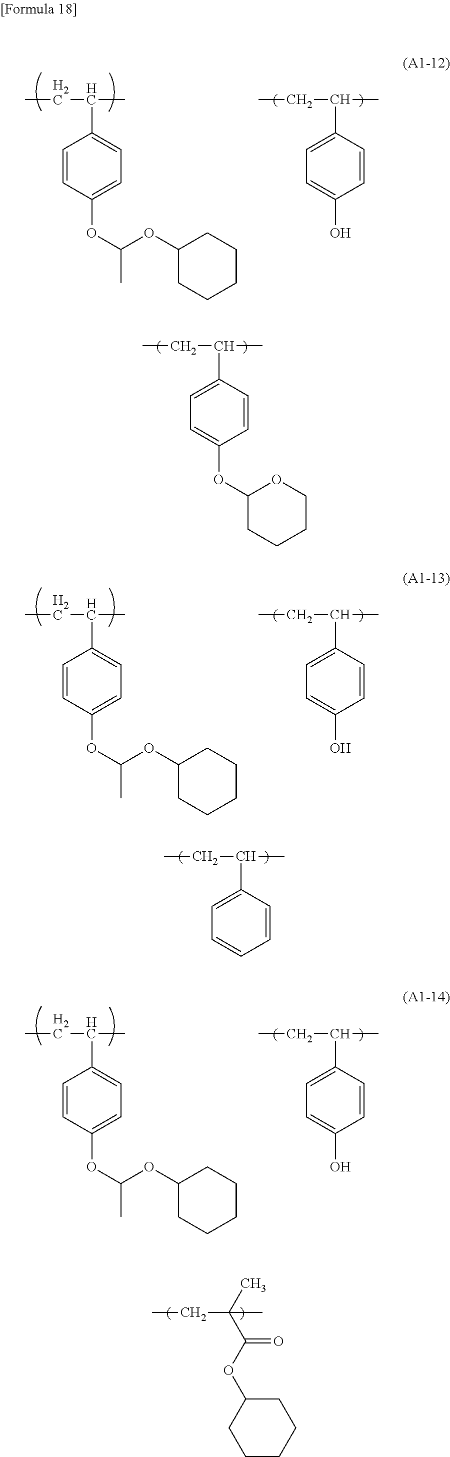

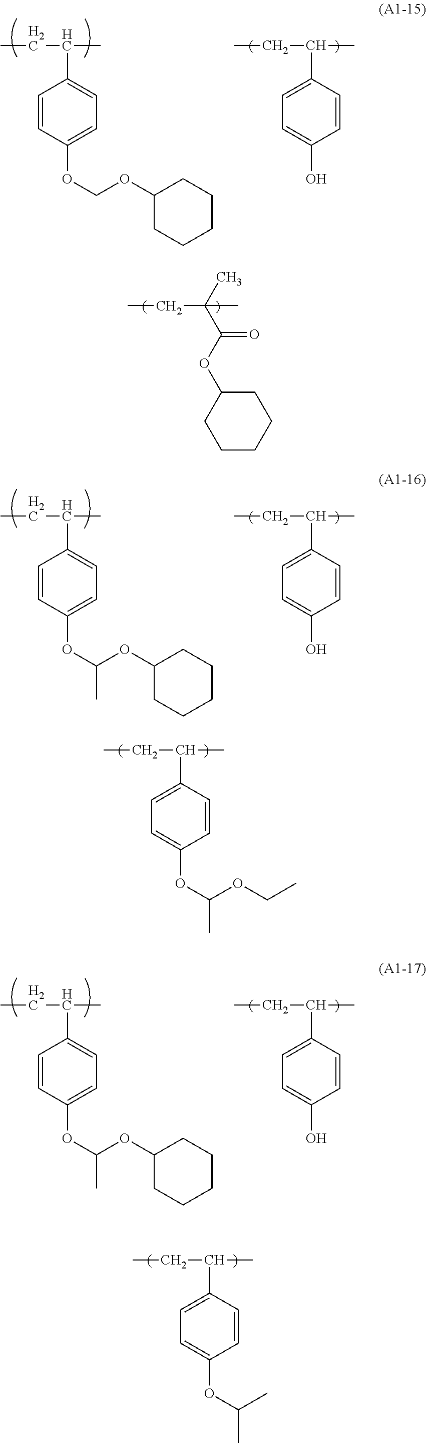

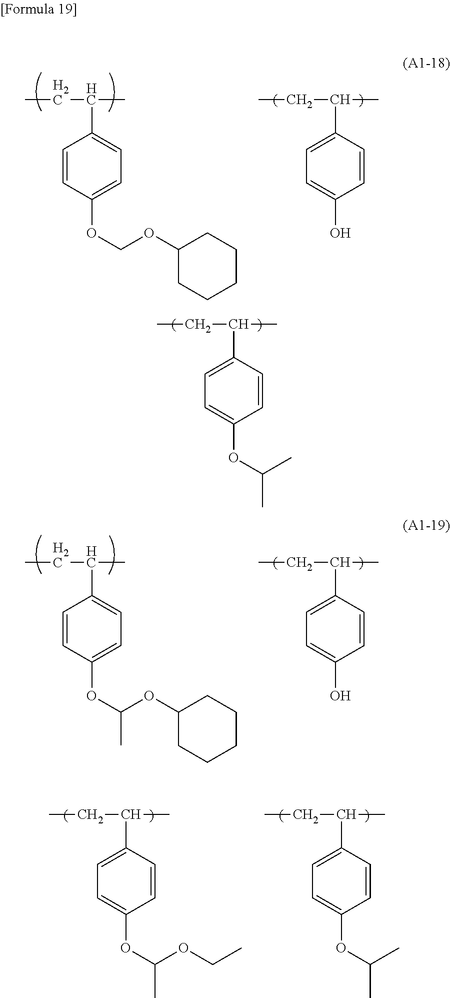

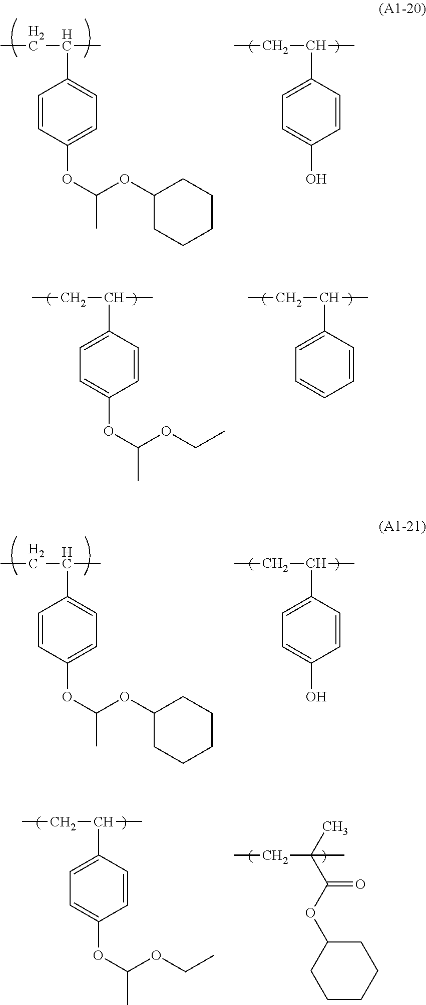

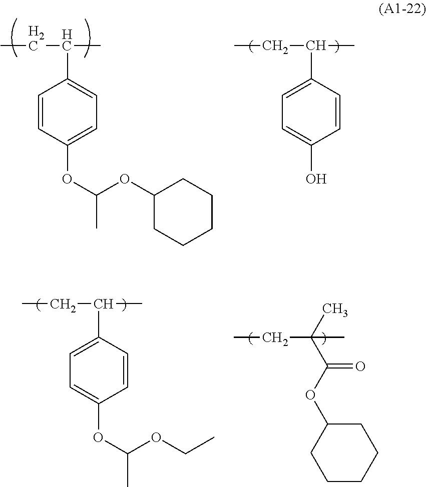

In the above structural formula, specific examples of the structural unit include structural units in which hydrogen atoms or methyl groups corresponding to R^{a4} and R^{a24} are replaced with hydrogen atoms, halogen atoms, alkyl groups having 1 to 6 carbon atoms, or haloalkyl groups having 1 to 6 carbon atoms.

Resin (A1) can be produced by polymerizing a monomer that leads to structural unit (a1) including the group represented by the above formula (1), a monomer that leads to structural unit (a2) as necessary, and other monomers that lead to structural units known in the art, by a polymerization method (e.g., a radical polymerization method).

Among resins (A1), the resin including structural unit (a1-1) and formula (a2-1) can be obtained, for example, by reacting a resin including structural unit (a2-1) with an acetal-based protecting group under acidic conditions to protect a part of the phenolic hydroxy group included in structural unit (a2-1). Examples of the acetal-based protecting group include alkyl vinyl ether, 3,4-dihydro-2H-pyran, or a group represented by formula (1′).

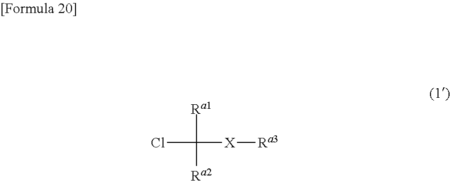

In formula (1′), all symbols have the same meaning as in formula (1).

The content ratio of each structural unit included in resin (A1) can be adjusted by the amount of the monomer used in the polymerization or the amount of the formula (1′) used.

The weight average molecular weight of resin (A1) is preferably 3,000 or more, more preferably 4,000 or more, and preferably 600,000 or less, more preferably 500,000 or less. The weight average molecular weight is determined by gel permeation chromatography analysis as a converted value based on standard polystyrene. Detailed analysis conditions for this analysis are described in the example of the present application. <Resin (A2)>

The resist composition of the present invention includes resin (A2) that includes a structural unit represented by formula (a3) as an alkali-soluble resin.

The alkali-soluble resin is a resin that has an acidic group (may be referred to as a hydrophilic group) and is soluble in an alkaline developer. Examples of the acidic group include a carboxy group, a sulfo group, and a hydroxy group (such as a phenolic hydroxyl group).

Examples of the alkali-soluble resins include a resin that has a residual film rate of 0% or more and 90% or less when developed with an alkaline developer under actual use conditions. The residual film rate is preferably 0% or more and 85% or less, and more preferably 0% or more and 80% or less. The residual film rate can be measured, for example, as follows. The resin is dissolved in an organic solvent, then filtering is performed using a filter as necessary, and then application is performed onto a substrate using a spin coater or the like, followed by heating to remove the organic solvent. The film thickness of the obtained organic film on the substrate is measured with a film thickness meter and developed with a 2.38% by mass alkaline aqueous solution, and the film thickness after development is measured again using the film thickness meter. For the measured values thus obtained, the film thickness after development is divided by the film thickness before development, allowing to provide the residual film rate. The development conditions are the actual use conditions. Examples of the development temperature include 5 to 60° C., and examples of the development time include 5 to 600 seconds. The alkaline developer includes various alkaline aqueous solutions used in this field, such as an aqueous solution of tetramethylammonium hydroxide or (2-hydroxyethyl)trimethylammonium hydroxide (commonly known as choline).

Resin (A2) is a resin including a structural unit represented by formula (a3), and is at least a resin obtained by polymerizing acrylic acid and an alkyl methacrylate, or a resin obtained by polymerizing methacrylic acid and an alkyl acrylate.

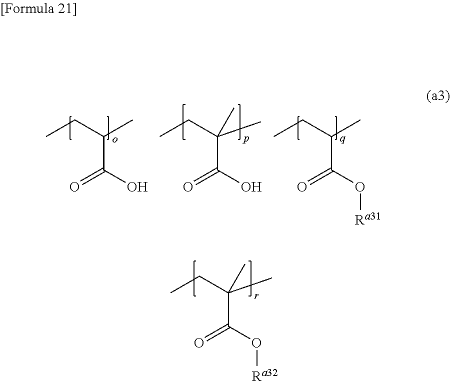

In formula (a3),
R^{a31} and R^{a32} each independently represent an alkyl group having 1 to 12 carbon atoms, and a methylene group included in the alkyl group is optionally replaced with an oxygen atom.

o, p, q, and r each independently represent 0 or a positive number less than 1, and at least one of o and p represents a positive number less than 1, and when o is 0, p and q each represent a positive number less than 1, and when p is 0, o and r each represent a positive number less than 1, and when q is 0, o and r each represent a positive number less than 1, and when r is 0, p and q each represent a positive number less than 1. With the proviso that o+p+q+r=1 is satisfied.

Examples of the alkyl group having 1 to 12 carbon atoms for R^{a31} and R^{a32} include a methyl group, an ethyl group, a propyl group, a butyl group, a pentyl group, a hexyl group, a heptyl group, an octyl group, a decyl group, and a dodecyl group.

It is preferable that R^{a31} and R^{a32} be each independently a methyl group or an ethyl group.

The total content ratio of structural units derived from acrylic acid and methacrylic acid in resin (A2) is preferably 5 mol % or more and 30 mol % or less with respect to all structural units constituting resin (A2), that is, it is preferable to satisfy 0.05<o+p <0.30.

In resin (A2), the total content ratio of structural units derived from an alkyl acrylate and an alkyl methacrylate is preferably 70 mol % or more and 95 mol % or less with respect to all structural units constituting resin (A2), that is, it is preferable that 0.70≤q+r≤0.95 be satisfied.

Resin (A2) preferably includes both a structural unit derived from an alkyl acrylate and a structural unit derived from an alkyl methacrylate, that is, q and r each preferably represent a positive number of 1 or less.

In resin (A2), the ratio between the total content ratio of a structural unit derived from acrylic acid and a structural unit derived from an alkyl acrylate, and the total content ratio of a structural unit derived from methacrylic acid and a structural unit derived from an alkyl methacrylate is preferably 30:70 to 70:30, that is, it is preferable to satisfy 0.4≤(p+r)/(0+q) ≤2.3.

Resin (A2) may include a structural unit conventionally known in the art other than the structural unit represented by formula (a3), as long as it is an alkali-soluble resin. With the proviso that the total content ratio of a structural unit represented by formula (a3) in resin (A2) is preferably 80 mol % or more, and more preferably 90 mol % or more, with respect to all structural units constituting resin (A2).

Resin (A2) can be produced by polymerizing the monomer that leads to a structural unit derived from acrylic acid, methacrylic acid, or an alkyl acrylate, and the monomer that leads to a structural unit derived from an alkyl methacrylate, using a polymerization method (e.g., radical polymerization method). The content ratio of each structural unit included in resin (A2) can be adjusted by the amount of each monomer used in the polymerization.

Examples of the monomer that leads to a structural unit derived from an alkyl acrylate include methyl acrylate, ethyl acrylate, propyl acrylate, tert-butyl acrylate, and hexyl acrylate.

Examples of the monomer that leads to a structural unit derived from alkyl methacrylate include methyl methacrylate, ethyl methacrylate, propyl methacrylate, tert-butyl methacrylate, and hexyl methacrylate.

Alkali-soluble resin (A2) may be used singly or in combination of two or more.

The resist composition of the present invention may include an alkali-soluble resin in addition to resin (A2), as necessary.

Examples of the alkali-soluble resin other than resin (A2) include novolak resin (A³), a resin including a structural unit derived from a hydroxystyrene, a resin including a structural unit derived from a (meth)acrylate ester, and a polyalkylene glycol.

### <Novolak Resin (A³)>

Novolak resin (A³) is a resin obtained by condensing a phenol compound and an aldehyde in the presence of a catalyst, and is, for example, a resin including a structural unit represented by following formula (a4). The resist composition of the present invention can include, as an alkali-soluble resin, novolak resin (A³) including a structural unit represented by (a4).

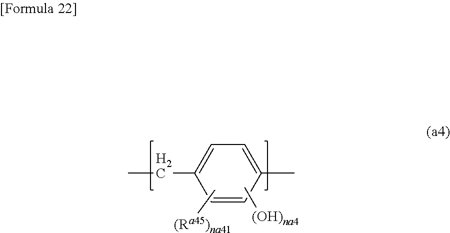

In formula (a4),
R^{a45} represents a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group.

na4 represents an integer of 1 to 4, and when na4 is 2 or more, the groups in parentheses are optionally the same or different from each other.

na41 represents a positive number of 0 to 3, and when na41 is 2 or more, a plurality of R^{a45}s are optionally the same or different from each other. With the proviso that 1<na4+na41<4 is satisfied.

Specific examples of the halogen atom, the alkyl group having 1 to 6 carbon atoms, the haloalkyl group having 1 to 6 carbon atoms, the alkoxy group having 1 to 6 carbon atoms, the alkoxyalkyl group having 2 to 12 carbon atoms, the alkoxyalkoxy group having 2 to 12 carbon atoms, the alkylcarbonyl group having 2 to 4 carbon atoms, and the alkylcarbonyloxy group having 2 to 4 carbon atoms of R^{a45} in formula (a4) include the specific examples same as R^{a5} in formula (a1-1).

In formula (a4), R^{a45} is preferably an alkyl group having 1 to 4 carbon atoms or an alkoxy group having 1 to 4 carbon atoms, more preferably an alkyl group having 1 to 3 carbon atoms or an alkoxy group having 1 to 3 carbon atoms, still more preferably a methyl group, an ethyl group, a methoxy group, or an ethoxy group, and even more preferably a methyl group or a methoxy group.

na4 is preferably 1 or 2, more preferably 1. na41 is preferably 0, 1, or 2, more preferably 0 or 1.

Novolak resin (A³) has a weight average molecular weight of preferably 3,000 or more, more preferably 4,000 or more, still more preferably 5,000 or more, and even more preferably 6,000 or more, and preferably 100,000 or less, more preferably 50,000 or less, still more preferably 10,000 or less, even more preferably 9,000 or less, and most preferably 8,000 or less. Setting to this range allows thinning and residue remaining after development to be effectively prevented. The weight average molecular weight is determined by gel permeation chromatography analysis as a converted value based on standard polystyrene. Detailed analysis conditions for this analysis are described in the Examples of the present application.

Novolak resin (A³) may be used singly or in combination of two or more.

The mass ratio between the content of resin (A1) in the resist composition and the total content of alkali-soluble resins (resin (A1): total alkali-soluble resins) is typically 20:80 to 80:20. In particular, the alkali-soluble resin is preferably composed of resin (A2) and resin (A³), and the mass ratio between the content of resin (A1) in the resist composition and the total content of resin (A2) and resin (A³) ((A1): (A2)+ (A³)) is typically 20:80 to 80:20, preferably 30:70 to 70:30, and more preferably 40:60 to 60:40. Setting to this range is preferable because it is possible to further improve the accuracy of the plated object.

The mass ratio between the content of resin (A2) in the resist composition and the content of alkali-soluble resins other than resin (A2) (resin (A2): total of alkali-soluble resins other than resin (A2)) is typically preferably 10:90 to 90:10, and more preferably 20:80 to 70:30.

In the resist composition of the present invention, the content of the resin components including resin (A1), resin (A2), and resin (A³) is preferably 80% by mass or more and 99.99% by mass or less, with respect to the total amount of solid contents of the resist composition. The content of resin (A1) is preferably 1% by mass or more and 98% by mass or less, more preferably 5% by mass or more and 90% by mass or less, and still more preferably 30% by mass or more and 80% by mass or less, with respect to the total amount of solid contents of the resist composition. The content of resin (A2) is preferably 1% by mass or more and 40% by mass or less, more preferably 18 by mass or more and 30% by mass or less, with respect to the total amount of solid contents in the resist composition. The content of resin (A³) is preferably 1% by mass or more and 50% by mass or less, more preferably 10% by mass or more and 40% by mass or less, with respect to the total amount of solid contents in the resist composition. The solid content and the content of each component included in the resist composition of the present invention can be measured by known analysis means, such as liquid chromatography or gas chromatography.

### <Acid Generator (B)>

Acid generator (B) is a compound that can decompose upon irradiation (exposure) with light to generate an acid. The generated acid can eliminate a leaving group included in the acid labile group of resin (A1), converting the acid labile group into a hydrophilic group (e.g., a carboxy group, a hydroxy group (phenolic hydroxyl group or the like)). That is, exposing a resist composition including resin (A1) to light allows the resist to be made soluble in a developer (alkaline aqueous solution).

Acid generator (B) may be either a nonionic type or an ionic type.

Examples of the non-ionic acid generator include: an organic halide, sulfonate esters (e.g., 2-nitrobenzyl ester, aromatic sulfonate, oxime sulfonate, N-sulfonyloxyimide, sulfonyloxyketone, and diazonaphthoquinone 4-sulfonate); and sulfones (e.g., disulfone, ketosulfone, and sulfonyldiazomethane). Representative examples of the ionic acid generator include an onium salt including an onium cation (e.g., diazonium salt, phosphonium salt, sulfonium salt, and iodonium salt). Examples of the anion of the onium salt include a sulfonate anion, a sulfonylimide anion, and a sulfonylmethide anion.

As acid generator (B), there can be used the compounds that generate an acid when exposed to radiation, such as those described in Japanese Patent Laid-Open No. 63-26653, Japanese Patent Laid-Open No. 55-164824, Japanese Patent Laid-Open No. 62-69263, Japanese Patent Laid-Open No. 63-146038, Japanese Patent Laid-Open No. 63-163452, Japanese Patent Laid-Open No. 62-153853, Japanese Patent Laid-Open No. 63-146029, U.S. Pat. Nos. 3,779,778, 3,849,137, German Patent No. 3914407, and European Patent No. 126, 712. In addition, the compound produced by a known method may be used. Acid generator (B) may be used singly or in combination of two or more.

As the nonionic acid generator, a compound having a group represented by formula (B¹) (* represents a bond) is preferable.

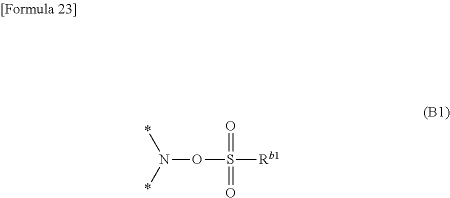

In formula (B¹),
R^{b1} represents a hydrocarbon group having 1 to 18 carbon atoms and optionally having a fluorine atom, and the methylene group included in the hydrocarbon group having 1 to 18 carbon atoms is optionally replaced with an oxygen atom or a carbonyl group.

The nitrogen atom may have a double bond.

The hydrocarbon group of Rbl having 1 to 18 carbon atoms and optionally having a fluorine atom includes a linear or branched chain hydrocarbon group having 1 to 18 carbon atoms, an alicyclic hydrocarbon group having 3 to 18 carbon atoms, an aromatic hydrocarbon group having 6 to 18 carbon atoms, and a group having 4 to 18 carbon atoms, being combinations of these groups.

The linear or branched chain hydrocarbon group having 1 to 18 carbon atoms is preferably an alkyl group having 1 to 18 carbon atoms, and examples thereof include a methyl group, an ethyl group, a propyl group, a butyl group, a pentyl group, a hexyl group, a heptyl group, an octyl group, a nonyl group, and a decyl group. Among these, linear ones are preferable.

Examples of the alicyclic hydrocarbon group having 3 to 18 carbon atoms include a cyclopropyl group, a cyclobutyl group, a cyclopentyl group, a cyclohexyl group, a cycloheptyl group, a cyclooctyl group, and an adamantyl group.

The aromatic hydrocarbon group having 6 to 18 carbon atoms is preferably an aryl group having 6 to 18 carbon atoms, and examples thereof include an aryl group such as a phenyl group, a naphthyl group, an anthryl group, a biphenyl group, and a phenanthryl group.

Among the groups having 4 to 18 carbon atoms formed by combining the above groups, examples of the group (group having 4 to 18 carbon atoms) in which a chain hydrocarbon group and an alicyclic hydrocarbon group are combined include a methylcyclohexyl group, a dimethylcyclohexyl group, a methylnorbornyl group, an isobornyl group, a 2-alkyladamantan-2-yl group, and a 1-(adamantan-1-yl)alkane-1-yl group.

Examples of the group in which a chain hydrocarbon group and an aromatic hydrocarbon group are combined (group having 7 to 18 carbon atoms) include an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Examples of the group in which an alicyclic hydrocarbon group and an aromatic hydrocarbon group are combined (group having 9 to 18 carbon atoms) include an aromatic hydrocarbon group having an alicyclic hydrocarbon group and an alicyclic hydrocarbon group having an aromatic hydrocarbon group, and specific examples thereof include a p-cyclohexylphenyl group, a p-adamantylphenyl group, and a phenylcyclohexyl group.

Among the hydrocarbon groups having 1 to 18 carbon atoms represented by R^{b1}, an alkyl group having 1 to 10 carbon atoms or an aromatic hydrocarbon group having 6 to 10 carbon atoms is preferable, an alkyl group having 1 to 8 carbon atoms is more preferable, and an alkyl group having 1 to 4 carbon atoms is still more preferable.

Examples of the group in which a methylene group included in an alicyclic hydrocarbon group having 3 to 18 carbon atoms in Rbl is replaced with an oxygen atom or a carbonyl group include groups represented by formulas (Y1) to (Y12). Preferably, it is a group represented by formulas (Y7) to (Y9), and more preferably, it is a group represented by formula (Y9).

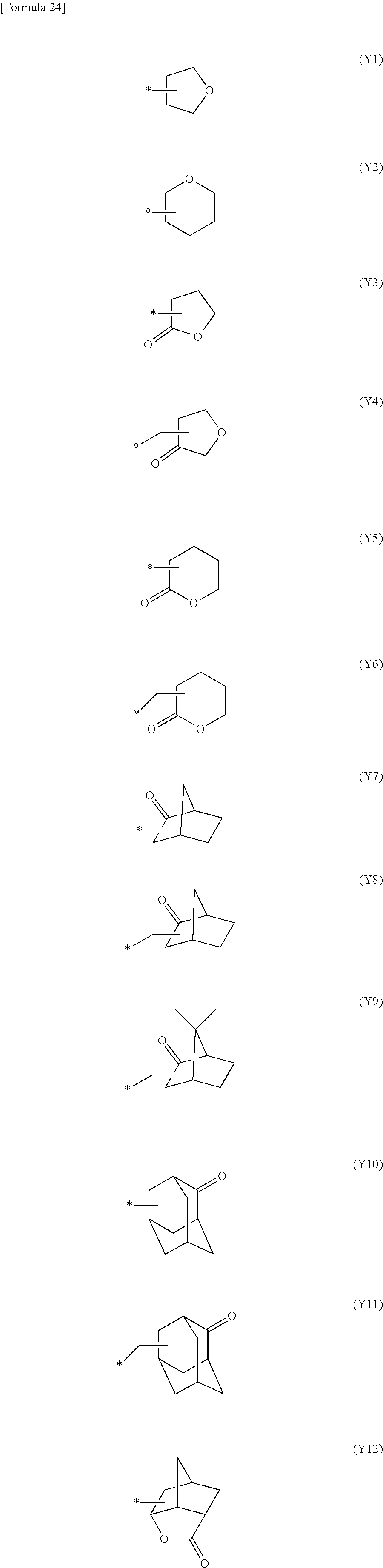

The hydrocarbon group having 1 to 18 carbon atoms and having a fluorine atom is a group in which one or more hydrogen atoms included in the above-described hydrocarbon group having 1 to 18 carbon atoms are replaced with a fluorine atom, and specific examples thereof include a fluoroalkyl group such as a fluoromethyl group, a fluoroethyl group, a fluoropropyl group, a fluorobutyl group, a fluoropentyl group, a fluorohexyl group, a fluoroheptyl group, a fluorooctyl group, a fluorononyl group, and a fluorodecyl group; a fluorocycloalkyl group such as a fluorocyclopropyl group, a fluorocyclobutyl group, a fluorocyclopentyl group, a fluorocyclohexyl group, a fluorocycloheptyl group, a fluorocyclooctyl group, and a fluoroadamantyl group; and a fluoroaryl group such as a fluorophenyl group, a fluoronaphthyl group, and a fluoroanthryl group.

The hydrocarbon group having 1 to 18 carbon atoms and having a fluorine atom is preferably an alkyl group having 1 to 10 carbon atoms and having a fluorine atom, or an aromatic hydrocarbon group having 6 to 10 carbon atoms and having a fluorine atom, more preferably a perfluoroalkyl group having 1 to 8 carbon atoms, and still more preferably a perfluoroalkyl group having 1 to 4 carbon atoms.

Examples of the compound having a group represented by formula (B¹) include compounds represented by formulas (b1) to (b4). Preferable are compounds represented by formulas (b1), (b2), and (b4), and more preferably compounds represented by formulas (b1) and (b4).

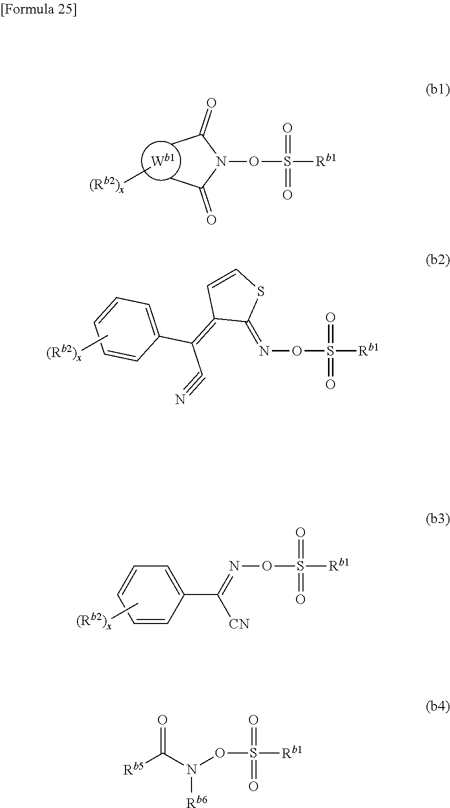

In formulas (b1) to (b4), R^{b1} has the same meaning as above.

R^{b2} each independently represents an alkyl group having 1 to 8 carbon atoms or an alkoxy group having 1 to 8 carbon atoms.

Ring Wbl represents an aromatic hydrocarbon ring having 6 to 14 carbon atoms or an aromatic heterocycle having 6 to 14 carbon atoms.

x represents an integer of 0 to 6 (and further 0 to 5). When x is 2 or more, a plurality of R^{b2}s are optionally the same or different from each other. R^{b5} represents an aromatic hydrocarbon group having 6 to 18 carbon atoms or an aromatic heterocyclic group having 6 to 14 carbon atoms, optionally having a substituent.

R^{b6} represents a hydrogen atom or an alkyl group having 1 to 8 carbon atoms.

Examples of the alkyl group having 1 to 8 carbon atoms include a methyl group, an ethyl group, a propyl group, a butyl group, and a pentyl group, preferably the methyl group.

Examples of the alkoxy group having 1 to 8 carbon atoms include a methoxy group, an ethoxy group, a propoxy group, a butoxy group, and a pentyloxy group, preferably the methoxy group.

Examples of the aromatic hydrocarbon ring having 6 to 14 carbon atoms include a benzene ring, a naphthalene ring, and an anthracene ring.

Examples of the aromatic heterocycle having 6 to 14 carbon atoms include a ring having 6 to 14 atoms constituting the ring, preferably the following rings.

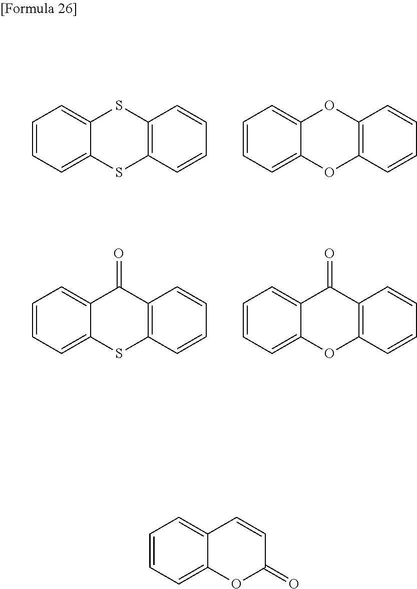

Ring W^{b1} is preferably a naphthalene ring.

Examples of the aromatic hydrocarbon group having 6 to 18 carbon atoms include a phenyl group, a naphthyl group, an anthryl group, a biphenyl group, and a phenanthryl group.

Examples of the aromatic heterocyclic group having 6 to 14 carbon atoms include a group obtained by removing a hydrogen atom from the above-described aromatic heterocycle having 6 to 14 carbon atoms.

The compound represented by formula (b1) is preferably a compound represented by any one of formulas (b5) to (b8), more preferably a compound represented by formula (b5).

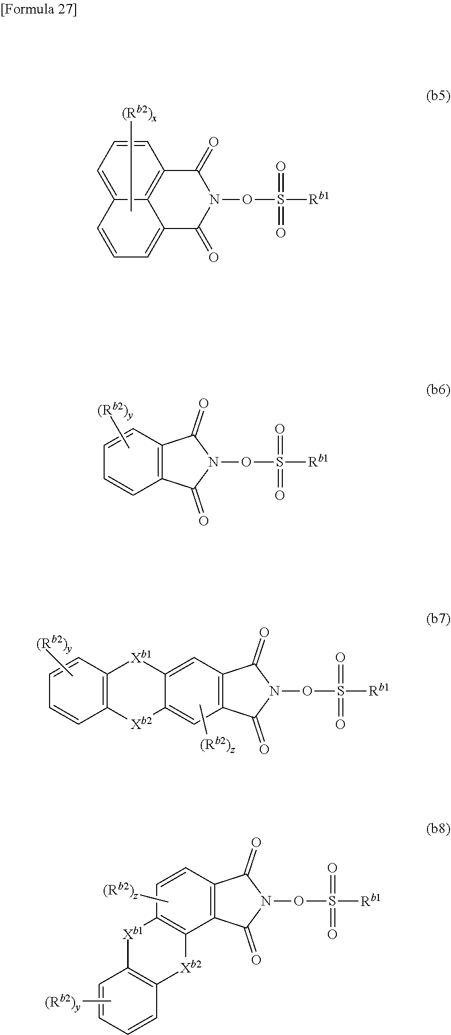

In formulas (b5) to (b8),
R^{b1}, R^{b2}, and x have the same meanings as above.
y represents an integer of 0 to 4, and z represents an integer of 0 to 2.
X^{b1} and X^{b2} each independently represent —O—, —S—, or —CO—.

Examples of the compound represented by formula (b1) include compounds represented by formulas (b1-1) to (b1-17). The compounds represented by formulas (b1-6) to (b1-10) and formulas (b1-13) to (b1-17) are preferable.

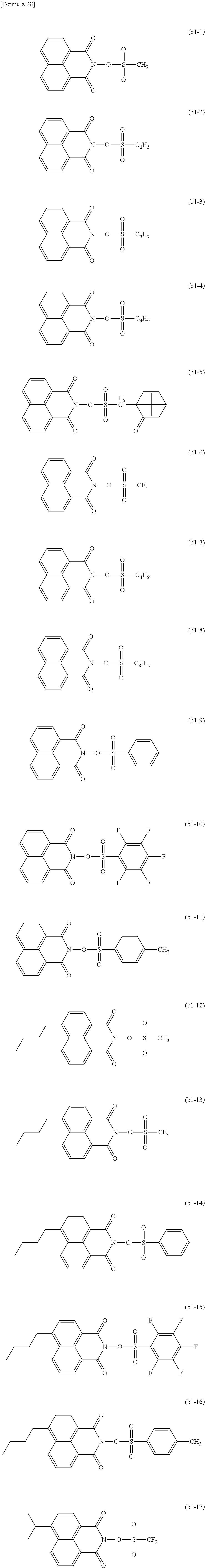

Examples of the compound represented by formula (b2) include a compound represented by the following formula.

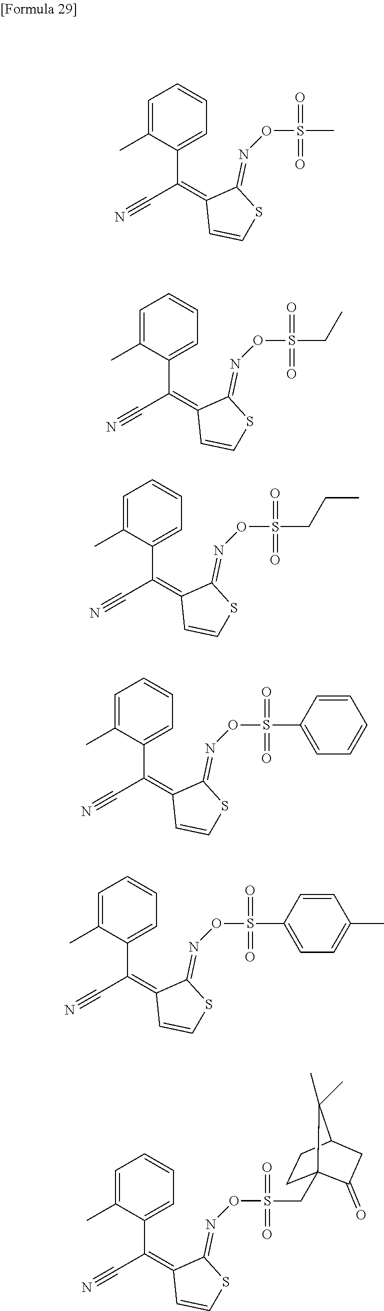

Examples of the compound represented by formula (b3) include a compound represented by the following formulas.

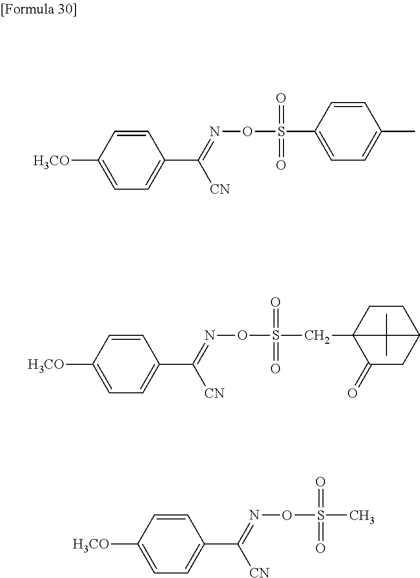 [SMILES: COc1ccc(/C(C#N)=N/OS(=O)(=O)c2ccc(C)cc2)cc1 ; COc1ccc(/C(C#N)=N/OS(=O)(=O)CC23CCC(CC2=O)C3(C)C)cc1 ; COc1ccc(/C(C#N)=N/OS(C)(=O)=O)cc1]

Examples of the compound represented by formula (b4) include a compound represented by the following formula.

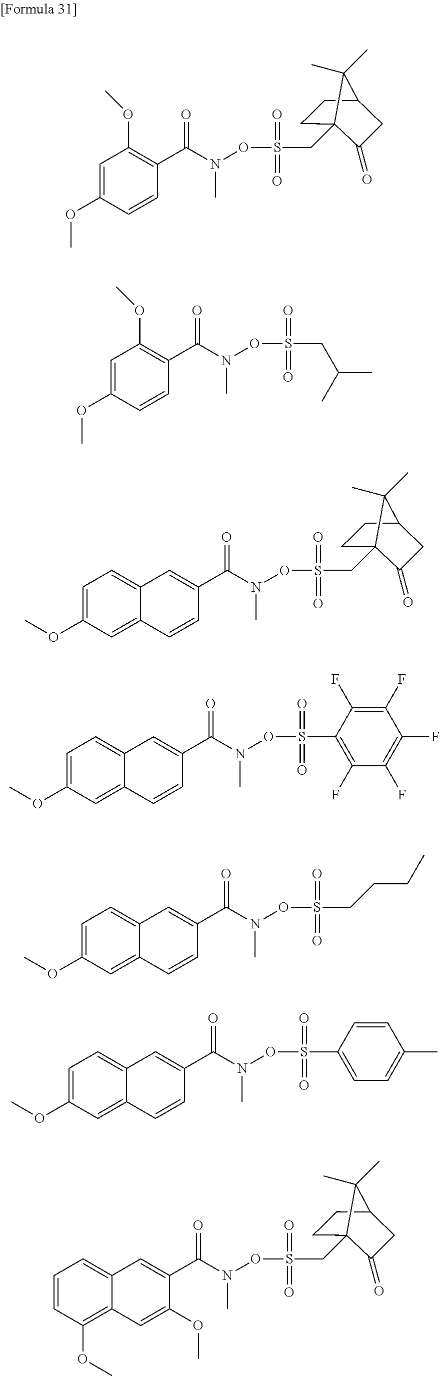

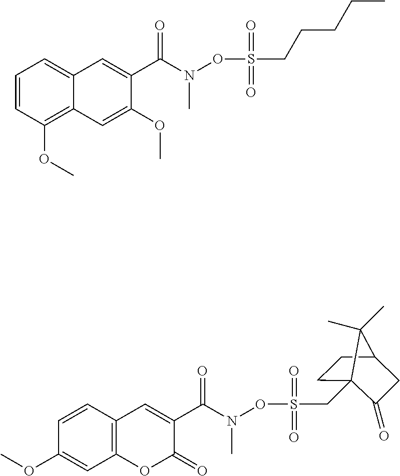

The ionic acid generator is preferably a compound represented by formula (b9) or formula (b10).

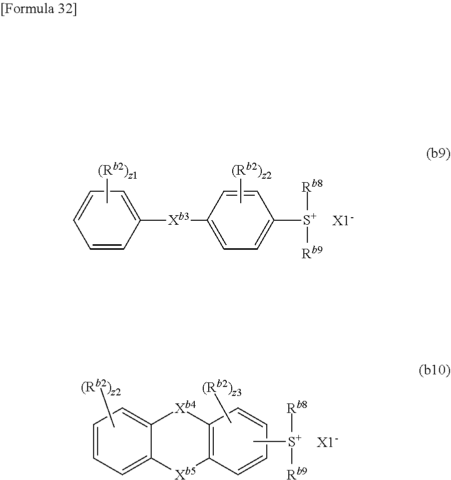

In formula (b9) and formula (b10),
R^{b2} has the same meaning as above.
z1 represents an integer of 0 to 5.
z2 represents an integer of 0 to 4.
z3 represents an integer of 0 to 3.
x^{b3} represents an oxygen atom or a sulfur atom.

X^{b4} and X^{b5} each independently represent an oxygen atom, a sulfur atom, or —CO—.

R^{b8} and R^{b9} each independently represent an alkyl group having 1 to 10 carbon atoms or an aromatic hydrocarbon group having 6 to 12 carbon atoms.

X1⁻ represents an organic anion.

Examples of the alkyl group having 1 to 10 carbon atoms include a methyl group, an ethyl group, a propyl group, a butyl group, a pentyl group, a hexyl group, a heptyl group, and an octyl group.

Examples of the aromatic hydrocarbon group having 6 to 12 carbon atoms include an aryl group such as a phenyl group, a naphthyl group, an anthryl group, a biphenyl group, and a phenanthryl group. The aromatic hydrocarbon group may further have a substituent, and examples of the aromatic hydrocarbon group having a substituent include an aromatic hydrocarbon group having an aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2,6-diethylphenyl group, and a 2-methyl-6-ethylphenyl group.

Each of R^{b8} and R^{b9} is preferably an aromatic hydrocarbon group having 6 to 12 carbon atoms, more preferably a phenyl group.

Examples of the organic anion represented by X1-include a sulfonate anion, a bis(alkylsulfonyl)amide anion, and a tris (alkylsulfonyl) methide anion, preferably a sulfonate anion, and more preferably a sulfonate anion represented by formula (b11).

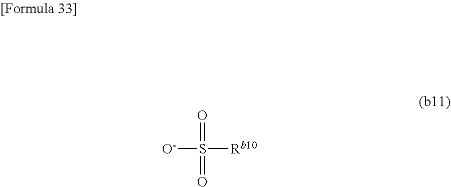

In formula (b11),
R^{b10} represents a hydrocarbon group having 1 to 18 carbon atoms optionally having a fluorine atom, and the methylene group included in the hydrocarbon group is optionally replaced with an oxygen atom or a carbonyl group.

Examples of R^{b10} include the same group as Rbl in formula (B¹).

Examples of the compound represented by formula (b9) include the following compound.

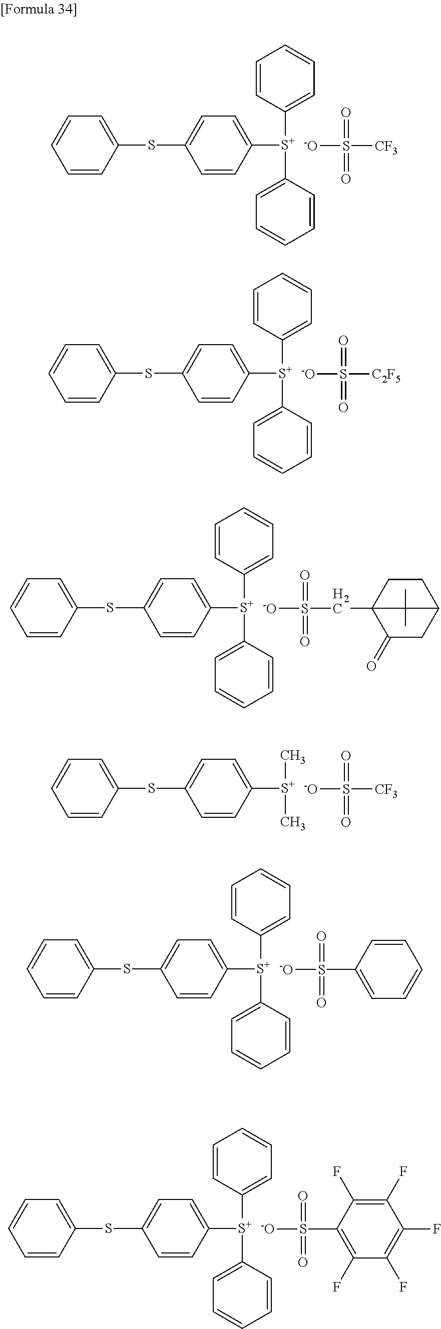

Examples of the compound represented by formula (b10) include the following compound.

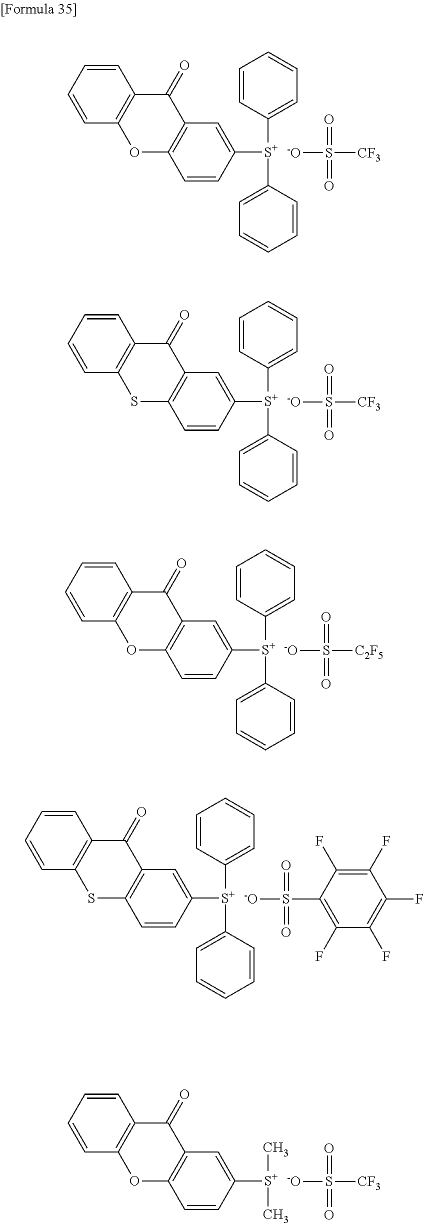

In the resist composition of the present invention, the content ratio of the acid generator is preferably 0.1 parts by mass or more and 40 parts by mass or less, more preferably 0.5 parts by mass or more and 30 parts by mass or less, still more preferably 0.7 parts by mass or more and 20 parts by mass or less, and even more preferably 0.9 parts by mass or more and 5 parts by mass or less, with respect to 100 parts by mass of resin (A1). The resist composition of the present invention may contain acid generator (B) singly or in combinations.

### <Solvent (D)>

The content ratio of solvent (D) in the resist composition is typically 45% by mass or more, preferably 50% by mass or more, more preferably 558 by mass or more, and typically 99.9% by mass or less, preferably 99% by mass or less, more preferably 90% by mass or less. The content ratio of solvent (D) can be measured by known analysis means such as liquid chromatography or gas chromatography.

Examples of solvent (D) include: glycol ether esters such as ethyl cellosolve acetate, methyl cellosolve acetate, and propylene glycol monomethyl ether acetate; glycol ethers such as propylene glycol monomethyl ether; esters such as ethyl lactate, butyl acetate, amyl acetate, and ethyl pyruvate; ketones such as acetone, methyl isobutyl ketone, 2-heptanone, and cyclohexanone; and cyclic esters such as γ-butyrolactone. Solvent (D) may be contained singly or in combination of two or more.

### <Quencher (C)>

The resist composition of the present invention may contain quencher (C).

Quencher (C) is a compound that has the effect of capturing the acid generated from the acid generator upon exposure. Examples of quencher (C) include a basic nitrogen-containing organic compound. The basic nitrogen-containing organic compound includes an amine and an ammonium salt. The amine includes an aliphatic amine (including a primary amine, a secondary amine, and a tertiary amine), an aromatic amine, and the like.

Examples of the amine include a compound represented by formula (C1) or formula (C2).

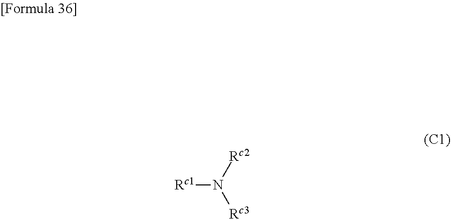

In formula (C1), Rc1, Rc2, and Rc3 each independently represent a hydrogen atom, an alkyl group having 1 to 6 carbon atoms, an alicyclic hydrocarbon group having 3 to 10 carbon atoms, or an aromatic hydrocarbon group having 6 to 10 carbon atoms, and the alkyl group having 1 to 6 carbon atoms and the alicyclic hydrocarbon group having 3 to 10 carbon atoms may have at least one group selected from the group consisting of a hydroxy group, an amino group, and an alkoxy group having 1 to 6 carbon atoms, and the aromatic hydrocarbon group having 6 to 10 carbon atoms may have at least one group selected from the group consisting of an alkyl group having 1 to 6 carbon atoms, an alkoxy group having 1 to 6 carbon atoms, and an alicyclic hydrocarbon group having 3 to 10 carbon atoms.

Examples of the compound represented by formula (C1) include 1-naphthylamine, 2-naphthylamine, aniline, diisopropylaniline, 2-, 3- or 4-methylaniline, 4-nitroaniline, N-methylaniline, N, N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, dibutylmethylamine, methyldipentylamine, dihexylmethylamine, dicyclohexylmethylamine, diheptylmethylamine, methyldioctylamine, methyldinonylamine, didecylmethylamine, ethyldibutylamine, ethyldipentylamine, ethyldihexylamine, ethyldiheptylamine, ethyldioctylamine, ethyldinonylamine, ethyldidecylamine, tris [2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane, and 4,4′-diamino-3,3′-diethyldiphenylmethane. Diisopropylaniline is preferable, and 2,6-diisopropylaniline is particularly preferable.

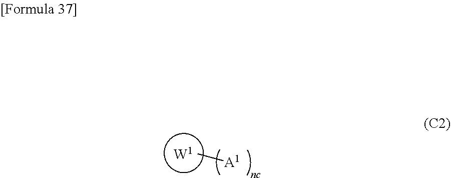

In formula (C2),
Ring W1 represents a heterocycle including a nitrogen atom as an atom constituting the ring, or a benzene ring having a substituted or unsubstituted amino group, and the heterocycle and the benzene ring may have at least one selected from the group consisting of a hydroxyl group and an alkyl group having 1 to 4 carbon atoms.

A¹ represents a phenyl group or a naphthyl group. nc represents 2 or 3, and a plurality of A¹s are optionally the same or different from each other.

The substituted or unsubstituted amino group is represented by —N(R⁴)(R⁵), where R⁴ and R⁵ each independently represent a hydrogen atom, a chain hydrocarbon group having 1 to 10 carbon atoms, an alicyclic hydrocarbon group having 3 to 10 carbon atoms, or an aromatic hydrocarbon group having 6 to 14 carbon atoms.

Examples of the chain hydrocarbon group having 1 to 10 carbon atoms include an alkyl group having 1 to 10 carbon atoms, such as a methyl group, an ethyl group, a propyl group, a butyl group, a pentyl group, a hexyl group, a heptyl group, and an octyl group.

Examples of the alicyclic hydrocarbon group having 3 to 10 carbon atoms include a monocyclic alicyclic hydrocarbon group such as a cycloalkyl group, such as a cyclopentyl group, a cyclohexyl group, a cycloheptyl group, and a cyclooctyl group; and a polycyclic alicyclic hydrocarbon group, such as a decahydronaphthyl group, an adamantly group, and a norbornyl group.

Examples of the aromatic hydrocarbon group having 6 to 14 carbon atoms include an aryl group, such as a phenyl group, a naphthyl group, an anthryl group, a biphenyl group, and a phenanthryl group. The aromatic hydrocarbon group may further have a substituent, and examples of the substituent include an aryloxy group having 6 to 10 carbon atoms.

A heterocycle including a nitrogen atom as an atom constituting the ring may be an aromatic ring or a non-aromatic ring, and may have other heteroatoms (e.g., oxygen atoms and sulfur atoms) in addition to the nitrogen atom. The number of nitrogen atoms in the heterocycle is, for example, 1 to 3. Examples of the heterocycle include a ring represented by any of formulas (Y13) to (Y28). One of the hydrogen atoms in the ring is removed to become a bond to A¹.

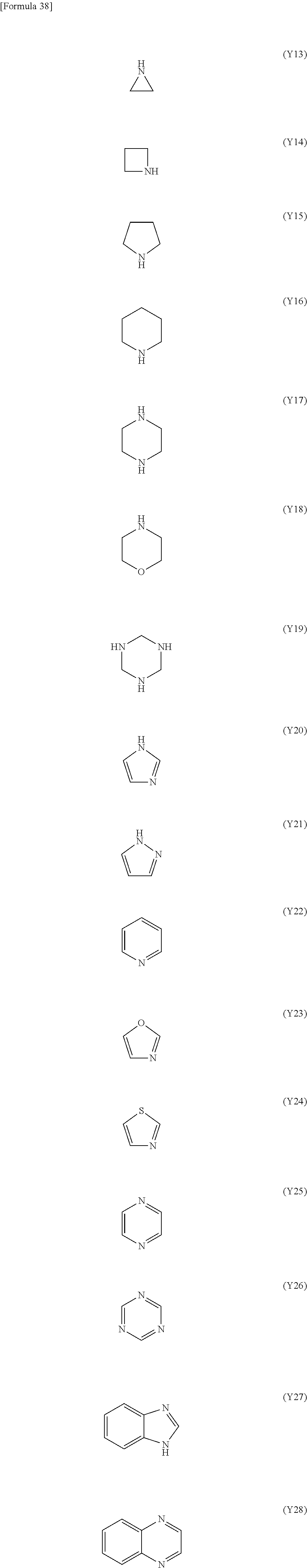

Ring W1 is preferably a heterocycle including a nitrogen atom as an atom constituting the ring, more preferably a 5- or 6-membered aromatic heterocycle including a nitrogen atom as an atom constituting the ring, and further preferably a ring represented by any of formulas (Y20) to (Y25).

Examples of the compound represented by formula (C2) include compounds represented by any of formulas (C2-1) to (C2-11). A compound represented by any of formulas (C2-2) to (C2-8) is preferable.

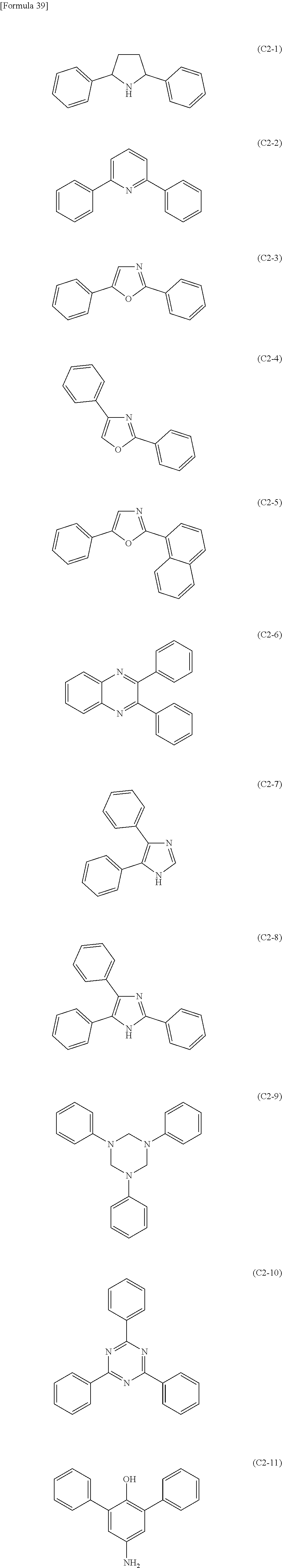

The content ratio of quencher (C) in the solid content of the resist composition is preferably 0.0001 to 5% by mass, more preferably 0.0001 to 4% by mass, still more preferably 0.001 to 3% by mass, even more preferably 0.01 to 1.0% by mass, and most preferably 0.05 to 0.7% by mass.

### <Adhesion Improver (E)>

Adhesion improver (E) is not particularly limited as long as it can prevent corrosion and/or improve adhesion to metals and the like used in substrates, wiring, or the like. Preventing metal corrosion exhibits an anti-rust effect. In addition to these effects, it is possible to improve adhesion between the substrate, metal, or the like and the resist composition.

Examples of adhesion improver (E) include a sulfur-containing compound, an aromatic hydroxy compound, a benzotriazole-based compound, a triazine-based compound, and a silicon-containing compound. These can be used singly or in combination of two or more.

The sulfur-containing compound may be, for example, a compound having a sulfide bond and/or a mercapto group. The sulfur-containing compound may be a chain compound or a compound having a cyclic structure.

Examples of the chain compound include dithiodiglycerol [S(CH₂CH(OH)CH₂(OH))₂], bis(2,3-dihydroxypropylthio)ethylene [CH₂CH₂(SCH₂CH(OH)CH₂(OH))_{2], 3}-(2, 3-dihydroxypropylthio)-2-methyl-propylsodium sulfonate [CH₂(OH)CH(OH)CH₂SCH₂CH(CH₃) CH₂SO₃Na], 1-thioglycerol [HSCH₂CH(OH)CH₂(OH)], 3-mercapto-1-propanesodium sulfonate [HSCH₂CH₂CH₂SO₃Na], 2-mercaptoethanol [HSCH₂CH₂(OH)], thioglycolic acid [HSCH₂CO₂H], and 3-mercapto-1-propanol [HSCH₂CH₂CH₂].

The sulfur-containing compound is preferably a compound having a sulfide bond and a mercapto group, and more preferably a heterocyclic compound having a sulfide bond and a mercapto group. The heterocyclic compound is more preferably a heterocyclic compound having a sulfide bond in the ring structure. The number of sulfide bonds and mercapto groups in the sulfur-containing compound is not particularly limited, and each may be 1 or more.

The heterocycle in the heterocyclic compound may be either a monocycle or a polycycle, and may be either a saturated or unsaturated ring. The heterocycle preferably further includes a heteroatom other than a sulfur atom. Examples of the heteroatom include an oxygen atom and a nitrogen atom, and preferably a nitrogen atom.

The heterocycle is preferably a heterocycle having 2 to 12 carbon atoms, and more preferably a heterocycle having 2 to 6 carbon atoms. The heterocycle is preferably a monocycle. The heterocycle is preferably an unsaturated ring. The heterocycle is preferably an unsaturated and monocycle.

Examples of the heterocycle include the following heterocycle.

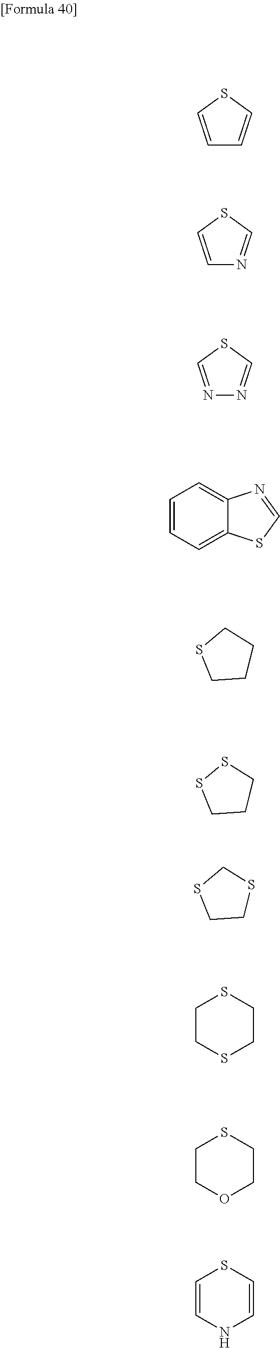

The sulfur-containing compound may be a polymer. This polymer preferably includes a structure having a sulfide bond and a mercapto group in the side chain thereof. The structure having a sulfide bond and a mercapto group (hereinafter may be referred to as unit (1)) is preferably bonded to the main chain via a linking group such as an amide bond, an ether bond, a thioether bond, or an ester bond.

The polymer may be a homopolymer or a copolymer.

When the polymer is a copolymer, the above-described structural unit (a1) having an acid labile group, structural unit (a2) not having an acid labile group, and the like may be included.

The weight average molecular weight of the homopolymer and copolymer is typically 3000 or more, preferably 5000 or more, and typically 100,000 or less, preferably 50,000 or less. The weight average molecular weight is determined by gel permeation chromatography analysis as a converted value based on standard polystyrene.

When the sulfur-containing compound is a polymer, the content of the structural unit having a sulfide bond and a mercapto group is typically 0.1 to 50 mol %, preferably 0.5 to 30 mol %, and more preferably 1 to 20 mol %, with respect to the total structural units of the polymer of the sulfur-containing compound.

The sulfur-containing compound is preferably, for example, a compound represented by formula (IA) or a polymer having a structural unit represented by formula (IB).

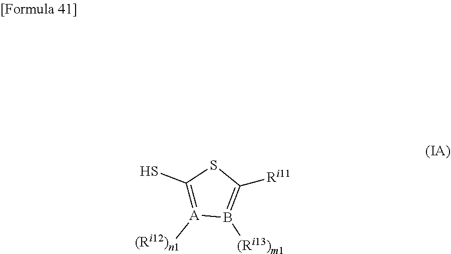

In formula (IA),
Rill represents a hydrogen atom, a chain hydrocarbon group having 1 to 10 carbon atoms, an aromatic hydrocarbon group having 6 to 14 carbon atoms, an alicyclic hydrocarbon group having 3 to 18 carbon atoms, a group represented by —SR¹¹, or a group represented by —NR¹²R¹³.

R¹¹, R¹², and R¹³ each independently represent a hydrogen atom, a chain hydrocarbon group having 1 to 10 carbon atoms, an aromatic hydrocarbon group having 6 to 14 carbon atoms, an alicyclic hydrocarbon group having 3 to 10 carbon atoms, or an acyl group having 2 to 12 carbon atoms, and these chain hydrocarbon groups, aromatic hydrocarbon groups, alicyclic hydrocarbon groups, and acyl groups may have a hydroxy group.

R¹¹² and R¹¹³ each independently represent a hydrogen atom, a chain hydrocarbon group having 1 to 10 carbon atoms, an aromatic hydrocarbon group having 6 to 14 carbon atoms, or an alicyclic hydrocarbon group having 3 to 18 carbon atoms. A and B each independently represent a nitrogen atom or a carbon atom.

n1 and m1 each independently represent 0 or 1.

However, when A is a nitrogen atom, n1 represents 0, and when A is a carbon atom, n1 represents 1, and when B is a nitrogen atom, m1 represents 0, and when B is a carbon atom, m1 represents 1.

Examples of the chain hydrocarbon group having 1 to 10 carbon atoms include an alkyl group having 1 to 10 carbon atoms, such as a methyl group, an ethyl group, a propyl group, a butyl group, a pentyl group, a hexyl group, a heptyl group, and an octyl group.

Examples of the aromatic hydrocarbon group having 6 to 14 carbon atoms include an aryl group having 6 to 14 carbon atoms, such as a phenyl group, a naphthyl group, an anthryl group, a biphenyl group, and a phenanthryl group. The aromatic hydrocarbon group may further have a substituent. Examples of the aromatic hydrocarbon group having a substituent include an aromatic hydrocarbon group having an aralkyl group and an alkyl group, and specific examples include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2, 6-diethylphenyl group, and a 2-methyl-6-ethylphenyl group.

Examples of the alicyclic hydrocarbon group having 3 to 18 carbon atoms include monocyclic alicyclic hydrocarbon groups such as cycloalkyl groups such as a cyclopentyl group, a cyclohexyl group, a cycloheptyl group, and a cyclooctyl group, and polycyclic alicyclic hydrocarbon groups such as a decahydronaphthyl group, an adamantyl group, and a norbornyl group.

R¹¹ is preferably a chain hydrocarbon group having 1 to 10 carbon atoms or an acyl group having 2 to 12 carbon atoms, and R¹² and R₁₃ are each preferably a hydrogen atom, a chain hydrocarbon group having 1 to 10 carbon atoms, an aromatic hydrocarbon group having 6 to 14 carbon atoms, or an acyl group having 2 to 12 carbon atoms.

Examples of the acyl group having 2 to 12 carbon atoms include an acetyl group, a propionyl group, a butyryl group, a valeryl group, a hexylcarbonyl group, a heptylcarbonyl group, an octylcarbonyl group, a decylcarbonyl group, a dodecylcarbonyl group, and a benzoyl group.

Rill is more preferably a hydrogen atom or a mercapto group.

R¹¹² and R¹¹³ are each preferably, independently, a hydrogen atom or an alkyl group having 1 to 4 carbon atoms, and more preferably a hydrogen atom.

At least one of A and B is preferably a nitrogen atom, and both are more preferably nitrogen atoms.

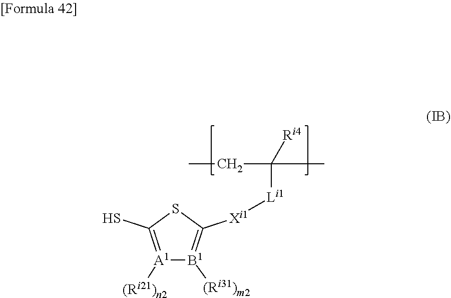

In formula (IB), R¹²¹ and R¹³¹ each independently represent a hydrogen atom, a chain hydrocarbon group having 1 to 10 carbon atoms, an aromatic hydrocarbon group having 6 to 14 carbon atoms, or an alicyclic hydrocarbon group having 3 to 18 carbon atoms. A¹ and B¹ each independently represent a nitrogen atom or a carbon atom.

n2 and m2 each independently represent 0 or 1. With the proviso that when A¹ is a nitrogen atom, n2 represents 0, and when A¹ is a carbon atom, n2 represents 1, and when B¹ is a nitrogen atom, m2 represents 0, and when B¹ is a carbon atom, m2 represents 1.

R¹⁴ represents a hydrogen atom or a methyl group.

Xⁱ¹ represents a sulfur atom or an NH group.

Lⁱ¹ represents a divalent hydrocarbon group having 1 to 20 carbon atoms. The methylene group included in the hydrocarbon group is optionally replaced with an oxygen atom or a carbonyl group.

Examples of the chain hydrocarbon group having 1 to 10 carbon atoms for R¹²¹ and R¹³¹ include an alkyl group having 1 to 10 carbon atoms, such as a methyl group, an ethyl group, a propyl group, a butyl group, a pentyl group, a hexyl group, a heptyl group, and an octyl group, and preferably an alkyl group having 1 to 4 carbon atoms.

Examples of the aromatic hydrocarbon group having 6 to 14 carbon atoms for R¹²¹ and R¹³¹ include an aryl group having 6 to 14 carbon atoms such as a phenyl group, a naphthyl group, an anthryl group, a biphenyl group, and a phenanthryl group, and preferably an aryl group having 6 to 10 carbon atoms. The aromatic hydrocarbon group may further have a substituent, and examples of the aromatic hydrocarbon group having a substituent include an aromatic hydrocarbon group having aralkyl group or an alkyl group, and specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2, 6-diethylphenyl group, and a 2-methyl-6-ethylphenyl group.

Examples of the alicyclic hydrocarbon group having 3 to 18 carbon atoms for R¹²¹ and R¹³¹ include: a monocyclic alicyclic hydrocarbon group of a cycloalkyl group having 3 to 18 carbon atoms, such as a cyclopentyl group, a cyclohexyl group, a cycloheptyl group, and a cyclooctyl group; and a polycyclic alicyclic hydrocarbon group, such as a decahydronaphthyl group, an adamantyl group, and a norbornyl group, and preferably an alicyclic hydrocarbon group having 5 to 10 carbon atoms.

R¹²¹ and R¹³¹ are preferably each independently a hydrogen atom or an alkyl group having 1 to 4 carbon atoms.

Examples of the divalent hydrocarbon group having 1 to 20 carbon atoms represented by Lⁱ¹ include an alkanediyl group such as a methylene group, an ethylene group, a propane-1,3-diyl group, a butane-1,4-diyl group, a pentane-1, 5-diyl group, a hexane-1,6-diyl group, a heptane-1, 7-diyl group, an octane-1, 8-diyl group, a nonane-1, 9-diyl group, a decane-1, 10-diyl group, an undecane-1, 11-diyl group, a dodecane-1, 12-diyl group, a tridecane-1, 13-diyl group, a tetradecane-1, 14-diyl group, a pentadecane-1, 15-diyl group, a hexadecane-1, 16-diyl group, a heptadecane-1, 17-diyl group, an ethane-1,1-diyl group, a propane-1,1-diyl group, a propane-1,2-diyl group, a propane-2,2-diyl group, a pentane-2, 4-diyl group, a 2-methylpropane-1,3-diyl group, a 2-methylpropane-1,2-diyl group, a pentane-1,4-diyl group, and 2-methylbutane-1,4-diyl group;
a monocyclic divalent alicyclic saturated hydrocarbon group such as a cycloalkanediyl group such as a cyclobutane-1,3-diyl group, a cyclopentane-1,3-diyl group, a cyclohexane-1,4-diyl group, and a cyclooctane-1, 5-diyl group;
a polycyclic divalent alicyclic saturated hydrocarbon group such as a norbornane-1,4-diyl group, a norbornane-2, 5-diyl group, an adamantane-1, 5-diyl group, and an adamantane-2, 6-diyl group; and
an arylene group such as a phenylene group, a tolylene group, and a naphthylene group.

Lⁱ¹ is preferably a group obtained by combining an alkanediyl group having 2 to 14 carbon atoms including an ester bond or an arylene group having 6 to 10 carbon atoms and an alkanediyl group having 1 to 11 carbon atoms.

The structural unit represented by formula (IB) is preferably a structural unit represented by formula (IB-1) or a structural unit represented by formula (IB-2).

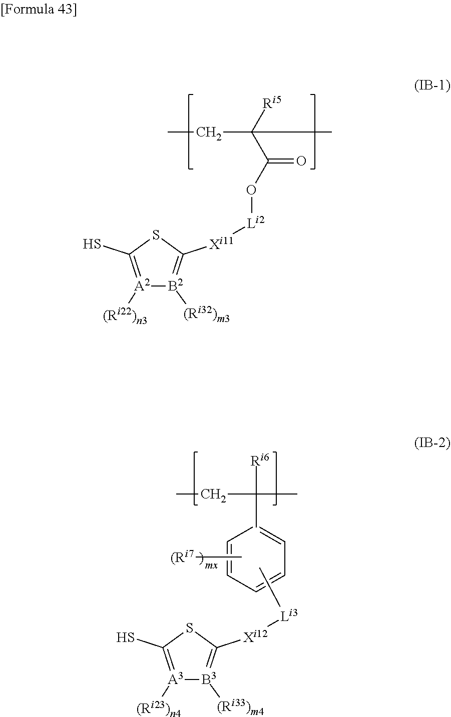

In formula (IB-1),
R¹²² and R¹³² each independently represent a hydrogen atom, a chain hydrocarbon group having 1 to 10 carbon atoms, an aromatic hydrocarbon group having 6 to 14 carbon atoms, or an alicyclic hydrocarbon group having 3 to 18 carbon atoms. A² and B³ each independently represent a nitrogen atom or a carbon atom.

n3 and m3 each independently represent 0 or 1. However, when A² is a nitrogen atom, n3 represents 0, and when A² is a carbon atom, n3 represents 1, and when B² is a nitrogen atom, m3 represents 0, and when B² is a carbon atom, m3 represents 1.

Xⁱ¹¹ represents a sulfur atom and an NH group.

Lⁱ² represents a divalent hydrocarbon group having 1 to 18 carbon atoms. A methylene group included in the hydrocarbon group is optionally replaced with an oxygen atom or a carbonyl group.

Rⁱ⁵ represents a hydrogen atom or a methyl group.

In formula (IB-2),
Rⁱ²³ and Rⁱ³³ each independently represent a hydrogen atom, a chain hydrocarbon group having 1 to 10 carbon atoms, an aromatic hydrocarbon group having 6 to 14 carbon atoms, or an alicyclic hydrocarbon group having 3 to 18 carbon atoms. A³ and B³ each independently represent a nitrogen atom or a carbon atom.

n4 and m4 each independently represent 0 or 1. However, when A³ is a nitrogen atom, n4 represents 0, and when A³ is a carbon atom, n4 represents 1, and when B³ is a nitrogen atom, m4 represents 0, and when B³ is a carbon atom, m4 represents 1.

Xⁱ² represents a sulfur atom or an NH group.

Lⁱ³ represents a divalent hydrocarbon group having 1 to 14 carbon atoms. The methylene group included in the hydrocarbon group is optionally replaced with an oxygen atom or a carbonyl group.

Rⁱ⁷ represents an alkyl group having 1 to 6 carbon atoms or an alkoxy group having 1 to 6 carbon atoms.

Rⁱ⁶ represents a hydrogen atom or a methyl group. mx represents an integer of 0 to 4.

Examples of the chain hydrocarbon group having 1 to 10 carbon atoms represented by R¹²², R¹³², Rⁱ²³, and Rⁱ³³ include the same chain hydrocarbon group having 1 to 10 carbon atoms represented by R¹²¹ and R¹³¹.

Examples of the aromatic hydrocarbon group having 6 to 14 carbon atoms represented by R¹²², R¹³², Rⁱ²³, and Rⁱ³³ include the same aromatic hydrocarbon group having 6 to 14 carbon atoms represented by R¹²¹ and R¹³¹.

Examples of the alicyclic hydrocarbon group having 3 to 18 carbon atoms represented by R¹²², R¹³², Rⁱ²³, and Rⁱ³³ include the same alicyclic hydrocarbon group having 3 to 18 carbon atoms represented by R¹²¹ and R¹³¹.

Examples of the divalent hydrocarbon group having 1 to 18 carbon atoms represented by Lⁱ² include an alkanediyl group such as a methylene group, an ethylene group, a propane-1,3-diyl group, a butane-1,4-diyl group, a pentane-1, 5-diyl group, a hexane-1,6-diyl group, a heptane-1, 7-diyl group, an octane-1, 8-diyl group, a nonane-1, 9-diyl group, a decane-1, 10-diyl group, an undecane-1, 11-diyl group, a dodecane-1, 12-diyl group, a tridecane-1, 13-diyl group, a tetradecane-1, 14-diyl group, a pentadecane-1, 15-diyl group, a hexadecane-1, 16-diyl group, a heptadecane-1, 17-diyl group, an ethane-1,1-diyl group, a propane-1,1-diyl group, a propane-1,2-diyl group, a propane-2,2-diyl group, a pentane-2, 4-diyl group, a 2-methylpropane-1,3-diyl group, a 2-methylpropane-1,2-diyl group, a pentane-1,4-diyl group, and a 2-methylbutane-1,4-diyl group;

a monocyclic divalent alicyclic saturated hydrocarbon group such as a cycloalkanediyl group such as a cyclobutane-1,3-diyl group, a cyclopentane-1,3-diyl group, a cyclohexane-1,4-diyl group, and a cyclooctane-1, 5-diyl group;

a polycyclic divalent alicyclic saturated hydrocarbon group such as a norbornane-1,4-diyl group, a norbornane-2, 5-diyl group, an adamantane-1, 5-diyl group, and an adamantane-2, 6-diyl group; and
an arylene group such as a phenylene group, a tolylene group, and a naphthylene group.

Lⁱ² is preferably an alkanediyl group having 1 to 14 carbon atoms, and more preferably an alkanediyl group having 1 to 11 carbon atoms.

Examples of the divalent hydrocarbon group having 1 to 14 carbon atoms represented by Lⁱ³ include an alkanediyl group such as a methylene group, an ethylene group, a propane-1,3-diyl group, a butane-1,4-diyl group, a pentane-1, 5-diyl group, a hexane-1,6-diyl group, a heptane-1, 7-diyl group, an octane-1, 8-diyl group, a nonane-1, 9-diyl group, a decane-1, 10-diyl group, an undecane-1, 11-diyl group, a dodecane-1, 12-diyl group, an ethane-1,1-diyl group, a propane-1,1-diyl group, a propane-1,2-diyl group, a propane-2,2-diyl group, a pentane-2, 4-diyl group, a 2-methylpropane-1,3-diyl group, a 2-methylpropane-1,2-diyl group, a pentane-1,4-diyl group, and a 2-methylbutane-1,4-diyl group;
a monocyclic divalent alicyclic saturated hydrocarbon group such as a cycloalkanediyl group such as a cyclobutane-1,3-diyl group, a cyclopentane-1,3-diyl group, a cyclohexane-1,4-diyl group, and a cyclooctane-1, 5-diyl group; and
a polycyclic divalent alicyclic saturated hydrocarbon group such as a norbornane-1,4-diyl group, a norbornane-2, 5-diyl group, an adamantane-1, 5-diyl group, and an adamantane-2, 6-diyl group.

Lⁱ³ is preferably an alkanediyl group having 1 to 14 carbon atoms, and more preferably an alkanediyl group having 1 to 11 carbon atoms.

Based on the position at which the phenyl group is bonded to the main chain, Lⁱ³ is preferably bonded to the p-position.

Examples of the alkyl group having 1 to 6 carbon atoms represented by R¹⁷ include a methyl group, an ethyl group, a propyl group, and an isopropyl group.

Examples of the alkoxy group having 1 to 6 carbon atoms represented by R¹⁷ include a methoxy group, an ethoxy group, a propoxy group, and a butoxy group.

Examples of the sulfur-containing compound include compounds represented by any of the formulas (I-1) to (I-26). Among these, preferable are compounds represented by formulas (I-1) to (I-13), and more preferable are compounds represented by formulas (I-1), (1-4), and (I-11).

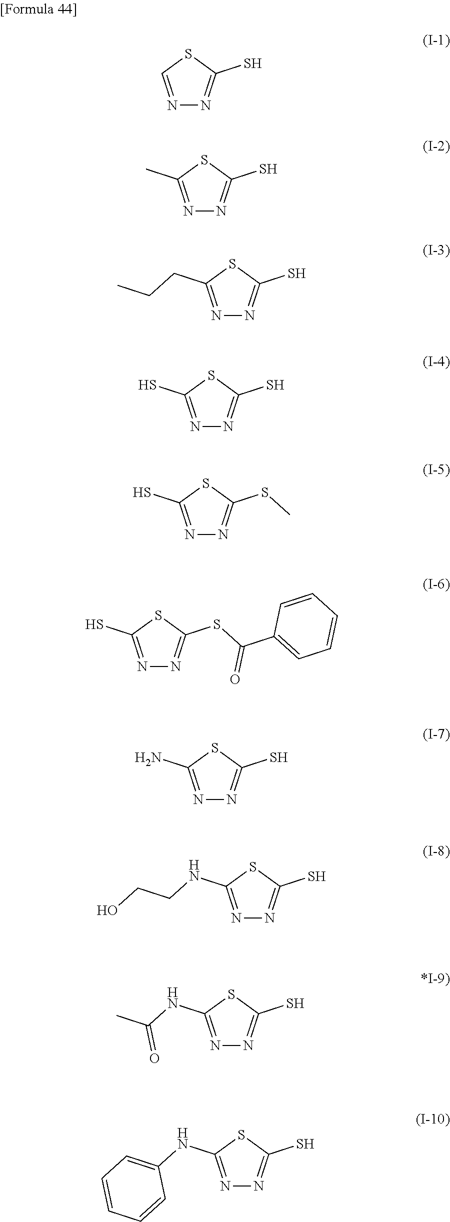

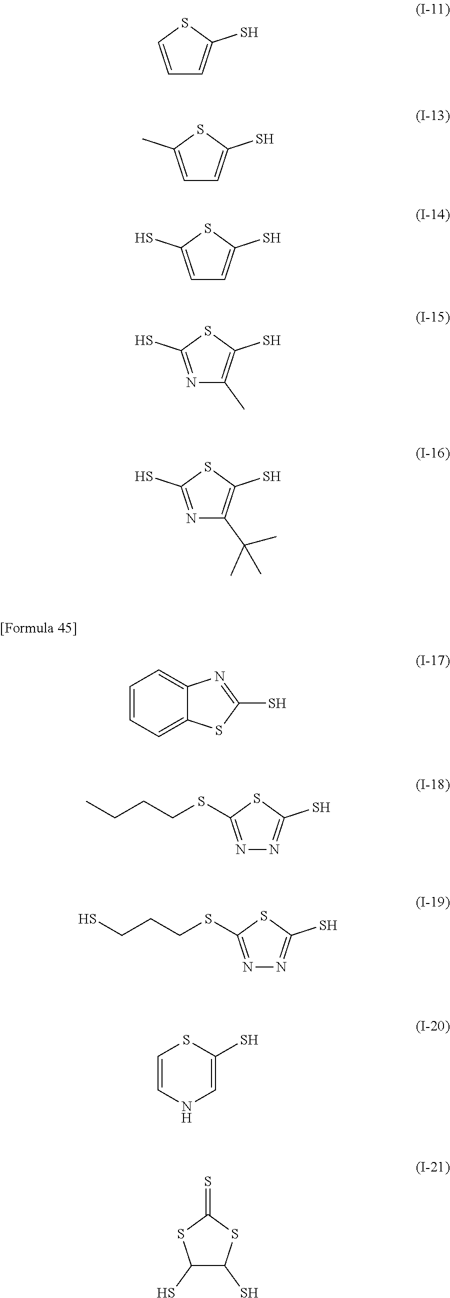

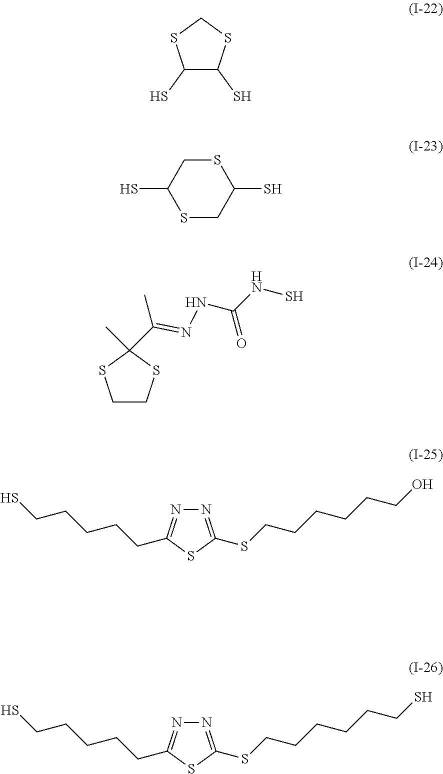 [SMILES: SC1SCSC1S ; SC1CSC(S)CS1 ; C/C(=N\NC(=O)NS)C1(C)SCCS1 ; OCCCCCCSc1nnc(CCCCCS)s1 ; SCCCCCCSc1nnc(CCCCCS)s1]

Examples of the sulfur-containing compound include a homopolymer composed of any one of the structural units represented by formulas (I-27) to (I-38) and a copolymer including one or more of these structural units.

A copolymer including one or more of the structural units represented by formulas (1-27) to (1-36) is preferable, and a copolymer including a structural unit represented by formula (I-33) is more preferable.

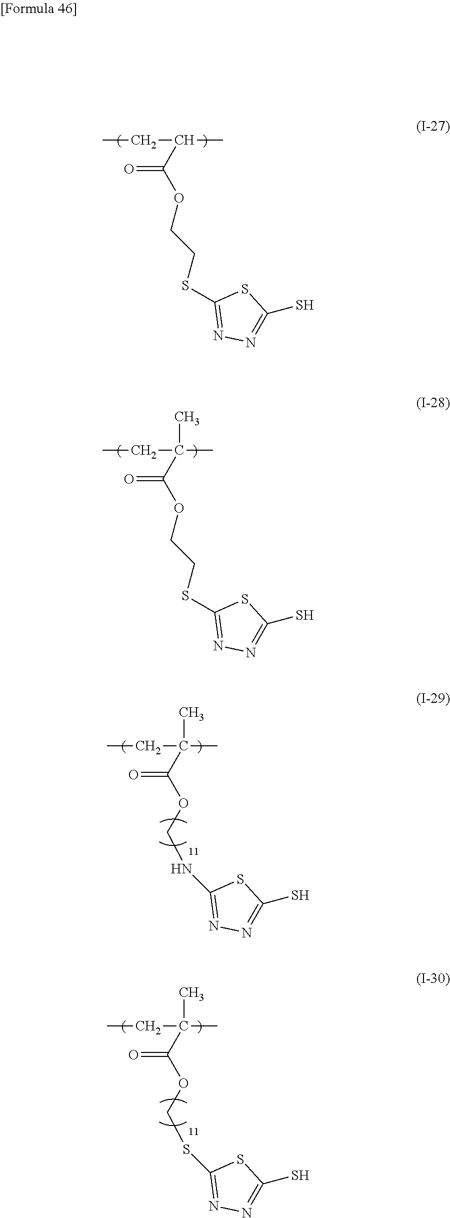

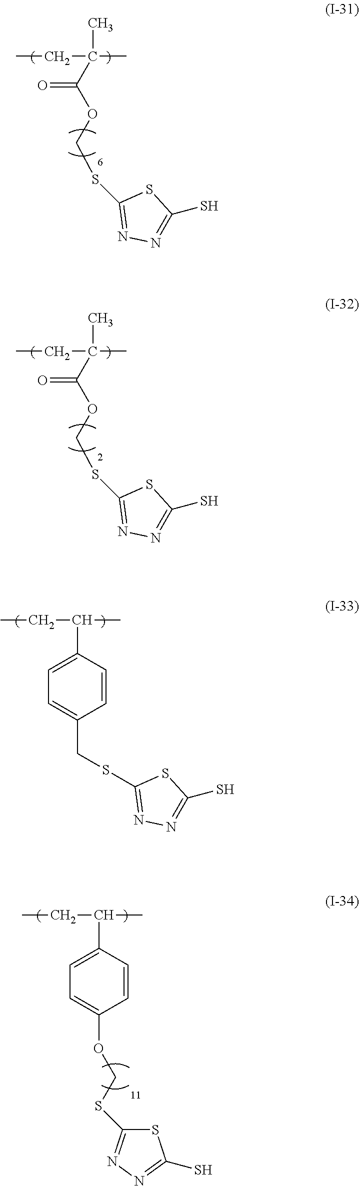

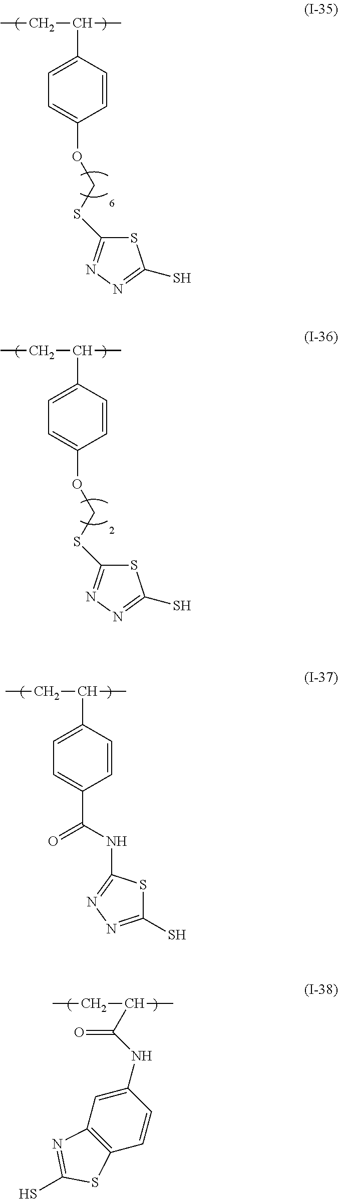

Examples of such a copolymer include a copolymer composed of structural units represented by formulas (I-39) to (I-48). Among these, a polymer having structural units represented by formulas (I-39) to (I-44) is preferable.

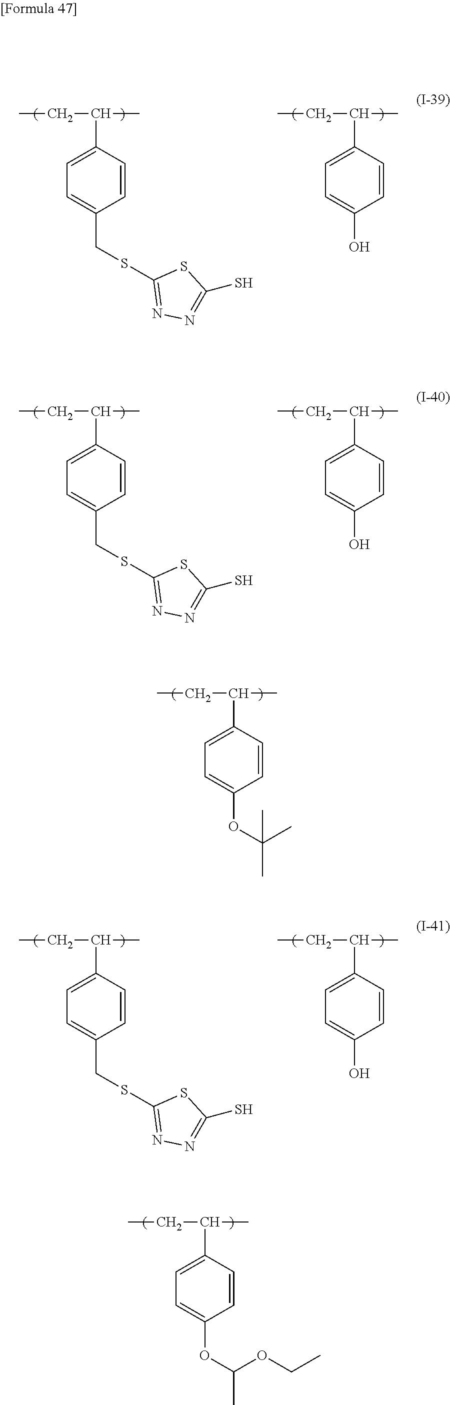

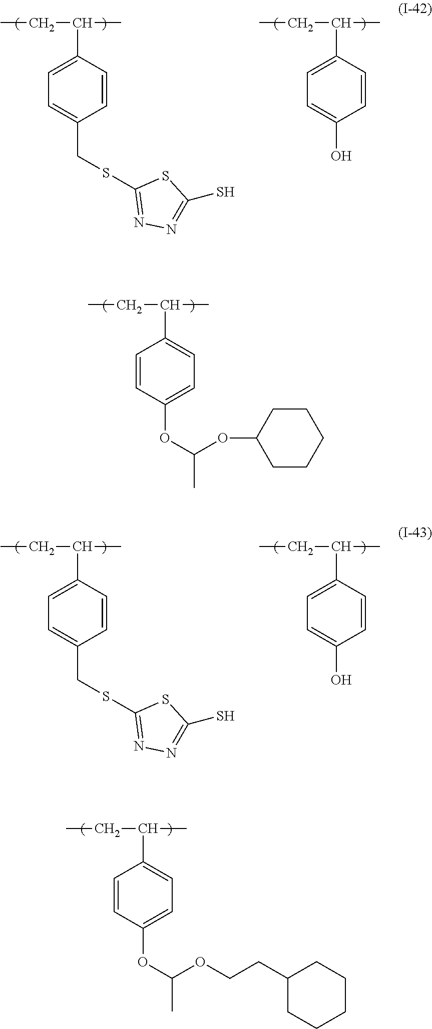

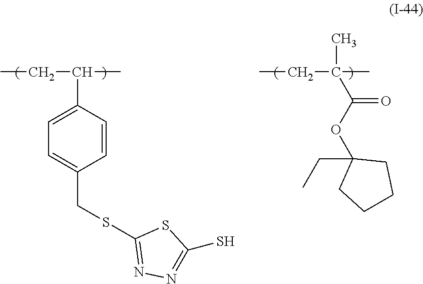

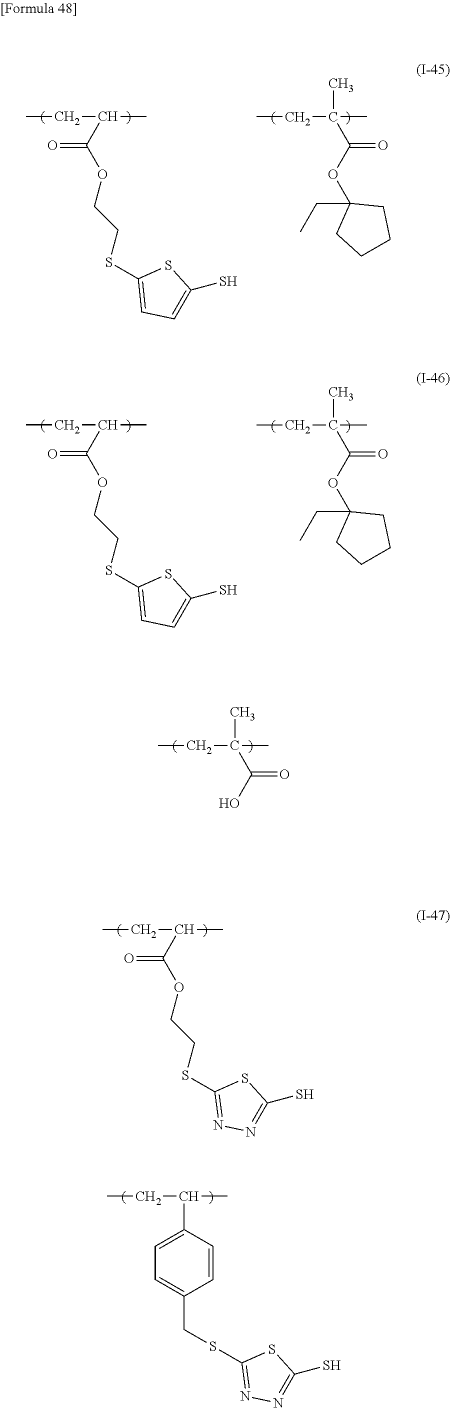

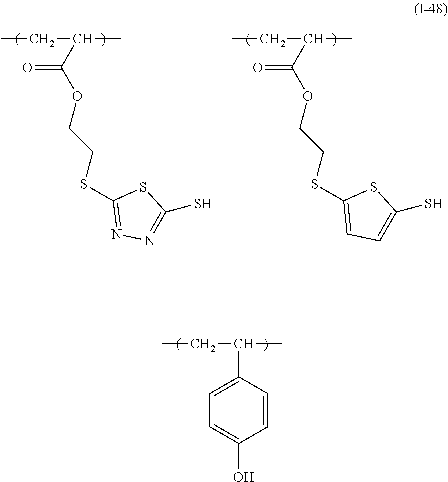

The sulfur-containing compound may be synthesized by a known method (e.g., Japanese Patent Laid-Open No. 2010-79081) or may be a commercially available product. The polymer including a sulfur-containing compound may be a commercially available product (e.g., bismuthiol, manufactured by Tokyo Chemical Industry Co., Ltd.) or may be synthesized by a known method (e.g., Japanese Patent Laid-Open No. 2001-75277).

Examples of the aromatic hydroxy compound include phenol, cresol, xylenol, pyrocatechol (=1,2-dihydroxybenzene), tert-butylcatechol, resorcinol, hydroquinone, pyrogallol, 1,2, 4-benzenetriol, salicyl alcohol, p-hydroxybenzyl alcohol, o-hydroxybenzyl alcohol, p-hydroxyphenethyl alcohol, p-aminophenol, m-aminophenol, diaminophenol, aminoresorcinol, p-hydroxybenzoic acid, o-hydroxybenzoic acid, 2, 4-dihydroxybenzoic acid, 2,5-dihydroxybenzoic acid, 3,4-dihydroxybenzoic acid, 3,5-dihydroxybenzoic acid, and gallic acid.

Examples of the benzotriazole compound include a compound represented by formula (IX).

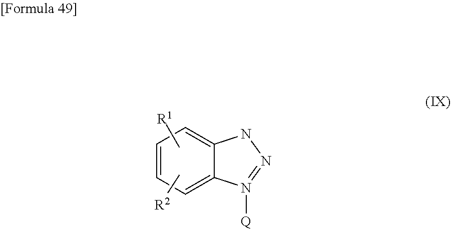

In formula (IX),
R¹ and R² each independently represent a hydrogen atom, a hydrocarbon group having 1 to 10 carbon atoms optionally having a substituent, a carboxy group, an amino group, a hydroxyl group, a cyano group, a formyl group, a sulfonylalkyl group, or a sulfo group.

Q represents a hydrogen atom, a hydroxy group, a hydrocarbon group having 1 to 10 carbon atoms optionally having a substituent, an aryl group, or **—R^{3X}—N(R^{4X})(R^{5X}), and the hydrocarbon group may have an amide bond or ester bond in the structure.

R^{3X} represents an alkanediyl group having 1 to 6 carbon atoms. ** represents a bond to the nitrogen atom included in the ring.

R^{4X} and R^{5X} each independently represent a hydrogen atom, a hydroxyl group, an alkyl group having 1 to 6 carbon atoms, a hydroxyalkyl group having 1 to 6 carbon atoms, or an alkoxyalkyl group having 2 to 6 carbon atoms.

The hydrocarbon group having 1 to 10 carbon atoms for R¹, R², and Q may be either a chain hydrocarbon group having 1 to 10 carbon atoms and an aromatic hydrocarbon group having 6 to 10 carbon atoms, and may have saturated and/or unsaturated bonds.

As the chain hydrocarbon group having 1 to 10 carbon atoms, an alkyl group is preferable, and examples of the alkyl group include a methyl group, an ethyl group, an n-propyl group, an isopropyl group, an n-butyl group, a sec-butyl group, a tert-butyl group, an n-pentyl group, a methylpentyl group, an n-hexyl group, and an n-heptyl group.

As the aromatic hydrocarbon group having 6 to 10 carbon atoms, an aryl group is preferable, and examples of the aryl group include a phenyl group, a naphthyl group, an anthryl group, a biphenyl group, and a phenanthryl group. The aromatic hydrocarbon group may further have a substituent, and examples of the aromatic hydrocarbon group having a substituent include an aromatic hydrocarbon group having an aralkyl group or alkyl group and, specific examples thereof include a benzyl group, a phenethyl group, a phenylpropyl group, a trityl group, a naphthylmethyl group, a naphthylethyl group, a p-methylphenyl group, a p-tert-butylphenyl group, a tolyl group, a xylyl group, a cumenyl group, a mesityl group, a 2, 6-diethylphenyl group, and a 2-methyl-6-ethylphenyl group.

Examples of the substituent that the hydrocarbon group having 1 to 10 carbon atoms may have include a hydroxyalkyl group and an alkoxyalkyl group.

The alkanediyl group having 1 to 6 carbon atoms for R^{3X} may be either linear or branched, and examples thereof include a methylene group, an ethylene group, a propane-1,3-diyl, and propane-1,2-diyl group.

The alkyl group having 1 to 6 carbon atoms for R^{4X} and R^{5X} may be a methyl group, an ethyl group, a propyl group, and an isopropyl group.

Examples of the hydroxyalkyl group having 1 to 6 carbon atoms for R^{4X} and R^{5X} include a hydroxymethyl group, a hydroxyethyl group, and a dihydroxyethyl group.

Examples of the alkoxyalkyl group having 2 to 6 carbon atoms for R^{4X} and R^{5X} include a methoxymethyl group, a methoxyethyl group, and a dimethoxyethyl group.

When the resist composition of the present invention is applied to a substrate on which Cu is formed, a compound represented by formula (IX) in which Q is represented by **—R^{3X}—N(R^{4X}) (R^{5X}) is preferable. Among these, when at least one of R^{4X} and R^{5X} is an alkyl group having 1 to 6 carbon atoms, the benzotriazole-based compound has poor water solubility, but is preferably used when other component capable of dissolving this compound is present.

In addition, when the resist composition of the present invention is applied to a substrate having an inorganic material layer (e.g., a polysilicon film and an amorphous silicon film), Q in formula (IX) preferably represents a water-soluble group. Specifically, a hydrogen atom, an alkyl group having 1 to 3 carbon atoms, a hydroxyalkyl group having 1 to 3 carbon atoms, a hydroxy group, and the like are preferable. This allows the corrosion prevention properties of the substrate to be exhibited more effectively.

Examples of the benzotriazole-based compound include benzotriazole, 5, 6-dimethylbenzotriazole, 1-hydroxybenzotriazole, 1-methylbenzotriazole, 1-aminobenzotriazole, 1-phenylbenzotriazole, 1-hydroxymethylbenzotriazole, methyl 1-benzotriazolecarboxylate, 5-benzotriazolecarboxylic acid, 1-methoxy-benzotriazole, 1-(2, 2-dihydroxyethyl)-benzotriazole, 1-(2, 3-dihydroxypropyl)benzotriazole, or 2, 2′-{[(4-methyl-1H-benzotriazol-1-yl)methyl] imino}bisethanol, 2,2′-{[(5-methyl-1H-benzotriazol-1-yl)methyl] imino}bisethanol, 2, 2 ‘-{[(4-methyl-1H-benzotriazol-1-yl)methyl] imino}bisethane, and 2, 2’-{[(4-methyl-1H-benzotriazol-1-yl)methyl] imino}bispropane.

Examples of the triazine-based compound include a compound represented by formula (II)

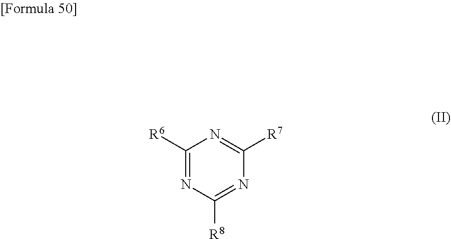

In formula (II),
R⁶, R⁷, and R⁸ each independently represent a halogen, a hydrogen atom, a hydroxyl group, an amino group, a mercapto group, an optionally substituted hydrocarbon group having 1 to 10 carbon atoms, an optionally substituted alkoxy group having 1 to 10 carbon atoms, or an amino group substituted with a hydrocarbon group having 1 to 10 carbon atoms.

Examples of the halogen atom include a fluorine atom, a chlorine atom, a bromine atom, and an iodine atom.

Examples of the hydrocarbon group having 1 to 10 carbon atoms include the same as those listed above.

Examples of the alkoxy group having 1 to 10 carbon atoms include a methoxy group, an ethoxy group, and a propoxy group.

Examples of the triazine-based compound include 1, 3, 5-triazine-2, 4, 6-trithiol.

Examples of the silicon-containing compound include a compound represented by formula (IIA).

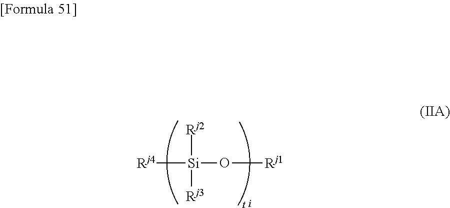

In formula (IIA),
Rⁱ¹ represents a chain hydrocarbon group having 1 to 5 carbon atoms or a mercaptoalkyl group having 1 to 5 carbon atoms.

R^{j2} to R^{j4} each independently represent a chain hydrocarbon group having 1 to 5 carbon atoms, an alkoxy group or mercapto group having 1 to 5 carbon atoms, or a mercaptoalkyl group having 1 to 5 carbon atoms, and at least one of R¹² to R^{j4} is a mercapto group or a mercaptoalkyl group having 1 to 5 carbon atoms.

tⁱ represents an integer of 1 to 10.

Examples of the chain hydrocarbon group having 1 to 5 carbon atoms include an alkyl group having 1 to 5 carbon atoms, such as a methyl group, an ethyl group, a propyl group, a butyl group, and a pentyl group.

Examples of the alkoxy group having 1 to 5 carbon atoms include a methoxy group and an ethoxy group.

Examples of the mercaptoalkyl group having 1 to 5 carbon atoms include a methyl mercapto group, an ethyl mercapto group, and a propyl mercapto group.

R^{j1} is preferably a methyl group, an ethyl group, or a mercaptoalkyl group having 1 to 3 carbon atoms, and more preferably a methyl group or a mercaptopropyl group (particularly, a 3-mercaptopropyl group).

R^{j2} to R^{j4} are preferably independently a methyl group, an ethyl group, a methoxy group, or an ethoxy group, and more preferably a methyl group or a methoxy group. However, at least one of these is preferably a mercapto group or a mercaptoalkyl group having 1 to 3 carbon atoms, and more preferably a mercapto group or a mercaptopropyl group. R^{j2} and R¹³ are optionally the same or different, but preferably the same from the viewpoint of productivity.

Examples of the compound of formula (IIA) include compounds represented by the following formulas (II-1) to (II-7).

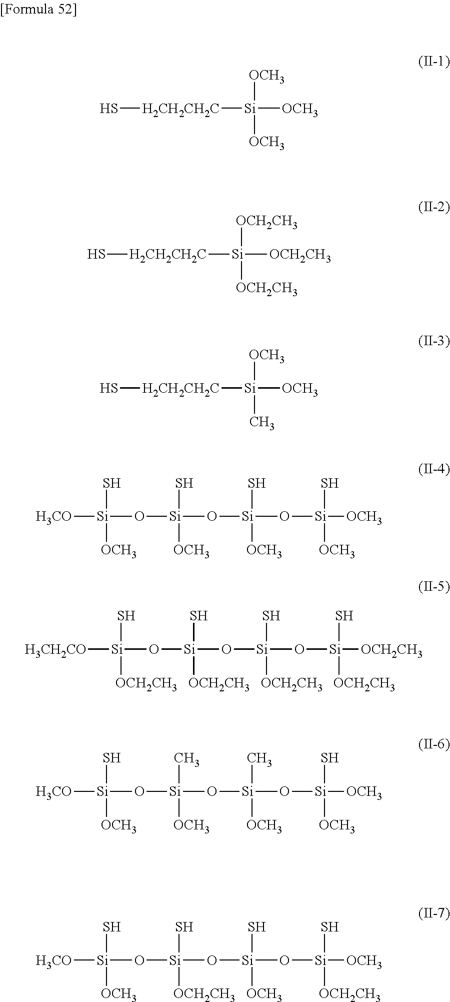

Among these, 3-mercaptopropyltrimethoxysilane, 3-mercaptopropyltriethoxysilane, and the like are preferable.

The content of adhesion improver (E) is preferably 0.001% by mass or more, more preferably 0.002% by mass or more, still more preferably 0.005% by mass or more, and particularly preferably 0.008% by mass or more, with respect to the total amount of solids in the resist composition, and is preferably 20% by mass or less, more preferably 10% by mass or less, still more preferably 4% by mass or less, even more preferably 3% by mass or less, particularly preferably 18 by mass or less, and most preferably 0.1% by mass or less. With such a range, a resist composition that can form a high-precision resist pattern can be obtained, and adhesion between the resist pattern and the substrate can be ensured.

### <Other Compositions>

The resist composition of the present invention may contain components other than those described above (hereinafter, may be referred to as “other components (F)”) as necessary. Other components (F) are not particularly limited, and an additive known in the resist field, such as a sensitizer, a dissolution inhibitor, a surfactant, a stabilizer, and a dye can be used.

When other components (F) are used, the content thereof is appropriately selected depending on the type of other components (F).

### <Preparation of Resist Composition>

The resist composition of the present invention can be prepared by mixing resin (A1), resin (A2), acid generator (B), and, as necessary, resin (A3), resins other than resins (A1) to (A3), quencher (C), solvent (D), adhesion improver (E), and other components (F). The order of mixing is arbitrary and is not particularly limited. An appropriate temperature for mixing can be selected from 10 to 40° C. depending on the type of resin and the like and the solubility of the resin and the like in solvent (D). An appropriate mixing time can be selected from 0.5 to 24 hours depending on the mixing temperature. The mixing means are not particularly limited, and stirring and mixing and the like can be used.

After mixing the components, filtration is preferable performed using a filter with a pore size of about 0.003 to 50 μm.

### <Dry Film Resist>

One aspect of the dry film resist of the present invention is a resist dry film including a support film and a resist composition layer stacked on the support and containing the resist composition of the present invention. One aspect of the dry film of the present invention may, as necessary, include a protective film stacked on the resist composition layer stacked on the support.

The support film and protective film are not particularly limited as long as they can be peeled off from the composition layer without damaging the form of the resist composition layer, and a single film or a multilayer film obtained by stacking a plurality of polymers can be used. Examples of the plastic films that can be used include nylon film, polyethylene (PE) film, polyethylene terephthalate (PET) film, polyethylene naphthalate film, polyphenylene sulfide (PPS) film, polypropylene (PP) film, polystyrene film, polymethylpentene (TPX) film, polycarbonate, fluorine-containing film, special polyvinyl alcohol (PVA) film, and polyester film that has been subjected to a release treatment.

The thickness of each of the support film and protective film is preferably 10 to 100 μm, and more preferably 25 μm to 50 μm, from the viewpoints of production stability and winding set with respect to the winding core.

The thickness of the resist composition layer is 1 μm to 500 μm, and more preferably 5 μm to 450 μm.

A method for producing a dry film resist of the present invention will be described. The method for producing a dry film of the present invention includes the steps of (la) applying the resist composition of the present invention to a support film to form a photoresist composition layer, and (2a) drying the resist composition layer. If necessary, the method may include the step of laminating a protective film on the resist composition layer after drying the resist composition layer.

As the method for stacking the resist composition layer of the present invention on the support film, a method known in the art can be used, and uniform application is possible with the apparatus that is typically used, for example, a forward roll coater, reverse roll coater, comma coater, die coater, lip coater, gravure coater, a dip coater, air knife coater, capillary coater, raising & rising (R&R) coater, a blade coater, a bar coater, an applicator, and an extrusion molding machine.

As the method for drying the resist composition layer on the support film, a method such as air drying, heating and drying in an oven or on a hot plate, or drying under reduced pressure is used. The heating temperature is preferably 40° C. to 150° C., and more preferably 50° C. to 130° C., and the heating time is preferably 1 to 40 minutes, and more preferably 2 to 30 minutes. In addition, the pressure during drying under reduced pressure is preferably about 1 to 1.0×10⁵ Pa.

After drying, as a method for stacking a protective film on the resist composition layer, a method known in the art can be used, and for example, pressure bonding and stacking may be possible using a roll laminator.

In the present invention, incorporating a resist material solution on a support film under specific molding conditions and using a molding machine into a production line allows to continuously form a roll film and produce a roll film that can be handled in a desired shape, and the same is true when a protective film is formed on a resist dry film layer.

### <Method for Producing Resist Pattern>

One aspect of the method for producing (forming) a resist pattern of the present invention is a method for producing a resist pattern using the resist composition of the present invention, and another aspect of the method for producing a resist pattern of the present invention is a method for producing a resist pattern using the dry film resist of the present invention.

### <Method for Producing Resist Pattern Using Resist Composition>

A method for producing a resist pattern using the resist composition of the present invention is described below.

The method for producing a resist pattern using the resist composition of the present invention includes: a step of (1b) applying the resist composition of the present invention onto a substrate and drying the resist composition to form a resist composition layer; a step of (2b) exposing the resist composition layer to ultraviolet light having a wavelength of 500 nm or less, and a step of (3b) developing the exposed resist composition without heating.

As a method for applying the resist composition onto a substrate, any method known in the art can be used, and a commonly used apparatus such as a spin coater can be used.

The substrate to which the resist composition is applied includes an inorganic substrate such as a silicon wafer, and semiconductor elements (e.g., transistors or diodes) may be formed previously on the substrate. When the resist composition of the present invention is used for bump formation, the substrate is preferably one on which a conductive material is further stacked. The conductive material includes at least one metal selected from the group consisting of gold, copper, nickel, tin, palladium and silver, or an alloy containing at least one metal selected from the group, and preferably copper or an alloy containing copper.

Before applying the resist composition, the substrate may be washed, and an anti-reflective film or the like may be formed on the substrate.

The applied resist composition is dried to remove a solvent and form a composition layer. Drying is performed, for example, by evaporating the solvent using a heating device such as a hot plate (so-called pre-baking), or by using a vacuum device. The heating temperature is preferably 50 to 200° C., and the heating time is preferably 30 to 600 seconds. In addition, the pressure during reduced pressure drying is preferably around 1 to 1.0×10⁵ Pa.

After drying the resist composition, the film thickness of the resulting composition is preferably 1 to 500 μm, more preferably 1 to 300 μm, and still more preferably 1.5 μm to 130 μm.

After drying the resist composition, in order to achieve a desired film thickness for the resist composition layer, the step of applying the resist composition of the present invention or stacking a resist composition layer of the dry film resist of the present invention on the dried resist composition layer and drying may be repeated before exposure. As necessary, a composition other than the resist composition of the present invention can be stacked, or a resist composition layer other than the dry film resist of the present invention can be stacked.

Various types of exposure light sources can be used, such as: light sources that emit light with wavelengths of 345 to 436 nm (g-line (wavelength: 436 nm), h-line (wavelength: 405 nm), i-line (wavelength: 365 nm)); light sources that emit ultraviolet laser light such as KrF excimer laser (wavelength 248 nm), ArF excimer laser (wavelength 193 nm), and F2 excimer laser (wavelength 157 nm); light sources that convert the wavelength of laser light from a solid-state laser light source (YAG or semiconductor laser) to emit harmonic laser light in the far ultraviolet or vacuum ultraviolet range; and light sources that irradiate electron beams or extreme ultraviolet light (EUV). In the present specification, irradiation with these types of radiation may be collectively referred to as “exposure”. During exposure, exposure is typically performed through a mask that corresponds to the desired pattern. When the exposure light source is an electron beam, exposure may be performed by direct drawing without using a mask.

The exposed resist composition layer is developed without being subjected to a heat treatment. Specifically, this means that the exposed resist composition layer is not maintained at a temperature of 30° C. or more, and preferably is maintained at an environmental temperature typically used in resist pattern production (e.g., the environmental temperature in a clean room, specifically 23±5° C.).

The development is typically performed using a developing device and a developer. The development methods include a dipping method, a paddle method, a spray method, a dynamic dispensing method, and the like. The development temperature is preferably, for example, 5 to 60° C., and the development time is preferably, for example, 5 to 600 seconds. Selecting the type of the developer as follows allows a positive resist pattern or a negative resist pattern to be produced.

When producing a positive resist pattern from the resist composition of the present invention, an alkaline developer is used as the developer. The alkaline developer may be any of the various alkaline aqueous solutions used in this field. Examples thereof include an aqueous solution of tetramethylammonium hydroxide of (2-hydroxyethyl)trimethylammonium hydroxide (commonly known as choline). The alkaline developer may include a surfactant.

It is preferable to wash the developed resist pattern with ultrapure water, and then remove water remaining on the substrate and the pattern.

When producing a negative resist pattern from the resist composition of the present invention, a developer including an organic solvent (hereinafter, may be referred to as an “organic developer”) is used as the developer.

Examples of the organic solvent included in the organic developer include: ketone solvents such as 2-hexanone and 2-heptanone; glycol ether ester solvents such as propylene glycol monomethyl ether acetate; ester solvents such as butyl acetate; glycol ether solvents such as propylene glycol monomethyl ether; amide solvents such as N, N-dimethylacetamide; and aromatic hydrocarbon solvents such as anisole.

The content rate of the organic solvent in the organic developer is preferably 908 by mass or more and 100% by mass or less, more preferably 95% by mass or more and 100% by mass or less, and still more preferably substantially only organic solvent.

Among these, a developer including butyl acetate and/or 2-heptanone is preferable as the organic developer. The total content rate of butyl acetate and 2-heptanone in the organic developer is preferably 50% by mass or more and 100% by mass or less, more preferably 90% by mass or more and 100% by mass or less, and still more preferably substantially only butyl acetate and/or 2-heptanone.

The organic developer may include a surfactant. In addition, the organic developer may include a trace amount of water.

During the development, the development may be stopped by replacing the organic developer with a different type of solvent.

It is preferable to wash the developed resist pattern with a rinse solution. The rinse solution is not particularly limited as long as it does not dissolve the resist pattern, and a solution including a general organic solvent can be used, preferably an alcohol solvent or an ester solvent.

After washing, it is preferable to remove the rinse solution remaining on the substrate and pattern.

Exposing the resist obtained using the resist composition of the present invention allows a resist pattern with a highly accurate shape to be formed.

### <Production Method of Resist Pattern Using Dry Film Resist>

A method for producing resist pattern using the dry film resist of the present invention will be described.

The method for producing a resist pattern using the resist composition of the present invention includes: (1c) a step of stacking the dry film resist of the present invention on a substrate; (2c) an exposure step of peeling at least a portion of the support film from the resist composition layer and exposing the resist composition layer to ultraviolet light having a wavelength of 500 nm or less; and (3c) a step of developing the exposed resist composition layer without heating.

As the method for stacking the dry film on the substrate, a conventionally known method can be used, and for example, a vacuum laminator or a roll coater can be used. Specifically, when a vacuum laminator is used, the protective film of the dry film resist of the present invention is peeled off, then the vacuum chamber of the vacuum laminator is set to a desired vacuum level, and the resist composition layer on the support film can be adhered to the substrate. In addition, when a roll coater is used, the protective film can be stacked on the substrate while peeled off from the dry film resist of the present invention in a winding manner.

As the substrate to stack the dry film resist, the same substrate as the substrate to apply the resist composition as described above can be used.

As the method for stacking the dry film resist on the substrate and peeling off the protective film from the resist composition layer, a method known in the art can be used. Only the necessary portions of the support film may be peeled off, or the entire support film may be peeled off.

In order to achieve the desired film thickness of the resist composition layer, the support film is peeled off, then stacked on the resist composition layer before exposure, and the resist composition of the present invention may be applied, or a step of further stacking a resist composition layer of the dry film resist of the present invention may be repeated.

The production is possible in the same manner as in the method for producing a resist pattern using the resist composition of the present invention, by a step of peeling off the support film and then exposing the resist composition layer to ultraviolet light with a wavelength of 500 nm or less and the step of developing the exposed resist composition without heating.

### <Method for Producing Plated Object>

A resist pattern formed by the method for the resist pattern using the above-described resist composition of the present invention or the dry film resist of the present invention is used as a mold to deposit an electrode material by plating, and after deposition, the resist pattern is peeled off to create plated objects such as connection terminals or rewiring including bumps and metal pillars. Particularly, the resist pattern obtained using the resist composition of the present invention or the dry film resist of the present invention, if it is a thick film (for example, a thickness of 100 μm or more), has excellent resolution and plating resistance. Therefore, plated objects such as connection terminals or rewiring including bumps and metal pillars with accurate height can be created.

The method for producing a plated object of the present invention is described below. The method of the present invention is a method for forming a resist pattern using the resist composition of the present invention or the dry film resist of the present invention described above, and includes: (1d) a step of applying a resist composition or stacking a resist composition layer such that the resist composition layer contacts the conductive layer of the substrate; (2d) a step of exposing and developing the resist composition layer as described above to form a resist pattern on the substrate such that the conductive layer on the substrate is exposed; (3d) a step of forming a plated object using the resist pattern as a mold, and (4d) peeling off the resist pattern after forming the plated object.

Using a resist pattern formed on the substrate having a conductive layer as a mold, a conductive material is deposited using a plating solution by a known method to form a plated object.

Examples of the plating solution include copper plating solution, gold plating solution, nickel plating solution, solder plating solution, and silver-tin plating solution.

The plated object is formed, and then the resist pattern is removed using a stripping solution by a known method.

Examples of the stripping solution include: ethylene glycol alkyl ethers such as ethylene glycol monomethyl ether, ethylene glycol monoethyl ether, ethylene glycol monopropyl ether, and ethylene glycol monobutyl ether; diethylene glycol dialkyl ethers such as diethylene glycol dimethyl ether, diethylene glycol diethyl ether, diethylene glycol dipropyl ether, and diethylene glycol dibutyl ether; ethylene glycol alkyl acetates such as methyl cellosolve acetate and ethyl cellosolve acetate; propylene glycol alkyl ether acetates such as propylene glycol monomethyl ether acetate, propylene glycol monoethyl ether acetate, and propylene glycol monopropyl ether acetate; Ketones such as acetone, methyl ethyl ketone, cyclohexanone, and methyl amyl ketone; aromatic hydrocarbons such as toluene and xylene; cyclic ethers such as dioxane; and esters such as methyl 2-hydroxypropionate, ethyl 2-hydroxypropionate, ethyl 2-hydroxy-2-methylpropionate, ethyl 3-ethoxypropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, and ethyl acetoacetate. These may be used singly or in combination of two or more.

The above method allows formation of plated objects such as bumps and rewiring.

When forming the plated object, the ashing treatment and the like may be applied to the surface of the conductive layer to improve adhesion between the conductive layer and the plated object. Examples of the ashing treatment include a method using oxygen plasma.

The plated object obtained by using the resist pattern of the present invention swells little in the plating bath, and thus the plated object can be formed with high accuracy.

### EXAMPLES

The present invention will be explained in more detail with reference to Examples. In the Examples, “%” and “parts” indicating the content or amount used are based on mass unless otherwise specified.

The weight average molecular weight is the value determined by gel permeation chromatography under the following conditions.
Apparatus: HLC-8320 GPC (Tosoh Corporation)
Column: TSKgel Multipore HXL-M×3+guard column (Tosoh Corporation) Eluent: Tetrahydrofuran
Flow rate: 1.0 mL/min
Detector: RI detector
Column temperature: 40° C.
Injection volume: 100 μl
Molecular weight standard: Standard polystyrene

### (Tosoh Corporation)

### Synthesis Example 1 [Synthesis of Resin A¹-1]

20 parts of poly-p-hydroxystyrene (S-4P manufactured by Maruzen Petrochemical Co., Ltd.) was dissolved in 240 parts of methyl isobutyl ketone at room temperature and concentrated using an evaporator. The concentrated resin solution and 0.003 parts of p-toluenesulfonic acid dihydrate were added to a four-neck flask equipped with a reflux condenser, stirrer, and thermometer. While the resulting mixture was maintained at 20 to 25° C., 5.05 parts of ethyl vinyl ether was added dropwise to the resulting mixture over 10 minutes. The mixture was stirred at 20 to 25° C. for 2 hours. The resulting reaction mixture was diluted with 200 parts of methyl isobutyl ketone, washed with ion-exchanged water, and subjected to liquid-liquid separation five times. The resulting organic layer was concentrated to 45 parts using an evaporator, and then 150 parts of propylene glycol monomethyl ether acetate was added and concentrated again to provide 78 parts of a propylene glycol monomethyl ether acetate solution of Resin A¹-1 (solid content 29%). Resin A¹-1 is a resin having the following structural units. The weight average molecular weight of Resin A¹-1 was 1.16×10⁴. The proportion of hydroxy groups in poly-p-hydroxystyrene replaced with ethoxyethoxy groups was 40.9%.

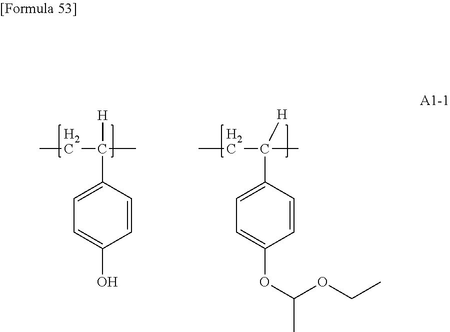

### Synthesis Example 2 [Synthesis of Resin AX1-1]

30 parts of methyl isobutyl ketone was charged into a four-neck flask equipped with a stirrer, reflux condenser, and thermometer, nitrogen replacement was completed, and then the temperature was raised to 82° C. A solution of 6 parts of t-butoxystyrene, 12.9 parts of 4-acetoxystyrene (molar ratio of t-butoxystyrene: 4-acetoxystyrene=30:70), and 0.75 parts of azobisisobutyronitrile dissolved in the methyl isobutyl ketone was added dropwise over one hour. Stirring was then continued for 6 hours while maintaining the temperature at 82° C. The reaction solution was cooled, and the resulting reaction solution was poured into a mixed solution of 184 parts of methanol and 61 parts of ion-exchanged water to reprecipitate the resin. After filtration, the resulting resin was dissolved in 40 parts of methyl isobutyl ketone, and 9.7 parts of ethanolamine, 1.94 parts of 4-dimethylaminopyridine, and 20 parts of methanol were added, followed by heating under reflux at 60° C. for 15 hours. After cooling, the mixture was concentrated and 40 parts of methyl isobutyl ketone was added to perform dissolution, and 10 parts of acetic acid and 30 parts of ion-exchanged water were added, stirred, followed by filtration. The resulting solution was poured into a large amount of a mixture of ion-exchanged water and methanol to precipitate the resin, which was then filtered and recovered. 140 parts of propylene glycol monomethyl ether acetate was added to the resulting resin, which was dissolved and concentrated, 70 parts of propylene glycol monomethyl ether acetate was then added and the mixture was concentrated again to provide 45 parts of a propylene glycol monomethyl ether acetate solution of resin AX1-1 (solid content 30%, yield 85%). The weight average molecular weight of resin AX1-1 was 1.33×10⁴.

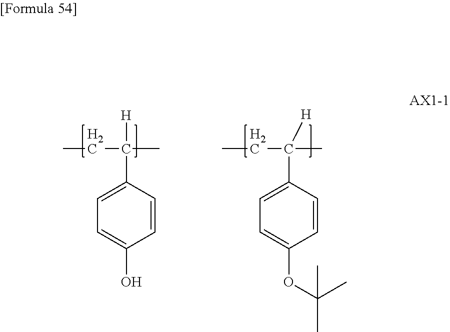

### Synthesis Example 3 [Synthesis of Resin A2-1]

70 parts of ethyl acetate was added to a four-neck flask equipped with a reflux condenser, stirrer, and thermometer, and the temperature was raised to 55° C., and a mixture of 15 parts of methacrylic acid, 58 parts of ethyl acrylate, 41 parts of methyl methacrylate (molar ratio: methacrylic acid: ethyl acrylate:methyl methacrylate=15:50:35), 3.46 parts of 2,2′-azobis (2,4-dimethylvaleronitrile), and 100 parts of ethyl acetate was added dropwise over 2 hours. The mixture was stirred for 3 hours while maintaining the temperature at 50° C. to 55° C. The resulting reaction mixture was cooled to 40° C. or less, diluted with 125 parts of ethyl acetate, and poured into a large amount of a mixture of ion-exchanged water and methanol to precipitate the resin, which was then filtered and recovered. 650 parts of propylene glycol monomethyl ether acetate was added to the obtained resin, which was then dissolved and concentrated, then 650 parts of propylene glycol monomethyl ether acetate was added and the mixture was concentrated again to provide 190 parts of a propylene glycol monomethyl ether acetate solution of Resin A2-1 (solid content 45%, yield 75%). The weight average molecular weight of Resin A2-1 was 3.79×10⁴.

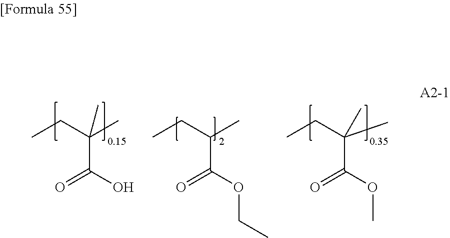

### Synthesis Example 4 [Synthesis of Resin A2-2]

70 parts of ethyl acetate was added to a four-neck flask equipped with a reflux condenser, stirrer, and thermometer, and the temperature was raised to 55° C., and a mixture of 10 parts of methacrylic acid, 58 parts of ethyl acrylate, 47 parts of methyl methacrylate (molar ratio: methacrylic acid: ethyl acrylate:methyl methacrylate=10:50:40), 3.46 parts of 2,2′-azobis (2,4-dimethylvaleronitrile), and 100 parts of ethyl acetate was added dropwise over 2 hours. The mixture was stirred for 3 hours while maintaining the temperature at 50° C. to 55° C. The resulting reaction mixture was cooled to 40° C. or less, diluted with 125 parts of ethyl acetate, and poured into a large amount of a mixture of ion-exchanged water and methanol to precipitate the resin, which was then filtered and recovered. 650 parts of propylene glycol monomethyl ether acetate was added to the resulting resin, which was dissolved and concentrated, and then 650 parts of propylene glycol monomethyl ether acetate was added and concentrated again to provide 186 parts of a propylene glycol monomethyl ether acetate solution of Resin A2-2 (solid content 45%, yield 73%). The weight average molecular weight of Resin A2-2 was 3.85×10⁴.

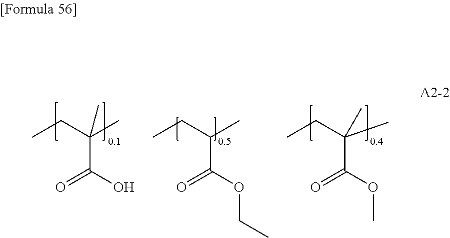

### Synthesis Example 5 [Synthesis of Resin A2-3]

70 parts of ethyl acetate was added to a four-neck flask equipped with a reflux condenser, stirrer, and thermometer, and the temperature was raised to 55° C., and a mixture of 8 parts of methacrylic acid, 58 parts of ethyl acrylate, 49 parts of methyl methacrylate (molar ratio of methacrylic acid: ethyl acrylate:methyl methacrylate=8:50:42), 3.46 parts of 2,2′-azobis (2,4-dimethylvaleronitrile), and 100 parts of ethyl acetate was added dropwise over 2 hours. The mixture was stirred for 3 hours while maintaining the temperature at 50° C. to 55° C. The resulting reaction mixture was cooled to 40° C. or less, diluted with 125 parts of ethyl acetate, and poured into a large amount of a mixture of ion-exchanged water and methanol to precipitate the resin, which was then filtered and recovered. 650 parts of propylene glycol monomethyl ether acetate was added to the resulting resin, which was dissolved and concentrated, and then 650 parts of propylene glycol monomethyl ether acetate was added and concentrated again to provide 184 parts of a propylene glycol monomethyl ether acetate solution of Resin A2-3 (solid content 45%, yield 72%). The weight average molecular weight of Resin A2-3 was 3.64× 104.

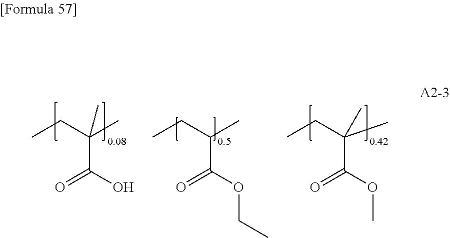

### Synthesis Example 6 [Synthesis of Resin AX2-1]

70 parts of ethyl acetate was added to a four-neck flask equipped with a reflux condenser, stirrer, and thermometer, and the temperature was raised to 55° C., and a mixture of 8 parts of acrylic acid, 100 parts of ethyl acrylate (molar ratio of acrylic acid: ethyl acrylate=10:90), 3.31 parts of 2,2′-azobis(2,4-dimethylvaleronitrile), and 100 parts of ethyl acetate was added dropwise over 2 hours. The mixture was stirred for 3 hours while maintaining the temperature at 50° C. to 55° C. The resulting reaction mixture was cooled to 40° C. or less, diluted with 110 parts of ethyl acetate, and poured into a large amount of a mixture of ion-exchanged water and methanol to precipitate the resin, which was then filtered and collected. 600 parts of propylene glycol monomethyl ether acetate was added to the obtained resin, which was then dissolved and concentrated, then 600 parts of propylene glycol monomethyl ether acetate was added and the mixture was concentrated again to provide 173 parts of a propylene glycol monomethyl ether acetate solution of resin AX2-1 (solid content 45%, yield 72%). The weight average molecular weight of resin AX2-1 was 6.67 × 104.

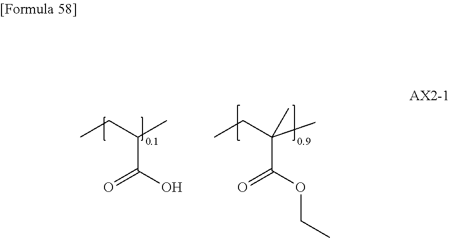

### Synthesis Example 7 [Synthesis of Resin A³-1]

413.5 parts of 2,5-xylenol, 103.4 parts of salicylaldehyde, 20.1 parts of p-toluenesulfonic acid, and 826.9 parts of methanol were added to a four-neck flask equipped with a stirrer, reflux condenser, and thermometer, and the temperature was raised to reflux and maintained at that temperature for 4 hours. After cooling, 1320 parts of methyl isobutyl ketone was added and 1075 parts of the solvent were distilled off at normal pressure. 762.7 parts of m-cresol and 29.0 parts of 2-tert-butyl-5-methylphenol were added, the temperature was raised to 65° C., and 678 parts of 37% aqueous formalin solution was added dropwise over 1.5 hours while adjusting the temperature such that the temperature reached 87° C. at the end of the addition. The resulting mixture was maintained at 87° C. for 10 hours, then 1, 115 parts of methyl isobutyl ketone was added, and the mixture was washed by liquid-liquid separation three times with ion-exchanged water. 500 parts of methyl isobutyl ketone was added to the resulting mixture, which was concentrated under reduced pressure until the total amount was 3,435 parts. 3,796 parts of methyl isobutyl ketone and 4, 990 parts of n-heptane were added to the resulting mixture, which was then heated to 60° C. and stirred for 1 hour. Thereafter, liquid-liquid separation was performed and the lower layer including the resin was taken out, diluted with 3, 500 parts of propylene glycol monomethyl ether acetate, and concentrated to provide 1, 690 parts of a propylene glycol monomethyl ether acetate solution of Resin A³-1 (solid content 43%). The weight average molecular weight of novolak resin A³-1 was 7×10³. In addition, the residual film rate in development with a 2.38% by mass aqueous solution of tetramethylammonium hydroxide was 74%. The residual film rate was measured by the method described in the section <Resin (A2)> of Embodiments for Carrying out Invention.

### <Preparation of Resist Composition>

The components shown in Table 1 were mixed and dissolved to provide a mixture, which was then filtered through a fluororesin filter with a pore size of 15 μm to prepare a resist composition.

TABLE 1

| Resist | | | | Acid | | | Adhesion |
|---|---|---|---|---|---|---|---|
| composition | Resin (A1) | Resin (A2) | Resin (A3) | generator | Quencher | Solvent | improver |
| Composition 1 | A1-1 = | A2-1 = | A3-1 = | B-1 = | C-1 = | D-1 = | E-1 = |
| | 7.43 parts | 2.02 parts | 4.05 parts | 0.07 parts | 0.020 parts | 13 parts | 0.002 parts |
| Composition 2 | A1-1 = | A2-1 = | A3-1 = | B-2 = | C-2 = | D-1 = | E-1 = |
| | 7.43 parts | 2.02 parts | 4.05 parts | 0.098 parts | 0.012 parts | 13 parts | 0.002 parts |
| Composition 3 | A1-1 = | A2-2 = | A3-1 = | B-1 = | C-1 = | D-1 = | E-1 = |
| | 7.43 parts | 2.02 parts | 4.05 parts | 0.07 parts | 0.020 parts | 13 parts | 0.002 parts |
| Composition 4 | A1-1 = | A2-3 = | A3-1 = | B-1 = | C-1 = | D-1 = | E-1 = |
| | 7.43 parts | 2.02 parts | 4.05 parts | 0.07 parts | 0.020 parts | 13 parts | 0.002 parts |
| Composition 5 | A1-1 = | A2-1 = | A3-1 = | B-3 = | C-2 = | D-1 = | E-1 = |
| | 7.43 parts | 2.02 parts | 4.05 parts | 0.098 parts | 0.012 parts | 13 parts | 0.002 parts |
| Comparative | A1-1 = | AX2-1 = | A3-1 = | B-1 = | C-1 = | D-1 = | E-1 = |
| composition 1 | 7.43 parts | 2.02 parts | 4.05 parts | 0.07 parts | 0.020 parts | 13 parts | 0.002 parts |
| Comparative | AX1-1 = | A2-1 = | A3-1 = | B-1 = | C-1 = | D-1 = | E-1 = |
| composition 2 | 7.43 parts | 2.02 parts | 4.05 parts | 0.07 parts | 0.020 parts | 13 parts | 0.002 parts |

<Resin>
A1-1: Resin A1-1
AX1-1: Resin AX1-1
A2-1: Resin A2-1
A2-2: Resin A2-2
A2-3: Resin A2-3
AX2-1: Resin AX2-1
A3-1: Resin A3-1

### <Acid Generator (B)>

B-1: N-hydroxynaphthalimide triflate (manufactured by Heraeus Holding GmbH)

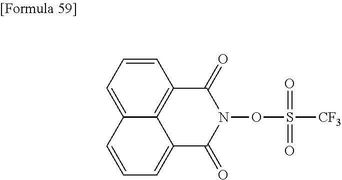 [SMILES: O=C1c2cccc3cccc(c23)C(=O)N1OS(=O)(=O)C(F)(F)F]

B-2: Compound represented by the following formula (synthesized by the method described in WO 2016/072049)

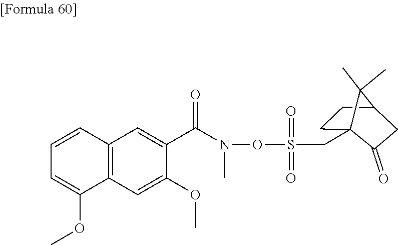 [SMILES: COc1cc2c(OC)cccc2cc1C(=O)N(C)OS(=O)(=O)CC12CCC(CC1=O)C2(C)C]

B-3: Compound represented by the following formula (synthesized by changing (+)-10-camphorsulfonyl chloride to 1-octanesulfonyl chloride in the same manner as described in WO 2016/072049).

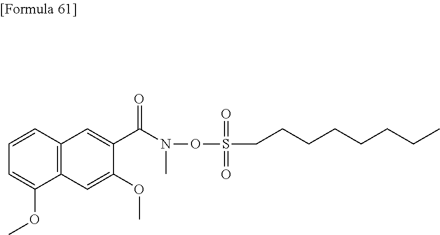 [SMILES: CCCCCCCCS(=O)(=O)ON(C)C(=O)c1cc2cccc(OC)c2cc1OC]

### <Quencher (C)>

C-1:2, 4,5-triphenylimidazole (Tokyo Chemical Industry Co., Ltd.)

C-2: N, N-dicyclohexylmethylamine (Sigma-Aldrich Co. LLC)

### <Solvent (D)>

D-1: Propylene glycol monomethyl ether acetate

### <Creating Dry Film Resist>

The resist compositions (compositions 1 to 5, comparative compositions 1 and 2) listed in Table 1 were applied using a die coater as the film coater and a polyethylene terephthalate (PET) film (thickness 38 μm) as the support film such that the film thickness after drying would be as listed in Table 2, and the film was dried in a temperature-rising oven at 70° C. for 5 minutes and then at 130° C. for 5 minutes. A polyethylene (PE) film was attached as a protective film on the surface of the dry film thus prepared, to provide the dry film resists listed in Table 2.

TABLE 2

| Dry film | Resist composition | Thickness |
|---|---|---|
| resist | layer | (μm) |
| Film 1 | Composition 1 | 130 |
| Film 2 | Composition 2 | 130 |
| Film 3 | Composition 3 | 130 |
| Film 4 | Composition 4 | 130 |
| Film 5 | Composition 5 | 130 |
| Comparative film 1 | Comparative composition 1 | 130 |
| Comparative film 2 | Comparative composition 2 | 130 |
| Comparative film 3 | Comparative composition 2 | 5 |

(i-Line Exposure Evaluation of Dry Film Resist)

Examples 1 to 5 and Comparative Examples 1 and 2 Using a vacuum laminator PVL0202S(Nisshinbo Mechatronics Inc.), the degree of vacuum in the vacuum chamber was set to 50 Pa, and the resist composition layers on the support films of the dry film resists of films 1 to 5 and comparative films 1 and 2 were adhered to a 4-inch silicon wafer substrate on which copper had been deposited by vapor deposition. Then, the resist composition layer was formed by pre-baking on a direct hot plate at 120° C. for 300 seconds.

Then, the composition layer formed on the wafer was exposed to light through a mask for forming a 1:1 contact hole pattern (hole diameter: 30, 40, 50 μm, pitch: 60, 80, 100 μm) using an i-line stepper (NSR-200519C, manufactured by NIKON CORPORATION, NA=0.5) while changing the exposure dose stepwise.

Without a heat treatment after exposure (post-exposure bake), a 2.38% by mass tetramethylammonium hydroxide (TMAH) aqueous solution was allowed to stand for 100 seconds (puddle development), and this was repeated five times to provide the resist pattern. The resist pattern obtained after development was observed with a scanning electron microscope, and the exposure dose at which a 50 μm hole pattern was obtained was determined to be the effective sensitivity.

### Reference Examples 1 and 2

In the i-line exposure evaluation of the above dry film resist, the i-line exposure evaluation of the dry film resist was performed in the same manner as in Example 1, except that comparative films 2 and 3 were used instead of film 1, and after exposure, post-exposure baking was performed on a hot plate at a temperature of 90° C. for 90 seconds.

### <Resolution Evaluation>

The resist pattern obtained at the effective sensitivity was observed with a scanning electron microscope, and the minimum mask hole diameter of the resolved contact hole pattern was measured.

A hole diameter of any one hole selected from the resolved contact hole patterns was rated as “O” in a case of 100% to 80% of the mask hole diameter, “O” in a case of 80% to 50%, and “Δ” in a case of 50% to 10%.

### <Plating Resistance Evaluation>

A patterned wafer was prepared at an effective sensitivity obtained in the i-line exposure evaluation as described above, and then was immersed in a Cu plating solution for 15 minutes.

After completion of the immersion, the patterned wafer was observed under an optical microscope to observe the contact hole pattern with a line width of 50 μm.

After immersion for 10 minutes, the resist pattern was dissolved in the plating solution and a change was observed in the resist pattern, which was rated as “x”, after immersion for 15 minutes, there was no change in the resist pattern, which was rated as “Δ” and after immersion for 20 minutes, there was no change in the resist pattern, which was marked as “O”.

Table 3 shows the evaluation of resolution and plating resistance for each of Examples 1 to 5, Comparative Examples 1 and 2, and Reference Examples 1 and 2.

TABLE 3

| | | Resist | | Thickness | Resolution | Plating |
|---|---|---|---|---|---|---|
| | Dry film resist | composition | PEB | (μm) | (μm) | resistance |
| Example 1 | Film 1 | Composition 1 | — | 130 | 40 | ◯ |
| | | | | | ◯ | |
| Example 2 | Film 2 | Composition 2 | — | 130 | 40 | ◯ |
| | | | | | ⊙ | |
| Example 3 | Film 3 | Composition 3 | — | 130 | 40 | Δ |
| | | | | | ◯ | |
| Example 4 | Film 4 | Composition 4 | — | 130 | 40 | Δ |
| | | | | | ◯ | |
| Example 5 | Film 5 | Composition 5 | — | 130 | 40 | ◯ |
| | | | | | ⊙ | |
| Comparative | Comparative | Comparative | — | 130 | 40 | X |
| Example 1 | film 1 | composition 1 | | | ◯ | |
| Comparative | Comparative | Comparative | — | 130 | No | — |
| Example 2 | film 2 | composition 2 | | | resolution | |
| Reference | Comparative | Comparative | 90° C./90 sec | 130 | 40 | ◯ |
| Example 1 | film 2 | composition 2 | | | Δ | |
| | | | | | Residue | |
| Reference | Comparative | Comparative | 90° C./90 sec | 5 | 30 | ◯ |
| Example 2 | film 3 | composition 2 | | | | |

From Table 1, it has been confirmed that the resist patterns of Examples 1 to 5 had favorable resolution and plating resistance without heat treatment after exposure (post-exposure bake: PEB), despite having a large film thickness of 130 μm. In contrast, it has been confirmed that the resist pattern of Comparative Example 1 did not resolve and had poor plating resistance without PEB. It has been confirmed that the resist pattern of Comparative Example 2 achieved resolution by performing PEB, but left residues.

### INDUSTRIAL APPLICABILITY

The resist composition of the present invention can form a resist pattern that exhibits both excellent resolution and plating resistance, and is suitable for semiconductor microfabrication and therefore extremely useful industrially.

1. A resist composition comprising:
a resin (A1) having a group represented by formula (1);
a resin (A2) including a structural unit represented by formula (a3); and
an acid generator (B), 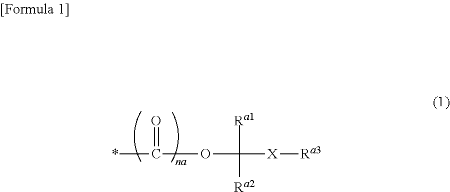
wherein,
R^{a1} and R^{a2} each independently represent a hydrogen atom or a hydrocarbon group having 1 to 20 carbon atoms, R^{a3} represents a hydrocarbon group having 1 to 20 carbon atoms, or R^{a1} represents a hydrogen atom or a hydrocarbon group having 1 to 20 carbon atoms, and R^{a2} and R^{a3} are bonded to each other to form a heterocycle having 3 to 20 carbon atoms together with the carbon atom to which R^{a2} is bonded and X to which R^{a3} is bonded, and a methylene group included in the hydrocarbon group and the heterocycle is optionally replaced with an oxygen atom or a sulfur atom,
X represents an oxygen atom or a sulfur atom,
na represents 0 or 1,
* represents a binding site, 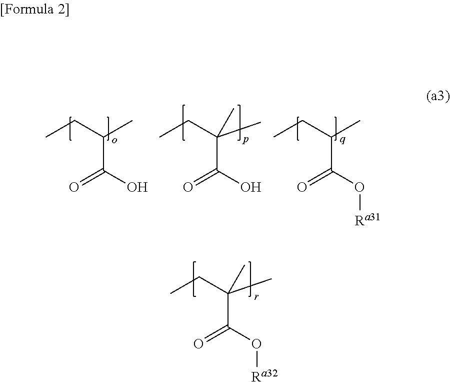
wherein,
R^{a31} and R^{a32} each independently represent an alkyl group having 1 to 12 carbon atoms, and a methylene group included in the alkyl group is optionally replaced with an oxygen atom, and
o, p, q, and r each independently represent 0 or a positive number less than 1, and at least one of o and p represents a positive number less than 1, and when o is 0, p and q each represent a positive number less than 1, and when p is 0, o and r each represent a positive number less than 1, and when q is 0, o and r each represent a positive number less than 1, and when r is 0, p and q each represent a positive number less than 1, provided that o+p+q+r=1 is satisfied.

2. The resist composition according to claim 1, wherein the resin (A1) includes a structural unit represented by formula (a1-1) or formula (a1-2): 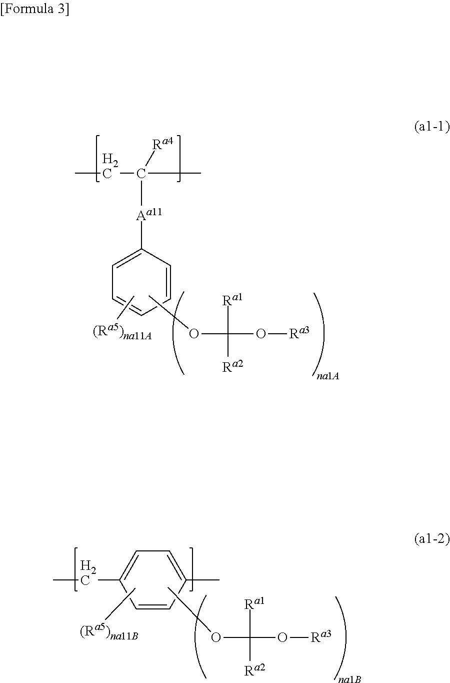
wherein,
R^{a1}, R^{a2}, and R^{a3} have a same meaning as in formula (1),
R^{a4} represents a hydrogen atom, a halogen atom, an alkyl group having 1 to 6 carbon atoms, or a haloalkyl group having 1 to 6 carbon atoms,
R^{a5} represents a halogen atom, a hydroxy group, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group,
A^{a11} represents a single bond or an alkanediyl group having 1 to 12 carbon atoms, and —CH₂— included in the alkanediyl group is optionally replaced with —O—, —CO—, or —NR^{a6}—, R^{a6} represents a hydrogen atom or an alkyl group having 1 to 6 carbon atoms,
na1A represents an integer of 1 to 5, and when na1A is 2 or more, a plurality of groups in parentheses are optionally the same or different from each other,
na11A represents an integer of 0 to 4, and when na11A is 2 or more, a plurality of R^{a5}s are optionally the same or different from each other, provided that 1≤na1A+na11A≤5 is satisfied,
na1B represents an integer of 1 to 4, and when na1B is 2 or more, a plurality of groups in parentheses are optionally the same or different from each other, and
na11B represents an integer of 0 to 3, and when na11B is 2 or more, a plurality of R^{a5}s are optionally the same or different from each other, provided that 1≤na1B+na11B≤4 is satisfied.

3. The resist composition according to claim 2, wherein the resin (A1) includes a structural unit represented by formula (a1-1).

4. The resist composition according to claim 1, wherein the resin (A1) further includes a structural unit represented by formula (a2-1): 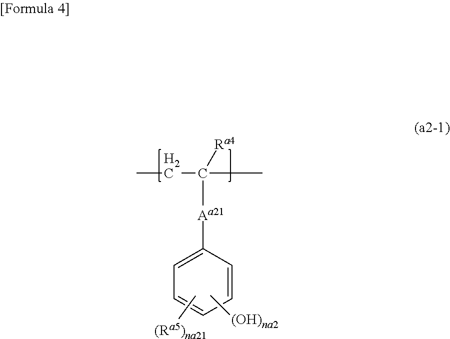
wherein,
R^{a24} represents a hydrogen atom, a halogen atom, an alkyl group having 1 to 6 carbon atoms, or a haloalkyl group having 1 to 6 carbon atoms,
R^{a25} represents a halogen atom, a carboxy group, an alkyl group having 1 to 6 carbon atoms, a haloalkyl group having 1 to 6 carbon atoms, an alkoxy group having 1 to 6 carbon atoms, an alkoxyalkyl group having 2 to 12 carbon atoms, an alkoxyalkoxy group having 2 to 12 carbon atoms, an alkylcarbonyl group having 2 to 4 carbon atoms, an alkylcarbonyloxy group having 2 to 4 carbon atoms, an acryloyloxy group, or a methacryloyloxy group,
A^{a21} represents a single bond or an alkanediyl group having 1 to 12 carbon atoms, and —CH₂— included in the alkanediyl group is optionally replaced with —O—, —CO—, or —NR^{a26}—,
R^{a26} represents a hydrogen atom or an alkyl group having 1 to 6 carbon atoms,
na2 represents an integer of 1 to 5, and
na21 represents an integer of 0 to 4, and satisfies 1≤na2+na21≤5, and when na21 is 2 or more, a plurality of R^{a25}s are optionally the same or different from each other.

5. The resist composition according to claim 1, wherein 0.05≤0+p≤0.30 is satisfied, and q and r each represent a positive number less than 1.

6. The resist composition according to claim 1, further comprising a novolak resin (A3).

7. The resist composition according to claim 1, further comprising an adhesion improver (E),
wherein the adhesion improver (E) includes at least one selected from the group consisting of a sulfur-containing compound, an aromatic hydroxy compound, a benzotriazole-based compound, a triazine-based compound, and a silicon-containing compound.

8. A dry film resist comprising:
a support film; and
a resist composition layer stacked on the support film and including the resist composition according to claim 1.

9. A method for producing a dry film resist, comprising:
(1a) a step of applying the resist composition according to claim 1 to a support film to form a photoresist composition layer; and
(2a) a step of drying the resist composition layer.

10. A pattern forming method comprising:
(1b) a step of applying the resist composition according to claim 1 onto a substrate and drying the resist composition to form a resist composition layer;
(2b) a step of exposing the resist composition layer to ultraviolet light having a wavelength of 500 nm or less; and
(3b) a step of developing the exposed resist composition layer without heating.

11. A pattern forming method comprising:
(1c) a step of stacking the dry film resist according to claim 8 on a substrate;
(2c) a step of peeling at least a portion of the support film from the resist composition layer and exposing the resist composition layer to ultraviolet light having a wavelength of 500 nm or less; and
(3c) a step of developing the exposed resist composition layer without heating.

12. A method for producing a plated object, comprising:
a step of forming a resist pattern on a substrate having a conductive layer using the resist composition according to claim 1 such that a portion of the conductive layer is exposed;
a step of forming a plated object using the resist pattern as a mold; and
a step of peeling off the resist pattern after forming the plated object.
